(19) United States
(12) Patent Application Publication
(10) Pub. No.: US 2025/0372590 A1
(43) Pub. Date: Dec. 4, 2025

(54) ELECTRO-OPTICAL MEMORY CIRCUIT PACKAGE

(71) Applicant: Celestial AI Inc., Santa Clara, CA (US)

(72) Inventors: Kyung Oh, Campbell, CA (US); Ankur Aggarwal, Pleasanton, CA (US); Suresh Venkata Pothukuchi, Chandler, AZ (US)

(21) Appl. No.: 19/192,064

(22) Filed: Apr. 28, 2025

Related U.S. Application Data
(60) Provisional application No. 63/655,461, filed on Jun. 3, 2024.
(60) Provisional application No. 63/694,684, filed on Sep. 13, 2024.

(51) Int. Cl. H01L 25/18; G02B 6/42; H01L 23/31; H10B 80/00; H10D 80/30

(52) U.S. Cl. CPC H01L 25/18; G02B 6/4249; G02B 6/4255; G02B 6/4274; G02B 6/4295; H01L 23/3107; H10B 80/00; H10D 80/30

(57) ABSTRACT

The present disclosure relates to packaging techniques in connection with packaging electrical and optical components within circuit packages. For example, one or more examples described herein involve producing or manufacturing memory circuit packages having memory stacks positioned on top of electronic integrated (EIC) dies positioned over one or more PIC wafers. Techniques described herein also relate to forming overmolded memory circuit packages having optical interfaces which are optically accessible via optical window(s).

### CROSS-REFERENCE TO RELATED APPLICATIONS

This application claims priority to U.S. Provisional Patent Application No. 63/655,461, entitled “PACKAGING OPTICALLY ACCESSIBLE COMPONENTS”, filed on Jun. 3, 2024, the entirety of which is incorporated herein by reference. This application also claims priority to U.S. Provisional Patent Application No. 63/694,684, entitled “PACKAGING OPTICAL COMPONENTS,” filed on Sep. 13, 2024, the entirety of which is incorporated herein by reference.

### BACKGROUND OF THE DISCLOSURE

The subject matter discussed in this section should not be assumed to be prior art merely as a result of inclusion in this section. Similarly, any problems mentioned in this section or associated with subject matter provided as background should not be construed as an admission of prior art.

Integrated circuits (ICs) with processors, especially those for executing artificial intelligence and machine learning functions, move large amounts of data among one or more processor ICs and one or more memory ICs. As processors and other electronic components have continued to evolve, becoming faster and more efficient with how data is processed, components responsible for moving data between different components within a circuit or between circuits has not scaled adequately to meet the growing demand. Many approaches have been made to scale the ability of systems to move and/or process data between various components, such as faster and more sophisticated memory hardware. These solutions, however, often fall short at scaling with the ever increasing demand to move more data at faster speeds between system components.

These and other problems exist in connection with moving an increasing amount of data between processors, memory, and other electronic components in electronic systems.

### BRIEF DESCRIPTION OF THE DRAWINGS

FIG. 1 illustrates an exemplary embodiment of a memory circuit package as described herein, according to embodiments of the present disclosure.

FIGS. 2A-2C illustrate an example of creating a memory stack on a base circuit package to generate a memory circuit package, according to embodiments of the present disclosure.

FIG. 2D illustrates an example of generating one or more memory hardware dies from a memory hardware wafer, according to embodiments of the present disclosure.

FIGS. 2E-2G illustrate an example of creating a memory stack and positioning the memory stack on a base circuit package to generate a memory circuit package, according to embodiments of the present disclosure.

FIGS. 2H-2J illustrate an example of generating memory stacks from memory hardware wafers, according to embodiments of the present disclosure.

FIGS. 2K-2L illustrate examples of a logic buffer in relation to the memory stack, according to embodiments of the present disclosure.

FIGS. 2M-2O illustrate examples of the memory circuit package having various photonic interfaces for facilitating off-chip photonic communication, according to embodiments of the present disclosure.

FIG. 2P illustrates an example of the memory circuit package having multiple EIC dies and memory stacks being photonically coupled for inter-chip electro-photonic communication, according to embodiments of the present disclosure.

FIGS. 3A-3I show different views of a sacrificial die for utilizing in connection with forming an overmolded circuit package in order to provide an optical path to an optical region of a photonic integrated circuit (or other wafer or substrate), according to embodiments of the present disclosure.

FIG. 4A illustrates a side view of a memory circuit package, according to embodiments of the present disclosure.

FIG. 4B illustrates a side view of an exemplary embodiment of forming a molded memory circuit package, according to embodiments of the present disclosure.

FIGS. 4C-4F illustrate an example of forming an optical window through an overmold of a molded memory circuit package, according to embodiments of the present disclosure.

FIG. 5A illustrates a side view of a memory circuit package, according to embodiments of the present disclosure.

FIG. 5B illustrates a side view of an exemplary embodiment of forming a molded memory circuit package, according to embodiments of the present disclosure.

FIGS. 5C-5E illustrate an example of forming an optical window through an overmold of a molded memory circuit package, according to embodiments of the present disclosure.

FIG. 6A illustrates a side view of a memory circuit package and a neighboring package, according to embodiments of the present disclosure.

FIG. 6B illustrates a top view of a photonic integrated circuit by which a memory circuit package and a neighboring package are implemented, according to embodiments of the present disclosure.

FIG. 6C illustrates a side view of an exemplary embodiment of forming a molded memory circuit package, according embodiments of the present disclosure.

FIGS. 6D-6E illustrate example grinding and dicing processes of a molded memory circuit package and neighboring molded package, according to embodiments of the present disclosure.

FIGS. 7A-7C illustrate an example of creating a memory hardware wafer stack on a base wafer package to generate a memory wafer package, according to embodiments of the present disclosure.

FIGS. 7D-7E illustrate examples of a logic buffer in relation to the memory hardware wafer stack, according to embodiments of the present disclosure.

FIGS. 7F-7G illustrate examples of a memory wafer package having various photonic interfaces for facilitating off-chip communication, according to embodiments of the present disclosure.

FIG. 7H illustrates another example of a memory hardware wafer stack having an optical region in a photonic integrated circuit wafer, according to embodiments of the present disclosure.

FIGS. 7I-7J illustrate an example of generating a memory wafer package having an optical region accessible to a lateral side of an electronic integrated circuit wafer and a memory hardware wafer stack, according to embodiments of the present disclosure.

FIG. 8 illustrates a flow diagram for a method or a series of acts for generating a memory circuit package as described herein, according to embodiments of the present disclosure.

FIG. 9 illustrates a flow diagram for a method or a series of acts for generating a memory circuit package as described herein, according to embodiments of the present disclosure.

FIG. 10A illustrates a top view of a wafer and a die, which may be included in one or more circuit packages, according to at least one embodiment of the present disclosure.

FIG. 10B illustrates a top view of a wafer having various components disposed thereon, according to at least one embodiment of the present disclosure.

FIG. 11 illustrates an example side-view cross-section diagram of a circuit package that includes various components and that is coupled to a fiber array unit, according to at least one embodiment of the present disclosure.

FIG. 12A illustrates an example package having a first die and a second die having intra-chip connections therebetween, according to at least one embodiment of the present disclosure.

FIG. 12B illustrates an example of a circuit package that enables inter-chip or inter-package connection, according to at least one embodiment of the present disclosure.

FIG. 12C illustrates another example of a circuit package that enables inter-chip or inter-package connection, according to at least one embodiment of the present disclosure.

FIG. 12D illustrates an example of a circuit package having inter-chip or inter-package connections via an edge coupler, according to at least one embodiment of the present disclosure.

### DETAILED DESCRIPTION

The present disclosure relates to example implementations of electro-photonic circuit packages, or computing packages having both electronic and photonic capabilities. Indeed, implementations herein relate to facilitating the manufacture and packaging of electro-photonic memory circuits having stacks of memory resources included thereon. For instance, stacks of memory hardware components, such as high-bandwidth memory (HBM) stacks or vertical stacks of dynamic random-access memory (DRAM) (or other types of memory), may be implemented on top of, or vertically stacked, EIC dies of an electro-photonic circuit package having one or more processing or computing components thereon. In this way, the memory stacks may be more directly accessible by the EIC dies upon which they are positioned.

This stacking of memory resources over the EIC dies provides more immediate access within limited space constraints over conventional packages in which hardware chips are provided via a stand-alone pool of memory, typically on a different chip package or on a separate location on a circuit package. Indeed, by positioning the memory stacks on top of the EIC dies, each EIC die may directly interface with associated memory hardware resources. Additionally, other devices, such as other EIC dies, may access a given memory stack through the associated EIC die whereon the stack is connected.

One or more embodiments of the present disclosure relate to a memory package (referred to herein in some embodiments as a memory circuit package) having features and functionality that provide access to the stacked memory resources via an optical region accessible via a top surface of a wafer or die (e.g., a PIC wafer). For example, one or more embodiments described herein refer to a memory package including a plurality of interconnected memory layers stacked on top of a logic buffer. The memory package may include a first die having an electrical portion of an electro-photonic transceiver stacked below the logic buffer, the electrical portion of the electro-photonic transceiver being configured to send or receive instructions to the logic buffer to read or write data to or from one or more of the plurality of interconnected memory layers. In one or more embodiments, the memory package includes a second die stacked below the first die having an optical portion of the electro-photonic transceiver that, in cooperation with the electrical portion of the electro-photonic transceiver, is configured to transform instructions from an optical signal to an electrical signal when receiving or transform instructions from an electrical signal to an optical signal when transmitting. In one or more embodiments, the memory package includes an optical region on a top surface of the second die which does not intersect with the first die, the optical region being designed to allow light to exit or enter from the top surface of the second die, the optical region being in communication with the optical portion of the electro-photonic transceiver such that the optical signal can exit the top surface when transmitting and enter the top surface when receiving.

As another example, in one or more embodiments, the memory package includes a plurality of interconnected memory layers stacked on top of a logic buffer. The memory package may include an electronic integrated circuit (EIC) layer, comprising an electronic die having an electrical portion of an electro-photonic transceiver stacked below the logic buffer, the electrical portion of the electro-photonic transceiver being configured to send or receive instructions to the logic buffer to read or write data to or from one or more of the plurality of interconnected memory layers. In one or more embodiments, the memory package includes photonic integrated circuit (PIC) wafer, including an optical region near a top surface of the PIC wafer configured to allow light to enter or exit the PIC wafer, and an optical portion of the electro-photonic transceiver in optical communication with the optical region, the optical portion being configured to, in cooperation with the electrical portion of the electro-photonic transceiver, transform instructions from an optical signal to an electrical signal when receiving or transform instructions from an electrical signal to an optical signal when transmitting.

Each of these examples may include additional features relates to providing access to the stacked memory layers, whether the memory package includes generic dies having optical and electrical portions, or whether the memory package includes EIC and PIC layers. For example, in one or more embodiments, the memory package includes a plurality of interconnected memory layers and the logic buffer are connected using one or more electrical vias. In one or more embodiments, the logic buffer is implemented as a layer of a memory stack including the plurality of interconnected memory layers, the logic buffer positioned between the plurality of interconnected memory layers and a top surface of the first die. In one or more embodiments, the logic buffer is implemented within the first die.

In one or more embodiments, the memory package includes an overmold layer including an overmold deposited over the plurality of interconnected memory layers and the first die and a portion of the second die and a sidewall positioned around the optical region and forming a void within the overmold layer above the optical region and extending toward a top surface of the second die. In one or more embodiments, the void provides an optical path from a top surface of the memory package to the top surface of the second die near the optical region.

In one or more embodiments, the memory package includes an optical interface component above the top surface of the second die configured to couple a first optical signal in a first fiber to a first waveguide in the second die when receiving and to couple a second optical signal from a second waveguide to a second fiber when transmitting. In one or more embodiments, the optical interface component is a fiber array unit (FAU).

In addition to embodiments related to providing access to stacked memory resources via a top surface of a wafer, one or more embodiments described herein provide access to a stacked memory resource via an edge coupling mechanism in a side of a wafer or other substrate layer. For example, in one or more embodiments, a memory package includes a plurality of interconnected memory layers stacked on top of a logic buffer. In one or more embodiments, the memory package includes a first die having an electrical portion of an electro-photonic transceiver stacked below the logic buffer, the electrical portion of the electro-photonic transceiver being configured to send or receive instructions to the logic buffer to read or write data to or from one or more of the plurality of interconnected memory layers. In one or more embodiments, the memory package includes a second die stacked below the first die having an optical portion of the electro-photonic transceiver that, in cooperation with the electrical portion of the electro-photonic transceiver, is configured to transform instructions from an optical signal to an electrical signal when receiving or transform instructions from an electrical signal to an optical signal when transmitting. In one or more embodiments, the memory package includes an optical region formed in a side surface of the second die, the optical region having one or more structures in which one or more fibers are secured to the one or more structures such that light can be coupled to and from waveguides that are formed within the second die and accessible via the one or more structures formed in the side surface of the second die.

As another example, in one or more embodiments, the memory package includes a plurality of interconnected memory layers stacked on top of a logic buffer. In one or more embodiments, the memory package includes an electronic integrated circuit (EIC) layer, comprising an electronic die having an electrical portion of an electro-photonic transceiver stacked below the logic buffer, the electrical portion of the electro-photonic transceiver being configured to send or receive instructions to the logic buffer to read or write data to or from one or more of the plurality of interconnected memory layers. In one or more embodiments, the memory package includes photonic integrated circuit (PIC) wafer including an optical region near a side surface of the PIC wafer and being formed in the side surface of the PIC wafer, the optical region being designed to allow one or more fibers to be coupled to waveguides that are formed within the PIC wafer and accessible via one or more structures formed in the side surface of the PIC wafer. The PIC wafer may further include an optical portion of the electro-photonic transceiver in optical communication with the optical region, the optical portion being configured to, in cooperation with the electrical portion of the electro-photonic transceiver, transform instructions from an optical signal to an electrical signal when receiving or transform instructions from an electrical signal to an optical signal when transmitting.

Whether the memory package include the first and second dies and/or the EIC and PIC layers, the memory package may include additional features related to providing access to the stacked memory resources described herein. For example, in one or more embodiments, the one or more structures are v-grooves formed within the side surface of the second die. In one or more embodiments, the side surface is formed within one of an interior side surface formed within an outer perimeter of the second die or an exterior side surface formed around the outer perimeter of the second die.

In one or more embodiments, the memory package includes an overmold layer including an overmold deposited over the plurality of interconnected memory layers and the electronic die and a portion of the PIC wafer. In one or more embodiments, the overmold layer includes a sidewall adjacent to the overmold on the top surface of the second die positioned above the optical region and not extending over the side surface of the second die, the sidewall and the overmold forming a structure that extends from the top of the optical region toward a top surface of the memory package. In one or more embodiments, the structure that extends from the top of the optical region toward the top surface of the memory package provides lateral access to the side surface of the second die such that the one or more fibers may be coupled to the waveguides via the one or more structures formed in the side surface of the second die.

In one or more embodiments, the plurality of interconnected memory layers and the logic buffer are connected using one or more electrical vias. In one or more embodiments, the logic buffer is implemented as a layer within a memory stack including the plurality of interconnected memory layers, the logic buffer positioned between the plurality of interconnected memory layers and a top surface of the first die. In one or more embodiments, the logic buffer is implemented within the first die.

In addition to providing access to the stacked memory resources through variety of optical regions and related features, one or more embodiments described herein relate to multiple memory stacks that provide inter and intra-chip accessibility via wafer/die layers. For example, one or more embodiments described herein involve a memory package including a first plurality of interconnected memory layers stacked on top of a first logic buffer and a second plurality of interconnected memory layers stacked on top of a second logic buffer. The memory package may include a first die layer. The first die layer may include a first die having an electrical portion of a first electro-photonic transceiver stacked below the first logic buffer, the electrical portion of the first electro-photonic transceiver being configured to send or receive instructions to the first logic buffer to read or write data to or from one or more of the first plurality of interconnected memory layers. The first die layer may also include a second die having an electrical portion of second first electro-photonic transceiver stacked below the second logic buffer, the electrical portion of the second electro-photonic transceiver being configured to send or receive instructions to the second logic buffer to read or write data to or from one or more of the second plurality of interconnected memory layers.

In one or more embodiments, the memory package includes a second die layer stacked below the first die layer comprising a wafer having an optical portion of the first electro-photonic transceiver and an optical portion of the second electro-photonic transceiver, the optical portion of the first electro-photonic transceiver being connected to the electrical portion of the first electro-photonic transceiver via first electrical interconnects between a top surface of the wafer a bottom surface of the first die, the optical portion of the second electro-photonic transceiver being connected to the electrical portion of the second electro-photonic transceiver via second electrical interconnects between the top surface of the wafer and a bottom surface of the second die, the second die layer including a plurality of waveguides formed in the wafer optically coupling the optical portion of the first electro-photonic transceiver and the optical portion of the second electro-photonic transceiver.

Similar to the above example, in one or more embodiments, the memory package includes a first plurality of interconnected memory layers stacked on top of a first logic buffer and a second plurality of interconnected memory layers stacked on top of a second logic buffer. In one or more embodiments, the memory package includes an EIC layer. The EIC layer may include a first electrical die having an electrical portion of a first electro-photonic transceiver stacked below the first logic buffer, the electrical portion of the first electro-photonic transceiver being configured to send or receive instructions to the first logic buffer to read or write data to or from one or more of the first plurality of interconnected memory layers. The EIC layer may also include a second electrical die having an electrical portion of second first electro-photonic transceiver stacked below the second logic buffer, the electrical portion of the second electro-photonic transceiver being configured to send or receive instructions to the second logic buffer to read or write data to or from one or more of the second plurality of interconnected memory layers.

In one or more embodiments, the memory package may include a photonic integrated circuit (PIC) wafer having an optical portion of the first electro-photonic transceiver and an optical portion of the second electro-photonic transceiver, the optical portion of the first electro-photonic transceiver being connected to the electrical portion of the first electro-photonic transceiver via first electrical interconnects between a top surface of the PIC wafer and a bottom surface of the first electrical die, the optical portion of the second electro-photonic transceiver being connected to the electrical portion of the second electro-photonic transceiver via second electrical interconnects between the top surface of the PIC wafer and a bottom surface of the second electrical die, the PIC wafer including a plurality of waveguides optically coupling the optical portion of the first electro-photonic transceiver and the optical portion of the second electro-photonic transceiver.

Each of the above examples involving multiple stacked memory layers over the same die layer or PIC wafer layer may have similar features and functionality as one another. For example, in one or more embodiments, the first plurality of interconnected memory layers and the second plurality of interconnected memory layers are formed within a plurality of memory wafers that are stacked over the first die layer. In one or more embodiments, a first memory layer of the first plurality of interconnected memory layers and a first memory layer of the second plurality of interconnected memory layers are formed within a first memory wafer of the plurality of memory wafers, and wherein a second memory layer of the first plurality of interconnected memory layers and a second memory layer of the second plurality of interconnected memory layers are formed within a second memory wafer of the plurality of memory wafers.

In one or more embodiments, the memory package includes an overmold layer including an overmold deposited over the first plurality of interconnected memory layers, the second plurality of interconnected memory layers, and at least a portion of a top surface of the wafer of the second die layer. In one or more embodiments, the first plurality of interconnected memory layers and the first logic buffer are connected using a first one or more electrical vias, and wherein the second plurality of interconnected memory layers and the second logic buffer are connected using a second one or more electrical vias. In one or more embodiments, the first logic buffer is implemented as a layer within a first memory stack including the first plurality of interconnected memory layers, the first logic buffer positioned between the first plurality of interconnected memory layers and top surface of the first die, and wherein the second logic buffer is implemented as a layer within a second memory stack including the second plurality of interconnected memory layers, the second logic buffer positioned between the second plurality of interconnected memory layers and top surface of the second die. In one or more embodiments, the first logic buffer is implemented within the first die and the second logic buffer is implemented within the second die.

Additional features and functionality may be applicable to each of the above examples and other examples described herein. For example, in one or more embodiments, the first die (or first dies) is an electrical die having a plurality of first electrical connections on a bottom surface thereof. In one or more embodiments, the second die(s) is a photonic integrated circuit (PIC) wafer having a plurality of second electrical connections on a top surface thereof such that there are electrical couplings between a plurality of first electrical connections (e.g., on a bottom surface of a first die, such as an EIC die) and a plurality of second electrical connections (e.g., on a top surface of a wafer, such as a PIC wafer).

In one or more embodiments, the electro-photonic transceiver includes a driver connected to a modulator in the second die, a transimpedance amplifier (TIA) connected to a photodiode in the second die, a serializer in the first die that provides an output to the driver, and a deserializer in the first die that receives an input from the TIA. In one or more embodiments, one or more of the driver and the TIA is in the second die. In one or more embodiments, the driver is selected from the group consisting of an electro-absorption modulator (EAM), a micro-ring resonator, a ring modulator, a Mach-Zender interferometer (MZI), and a quantum confined stark effect (QCSE) electro-absorptive modulator. In one or more embodiments, each memory layer of the plurality of interconnected memory layers includes a memory resource, wherein the memory resource is one or more of a NAND Flash memory, a solid-state drive (SSD) memory, a NOR Flash memory, a CMOS memory, a thin film transistor-based memory, a phase change memory (PCM), a storage class memory (SCM), a magneto-resistive memory (MRAM), a resistive RAM, a DRAM, an HBM, a DDR-based DRAM, or a DIMM memory.

In one or more embodiments, the first die includes one or more electronic components implemented therein, the one or more electronic components including one or more of a processor component, a memory component, or an analog mixed signal (AMS) block. In one or more embodiments, the second die includes waveguides formed within the second die and passing between the optical region and the optical portion of the electro-photonic transceiver in the second die

As will be discussed in further detail herein, the memory stacks may be generated in any of a variety of ways, including positioning and connecting the memory stacks to a base circuit package comprising an EIC die disposed on a top surface of a photonic integrated circuit (PIC). For example, in some cases, a memory stack may be generated by depositing dies of memory hardware directly on the EIC die, and, through several layers, forming the memory stack thereon. In other cases, memory stacks may be generated separate from the EIC die and may be positioned on the EIC die as an entire stack. As used in connection with various examples herein, a memory stack may refer to one or multiple hardware stacks including stacked memory resources that are interconnected with one another. As will be discussed below, the stacked memory resources may refer to a variety of memory hardware or types or computing resources as may server a particular embodiment. In one or more examples described herein, the memory stacks refer to DRAM stacks, though other types of memory resources may be used.

In other examples, these techniques may be implemented at the wafer level. For example, an EIC wafer having multiple EIC dies therein may be positioned on and connected to a PIC wafer having multiple corresponding instances of photonic components therein. Based on disposing memory hardware wafers on the EIC wafer, each having multiple instances of memory hardware components thereon in corresponding locations to the EIC dies in the EIC wafer, a memory hardware wafer stack may be generated comprising multiple memory stacks. This example may facilitate producing memory circuit packages at scale.

These techniques for implementing memory stacks may facilitate a more efficient use of the real estate of a circuit package on a wafer or substrate. For example, by locating the memory stacks on top of the EIC dies, the memory stacks may effectively be located within a same footprint as the EIC dies, for example, rather than occupying their own footprint or chip real estate. Co-locating the memory stacks with the EIC dies in this way may facilitate more densely populating a circuit package and/or wafer substrate with more EIC dies, more memory resources, other componentry, and combinations thereof.

In addition to creating memory stacks, the present disclosure describes various examples of memory circuit packages having photonic interface connections. For example, a memory circuit package having a memory stack may include on or more optical regions for connecting to an optical interface component which may coupler to one or more external or off-chip devices via optical fibers. As an example, an optical region may include a grating coupler (GC) for connecting to a fiber array unit (FAU). The memory stack may be accessible, via the EIC die and via photonic channels through the PIC, to the external device in this way through the optical interface component coupler to the optical region. The optical region may be advantageously positioned or accessible at a top surface of the PIC, or in some cases at a bottom surface of the PIC. In other examples, the memory circuit package may be configured with an optical region that includes an edge coupler at an edge of the PIC, which may facilitate coupling optical fibers to waveguides in the PIC for providing off-chip access to the memory stack in a similar manner to that of the optical region.

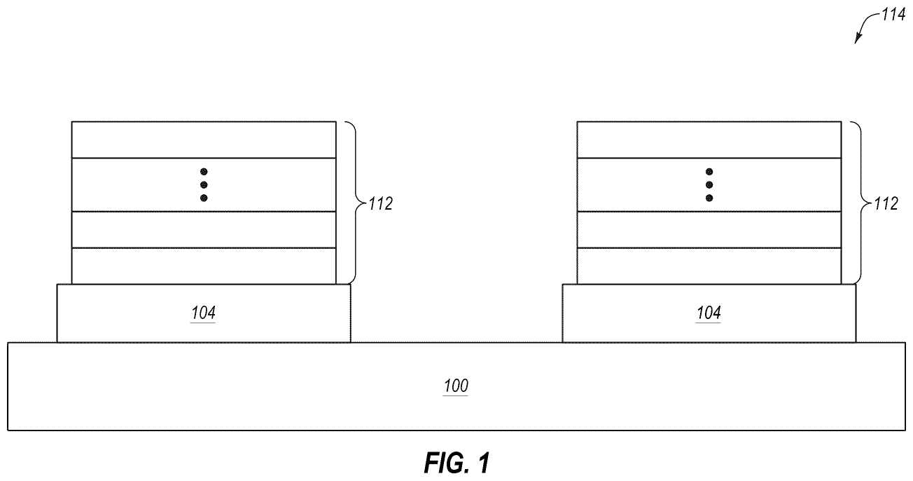

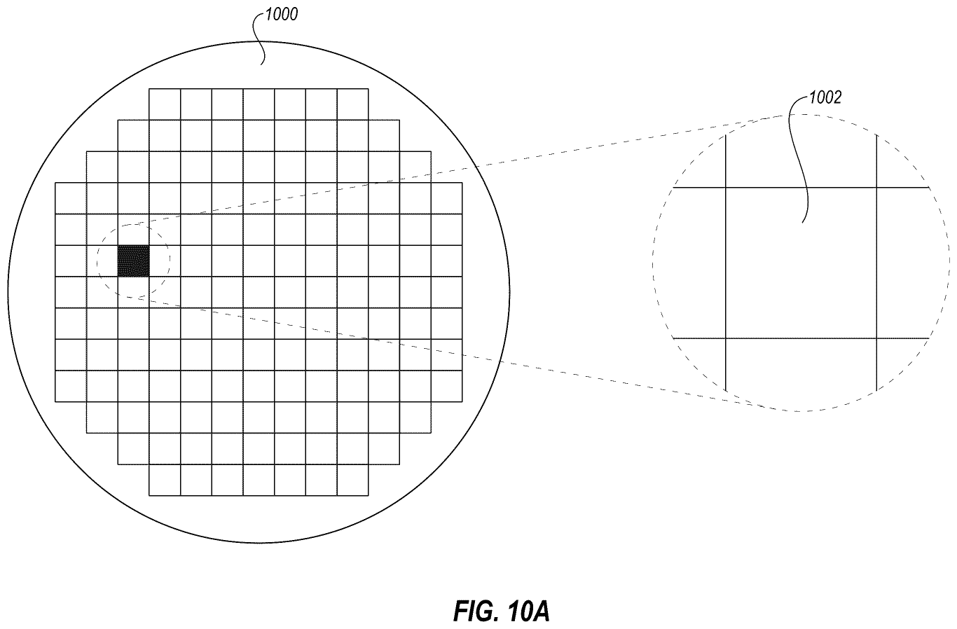

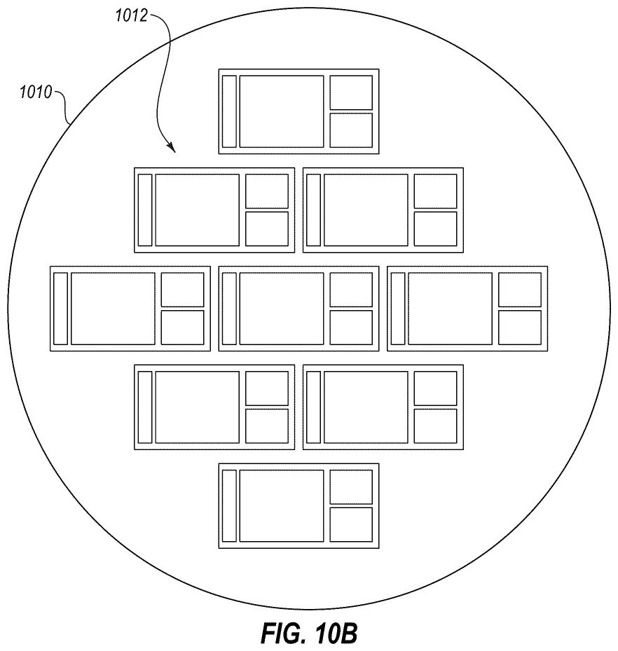

Additional detail will now be discussed in connection with illustrated examples of a memory package in accordance with one or more embodiments described herein. FIG. 1 illustrates an exemplary embodiment of a memory circuit package 114 (or simply “memory package 114”) as described herein, according to embodiments of the present disclosure. The memory circuit package 114 may include an EIC die 104 positioned on a PIC 100. As described in more detail below, the EIC die 104 may include various electronic and/or hardware components, such as computing components, processors, memory hardware, etc. Also, as described in more detail below, the PIC 100 may include photonic components disposed therein which may connect or couple to electronic components of the EIC die 100. For example, electronic transceiver components of the EIC die 104 may be electrically interconnected with photonic transceiver components in the PIC 100, which may facilitate the hardware components of the EIC die 104 communicating via photonic signals, or in a photonic domain. More details regarding the EIC die 104, the PIC 100, and photonic communication is described below in connection with FIGS. 10A-12D.

The memory circuit package 114 may include a memory stack 112. The memory stack 112 may include memory resources arranged a stacked or otherwise layered format. In some examples described herein, the memory stack is a high-bandwidth memory stack of various dynamic random-access memory (DRAM) hardware. Other implementations may include other types of memory resources (e.g., NAND, SSD, NOR, RRAM, DIMM, etc.). As shown in FIG. 1, a memory stack 112 may be positioned, or stacked, on top of the EIC die 104. The EIC die 104 may be physically and electrically connected to the memory stack 112 such that the hardware components of the EIC die 104 may access the memory resources in the memory stack 112. For instance, the EIC die 104 may include a first set of electrical contacts on a first surface (e.g., a top surface of the EIC die 104) that are electrically connected with a second set of electrical contacts on a bottom surface of the memory stack 112 such that when the memory stack 112 is deposited or otherwise secured in position over the EIC die 104, the layers of the memory stack 112 are electrically coupled to components within the EIC die 104. As will be discussed below, this connection between the memory stack 112 and EIC die 104 may be through a logic buffer layer between the respective components.

This arrangement of hardware is in contrast to other approaches, for example, which may locate memory resources separate, or at a discrete location on the circuit package, from the EIC die 104, such as at a separate locate on the PIC 100 or on another chip altogether. In this way, the memory stack 112 may be advantageously included in the memory circuit package 114 within a footprint of the EIC die 100 without sacrificing other PIC real estate.

As shown in FIG. 1, the memory circuit package 114 may optionally include two (or more) EIC dies 104 each having a memory stack 112 thereon. In this way, the memory circuit package may be configured with various EIC dies that may each have direct access to robust memory resources without having to allocate dedicated space on the PIC 100 for those memory resources. Additionally, as described below in detail, embodiments including multiple EIC dies 104 on the memory circuit package 114 may enable photonic communication between the EIC dies 104 by way of photonic channels traversing the PIC. In this way, the EIC dies 104 may also share memory resources based on accessing the memory stack 112 located on different EIC dies 104.

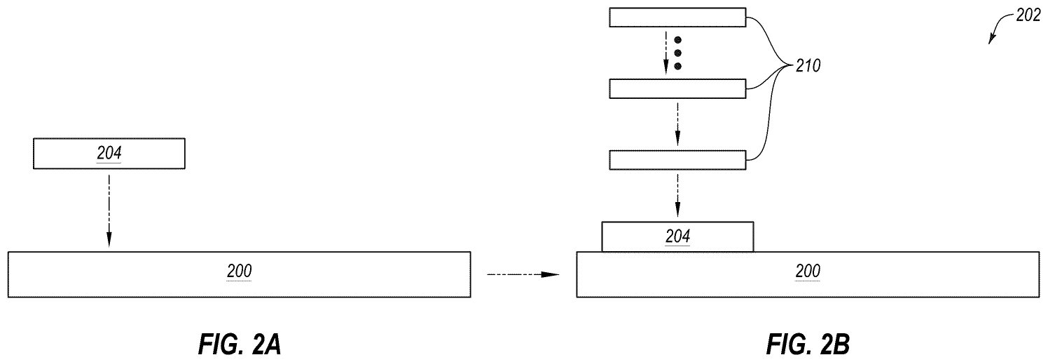

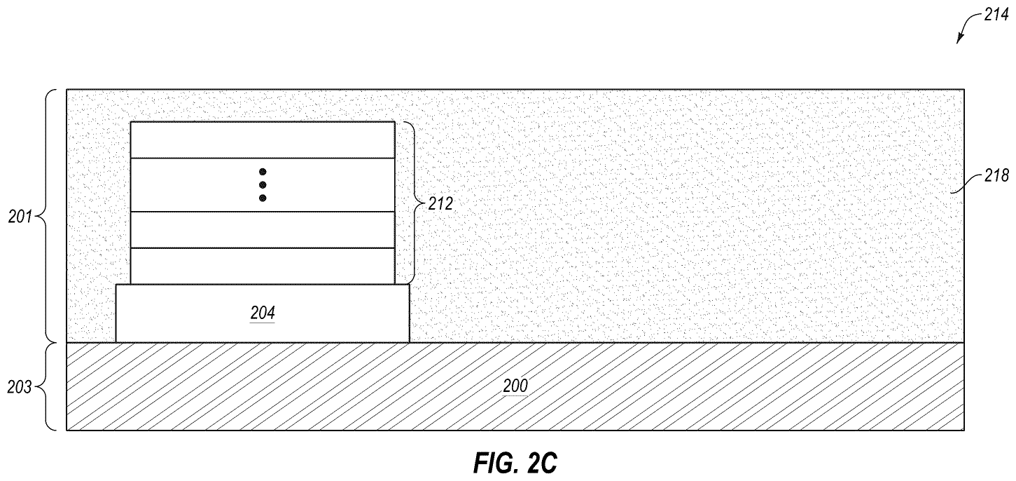

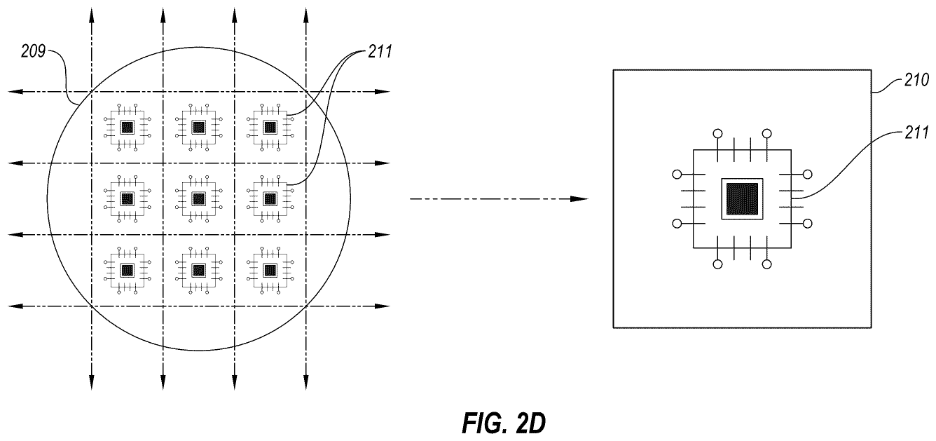

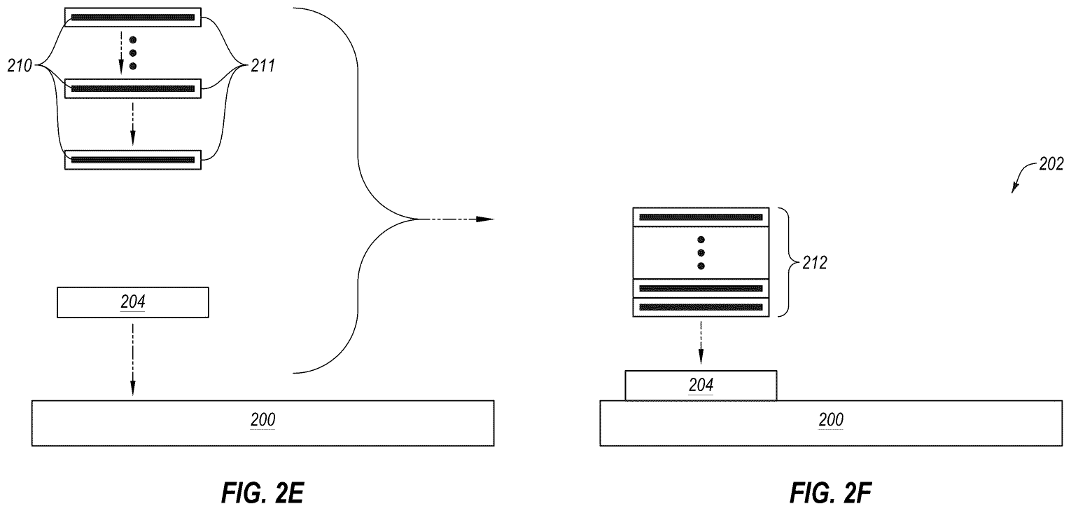

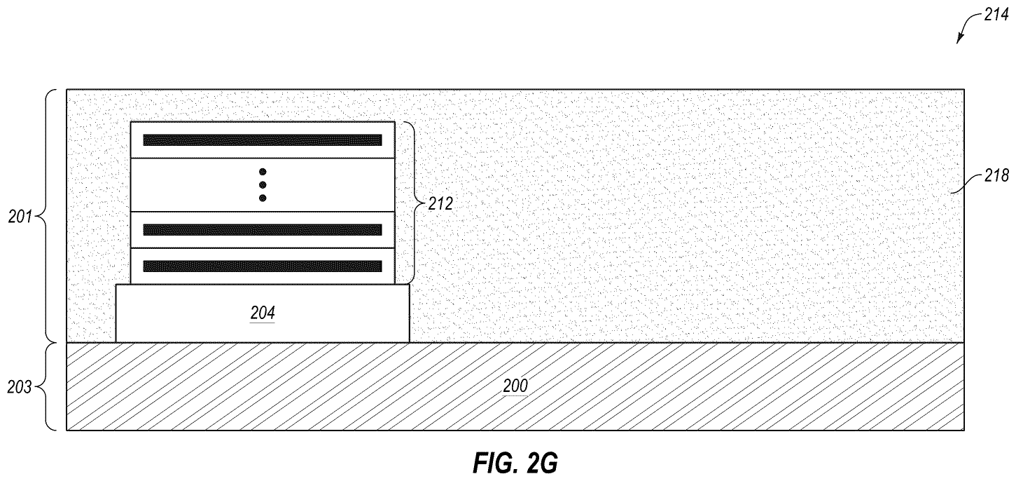

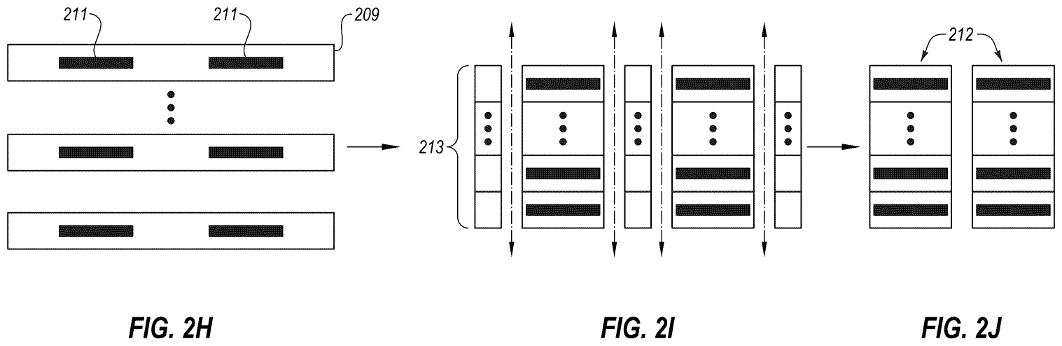

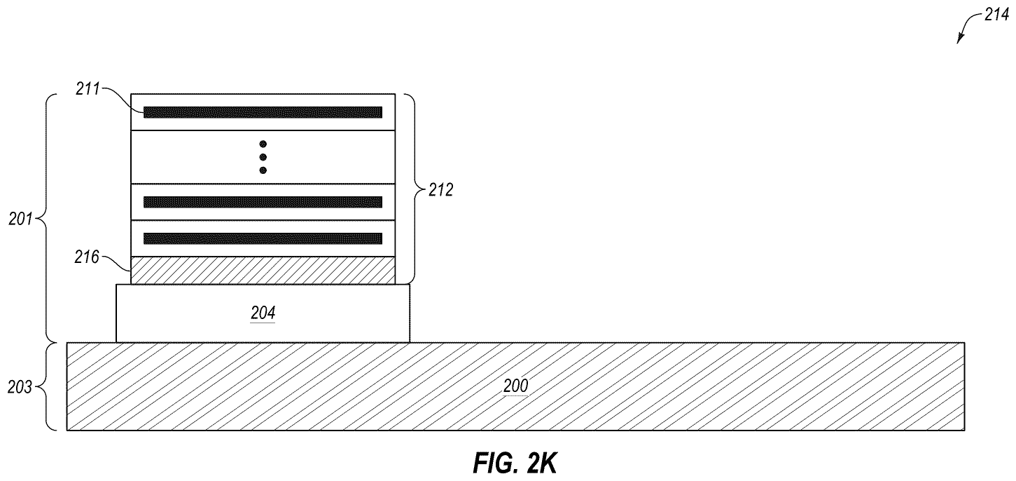

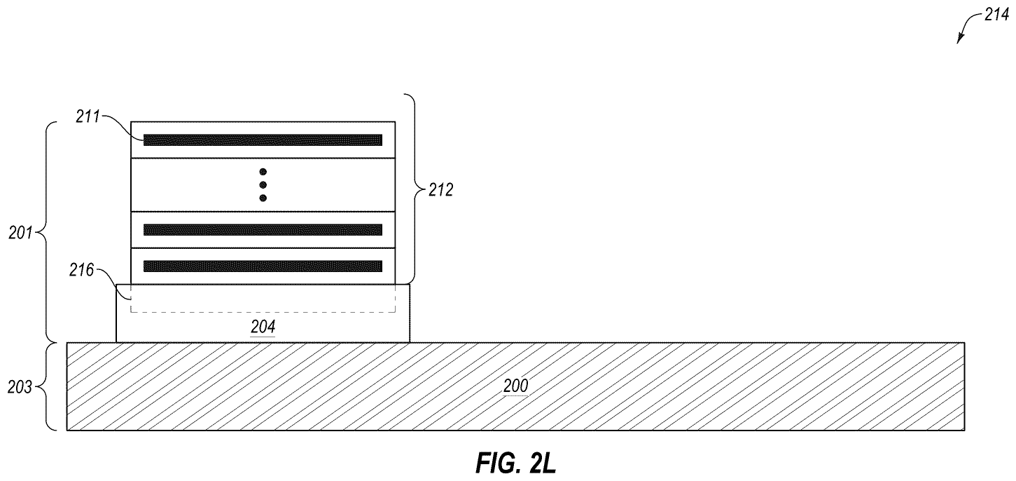

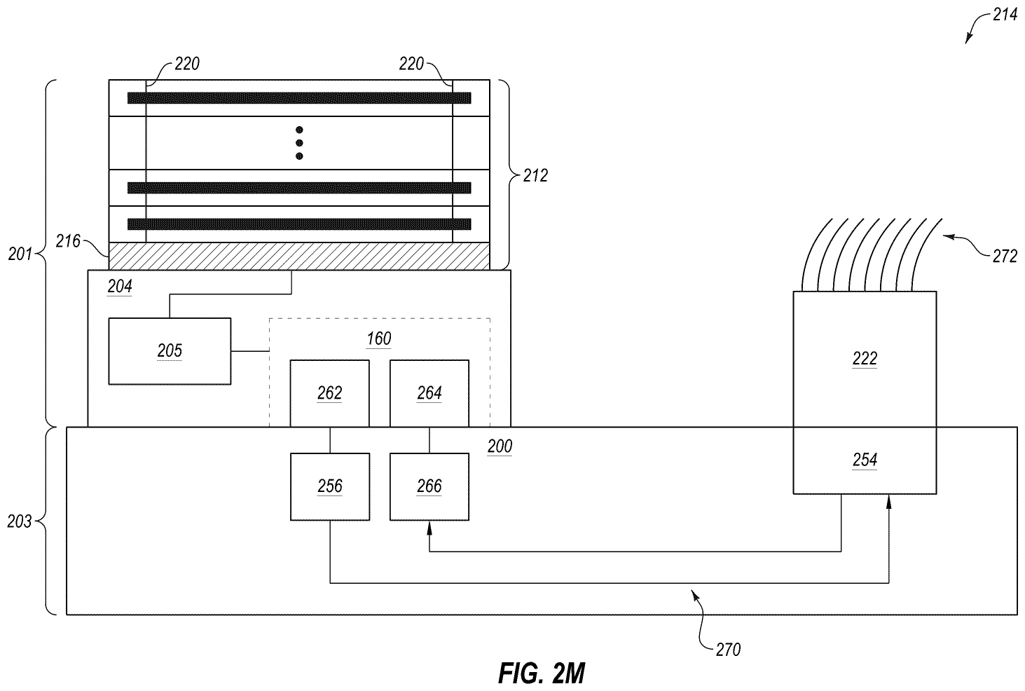

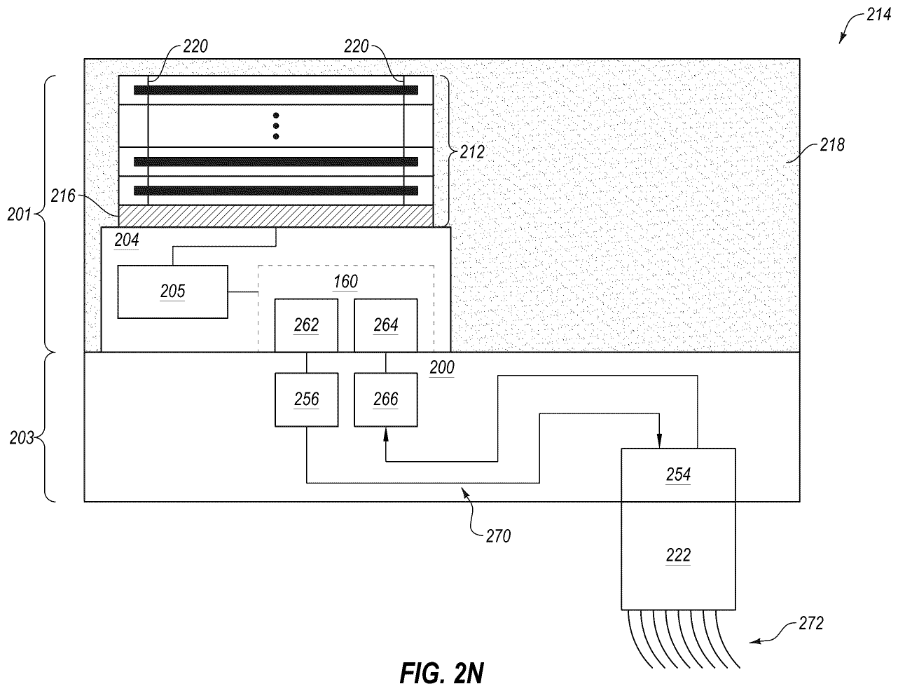

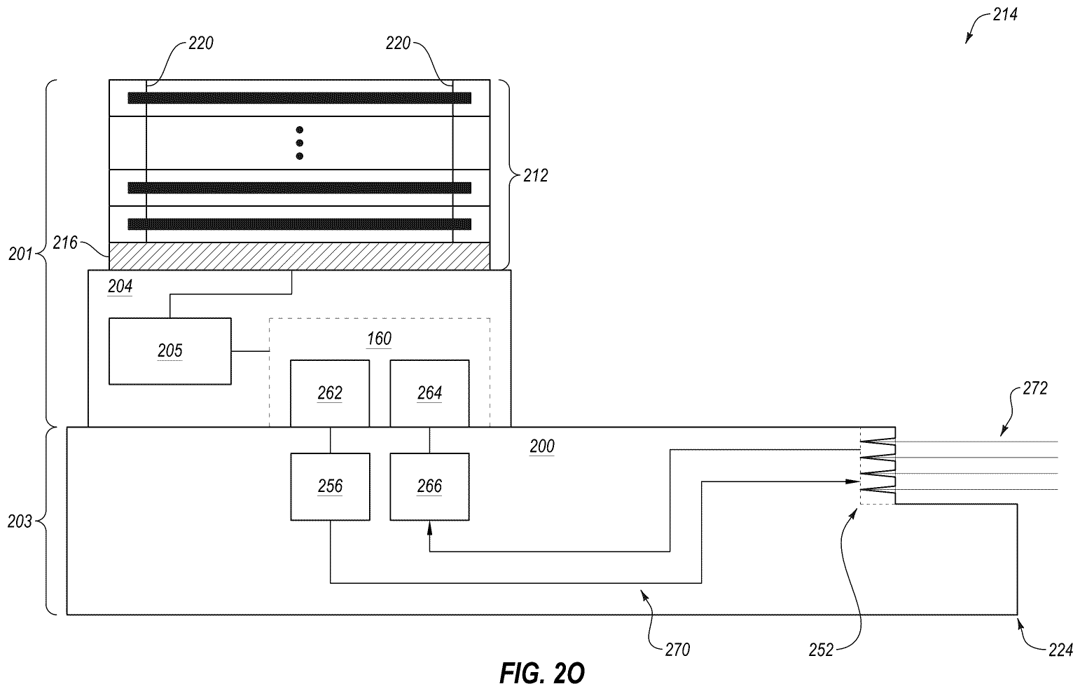

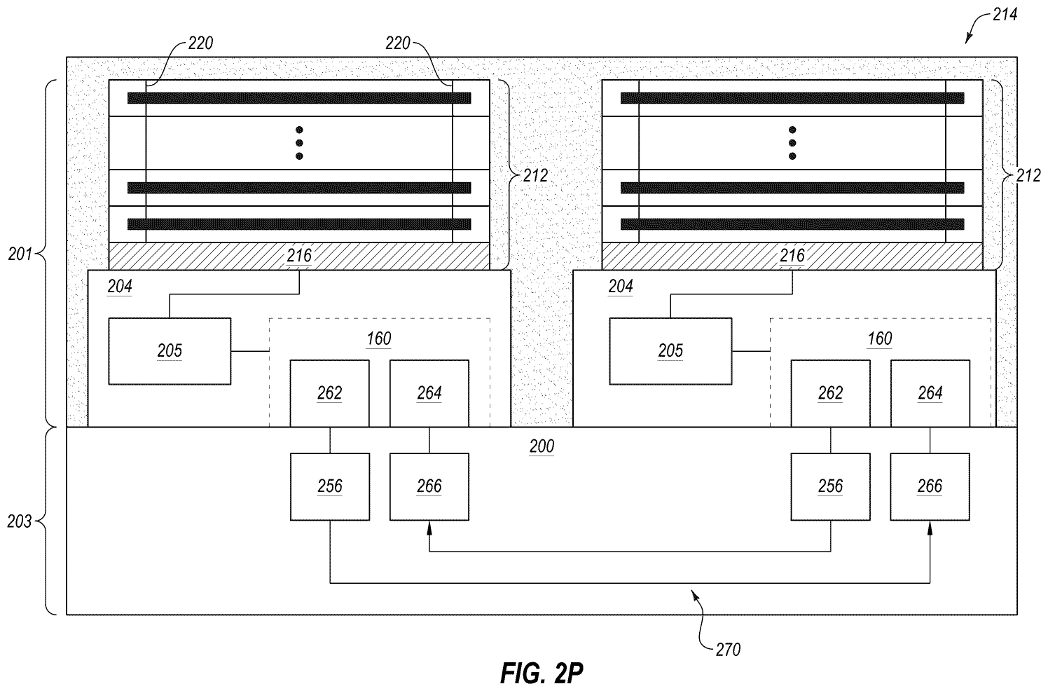

Moving on, the following figures (FIGS. 2A-2P) illustrate a number of example implementations of memory stacks in accordance with one or more embodiments. In some cases, these figures illustrate and are described with respect to components that are labeled using similar (or the same) reference numbers. As an example, several figures from FIGS. 2A-2P illustrate a PIC with a designation of “200,” which may be indicative of similarities between the various PICs, while not requiring that each PIC of each figure be the same embodiment and/or include the same features. Indeed, the similarity of numbering in not intended to limit the scope of any of these individual components (e.g., PICs or other components having the same or similar numbering) to the individual examples. Rather, as will be discussed below, while similar reference numbers may refer to similarly named components (e.g., PICs, EIC dies), each of the components in the respective figures may be directed to different embodiments of a memory circuit in which the similarly labeled components have different features and functionalities. For example, where one PIC may have an optical region on a top surface, another PIC may have an optical region on a side surface or a bottom surface (or a combination of multiple surfaces). Thus, while one or more of the components may be labeled using the same number, each of the components as they appear in respective illustrated examples may have the same or different features than similarly labeled components in other illustrated examples. Moreover, features of any individual or combination of components described in connection with one embodiment may apply to similar components shown in other embodiments.

With reference now to FIGS. 2A-2C, these figures illustrate an example of creating a memory stack 212 on a base circuit package 202 to generate a memory circuit package 214, according to embodiments of the present disclosure. For example, as shown in FIG. 2A, an EIC die 204 may be positioned on, connected to, and bonded to a PIC 200. The EIC die 204 may be a die, chip, chiplet, wafer, or other structure having one or more electronic components (e.g., hardware components) included thereon as described herein. The PIC 200 may be a wafer, such as a whole or uncut wafer, or may be a portion of a larger wafer structure, such as has been cut or diced therefrom. The PIC 200 may be representative of any base, substrate, semiconductor, interposer, etc., upon which one or more die components can be disposed. In some cases, the PIC 200 is larger (e.g., has one or more dimensions larger than) the EIC die 204, or the PIC 200 and the EIC die 204 may be substantially the same size.

The EIC die 204 and PIC 200 may be in accordance with the EIC dies, PICS, wafer, etc., as described below in connection with FIGS. 10A-12D. For example, the EIC die 204 may include one or more electronic hardware components for performing computing, memory, storage, and other functions, and may include electronic transceiver components (e.g., an AMS block). The PIC 200 may include various photonic components for facilitating communication of the EIC die 204 by photonic signals. For instance, the PIC 200 may include photonic transceiver components which may couple to electronic transceiver components (e.g., in the EIC die 204) to facilitate photonic communication, waveguides for directing photonic signals, and photonic interface components for facilitating off-chip communication.

In one or more embodiments describer herein, this transceiver that spans between the PIC 200 and EIC die 204 may be referred to as electrical portion(s) and optical portion(s) of an electro-photonic transceiver. For instance, in one or more embodiments, a first die or first die layer (e.g., the EIC die 204 or EIC layer) includes an electrical portion of an electro-photonic transceiver (e.g., stacked below a logic buffer) while a second die or second die layer (e.g., the PIC 200 or PIC layer) includes an optical portion of the electro-photonic transceiver. Each of the respective portions may include components therein, which will be discussed in further detail herein, and more particularly in connection with FIGS. 10A-12D.

With reference now to FIG. 2B, a plurality of memory hardware dies 210 (e.g., memory layers) may be disposed on a top surface of the EIC die 204. The memory hardware dies 210 may be dies or layers (e.g., discrete chips diced from a larger wafer structure) having memory hardware components 211 thereon. Thus, in one or more embodiments described herein, the memory hardware dies 210 may refer to the layer inclusive of the substrate material as well as any hardware components 211 on which memory resources are formed, layered, or otherwise implemented. For example, in some cases the memory hardware dies 210 have one or more arrays of DRAM hardware included thereon that provide functionality of the memory resource(s).

The memory hardware dies 210 may be stacked on top of one another to form a plurality of layers. For example, in some cases the memory hardware dies 210 are stacked in as many as 4, 6, 8, 10, 16, 20, or 24 layers. In other examples, any number of layers of the memory hardware dies 210 may be stacked in accordance with the techniques described herein. For example, a first or bottom layer of the memory hardware dies 210 may be positioned on the EIC die 204, after which a next memory hardware die 210 may be stacked on the first memory hardware die 204, and so on for each of the layers. In this way, a memory stack 212 (FIG. 2C) may be generated by layering each discrete die on top of one another to form the memory stack 212 including multiple dies in electrical communication with the EIC die 204.

The memory hardware dies 210 may be stacked with each layer connected and bonded to each adjacent layer. For example, the layers of the memory hardware dies 210 may be connected and bonded in a dense and/or tight packaging, with little space between layers. For instance, the memory hardware dies 210 may be connected to one another through hybrid bonding techniques. To elaborate, in various embodiments described herein, hybrid bonding may refer to wafer-to-wafer, die-to-die, or die-to-wafer bonding that facilitates direct copper-to-copper (Cu-to-Cu) and/or dielectric-to-dielectric bonding without using solder. For instance, dies and/or wafers are precisely aligned (e.g., with sub-micron precision) and annealed to create a bond at a molecular level, eliminating the need for solder and other bonding techniques. In this way, hybrid bonding may achieve high-density, low-resistance interconnections having a fine pitch and minimal gaps. In some cases, other bonding and/or interconnection techniques may be utilized for connecting one or more of the layers of the memory hardware dies 210.

As shown in FIG. 2C, based on depositing the layers of the memory hardware dies 210, a memory stack 212 may be generated on the base circuit package 202 at the top surface of the EIC die 204. The memory stack 212 may be physically connected to the EIC die 204, and be may electronically coupled to hardware components of the EIC die 204. For instance, a logic buffer may be connected to the memory stack 212 and to the EIC die 204 and may facilitate accessing the memory stack 212, as described in connection with FIGS. 2K and 2L. In this way, a memory circuit package 214 may be generated having the EIC die 204 disposed on the PIC 200, and the memory stack 212 formed on the EIC die 204. In some cases, an overmold 218 may be applied to the memory circuit package 214 to create an overmolded circuit package. For example, a molding compound may be disposed on and over exposed top surfaces of the PIC 200, the EIC die 204, and the memory stack 212, which, when dried or cured, may produce the overmold 218. The overmold 218 may facilitate maintaining the various components and/or dies in place and strengthening the circuit package, among other functions.

FIG. 2D illustrates an example of generating one or more memory hardware dies 210 from a memory hardware wafer 209, according to embodiments of the present disclosure. The memory hardware wafer 209 may be a substrate (e.g., silicon), wafer, structure, or other medium upon which one or more memory hardware components 211 may be positioned. For example, the memory hardware components 211 may be one or more discrete hardware components of any type of memory hardware. As mentioned above, in come cases the memory hardware is DRAM memory hardware. The memory hardware components 211 may be positioned on the memory hardware wafer 209 in one or more discrete regions or localized areas. For example, the memory hardware components 211 may be arranged in a grid or other pattern.

As shown, based on the arrangement of the memory hardware components 211 on the memory hardware wafer 209, the memory hardware wafer 209 may be cut, diced, singulated, or otherwise sectioned in order to cut, isolate, or singulate discrete memory hardware dies 210 from the memory hardware wafer 209. For example, each of the memory hardware dies 210 may have one, or multiple, memory hardware components 211 thereon. As mentioned in relation to one or more embodiments herein, the memory hardware components 211 on a memory hardware die 210 may serve as memory resources for a discrete layer of a memory stack. For instance, the memory hardware components 211 of one memory hardware die 210 may be configured to connected or couple to the memory hardware components 211 of another memory hardware die 210 based on stacking the memory hardware dies 210 to align and/or connect the memory hardware components 211. In this way, one or more memory hardware dies 210 may be generated for utilizing in accordance with one or more of the embodiments described herein.

Turning now to FIGS. 2E-2G, these figures illustrate an example of creating a memory stack 212 and positioning the memory stack 212 on a base circuit package 202 to generate a memory circuit package 214, according to embodiments of the present disclosure. As shown, an EIC die 204 may be positioned on, connected, to, and bonded to a PIC 200. The EIC die 204, the PIC 200, and the bonding thereof may be similar to one or more other embodiments described herein. In this way, a base circuit package 202 may be formed from the EIC die 204 and PIC 200, which may be, for example, a circuit package having any of the features and functionality as described below in connection with FIGS. 10A-12D.

In the example of FIGS. 2E-2G, a memory stack 212 may be generated separate and/or independent of the base circuit package 202. For instance, a plurality of memory hardware dies 210 may be disposed, layer by layer, on top of one another to form a memory stack 212 of a plurality of layers of the memory hardware dies 210. In this instance, the memory stack 212 may be generated on another substrate, base, support, or structure that is not the EIC die 204. For example, rather than depositing the layers of memory hardware dies 210 layer by layer on the EIC die 204 to form the memory stack 212 thereon, the memory stack 212 may be (e.g., first) formed at a separate location from the EIC die 204. After being formed, the memory stack 212 may be disposed, positioned, and connected to the EIC die 204, as shown in FIG. 2F. In this way, the base circuit package 202 and the memory stack 212 may be separately formed components, which may be brought together and joined to form the memory circuit package 214. In some cases, a molding compound may be disposed on and over exposed top surfaces of the PIC 200, the EIC die 204, and the memory stack 212 to produce an overmold 218.

Generating the memory stack 212 separately from the base circuit package 202 may provide benefits for creating memory circuit packages. For example, by producing the memory stack 212 separate from the EIC die 204, memory stacks may be generated in mass for later connecting the base circuit packages to form memory circuit packages as described.

FIGS. 2H-2J illustrate an example of generating memory stacks 212 from memory hardware wafers 209, according to embodiments of the present disclosure. As mentioned above, the memory hardware wafers 209 may include memory hardware components 211 positioned thereon, such as DRAM or other memory hardware. The memory hardware components 211 may be positioned on the memory hardware wafers 209 in discrete, localized areas or regions. As shown in FIGS. 2H and 2I, the memory hardware components 211 are positioned in 2 discrete regions (e.g., for generating 2 memory stacks 212), but it should be understood that the memory hardware components 211 may be positioned in any number of discrete regions (e.g., for generating a corresponding number of memory stacks 212). For instance, in some cases, the memory hardware wafer 209 may be configured with a grid or other pattern having tens or hundreds or more discrete regions of the memory hardware components 211.

Multiple layers of the memory hardware wafers 209 may be stacked (and bonded) on top of one another to form a memory hardware wafer stack 213. For instance, the memory hardware wafer stack 213 may include as many as 4, 6, 8, 10, 16, 20, or 24 layers, or other quantity in accordance with the techniques described herein. Based on stacking the memory hardware wafers 209, the memory hardware components 211 of each layer may align and/or may stack on top of one another. For instance, as mentioned above, the memory hardware components 211 (e.g., within the same discrete region) may be configured to connect and electronically couple to the memory hardware components 211 of adjacent layers. In this way, the memory hardware wafer stack 213 may include a plurality of memory stacks 212 formed therein, based on the memory hardware components 211 of each layer aligning with one another. The memory hardware wafer stack 213 may then be diced, cut, or separated in order to generate discrete memory stacks 212 having the plurality of layers corresponding with the memory hardware wafer stack 213. Accordingly, the memory stacks 212 may be utilized in connection with any of the techniques described herein for connecting memory stacks to base circuit packages, such as that described in connection with FIGS. 2E to 2G.

Accordingly, the techniques shown and described in connection with FIGS. 2A-2C and/or FIGS. 2E-2G may facilitate generating a memory circuit package 214 having a memory stack 212 positioned on the EIC die 204 and coupled thereto. The memory stack 212 being directly connected to the EIC die 204 may facilitate a direct connection and/or access of memory hardware resources by the hardware components of the EIC die 204. For example, the EIC die 204 may utilize the memory resources of the memory stack 212 for performing one or more computing functions. In some cases, these memory resources may be local to the EIC die 204 and may facilitate the EIC die 204 having access to more memory resources, for example, as opposed to sharing a common pool of memory resources among several EIC dies 204. In some cases, the memory resources of the memory stack 212 may be accessible to one or more other devices, such as other EIC dies, which may provide a larger pool of available resources for a system of many EIC dies or other processing units.

The memory stack 212 being positioned on top of the EIC die 204 may also achieve a more efficient use of the real estate available on the base circuit package 202. For example, in many conventional chip layouts, memory resources are configured to occupy their own footprint on the PIC 200, which may prevent other EIC dies (or other components) from being positioned in the same position over the PIC 200. By positioning the memory stack 212 on top of the EIC die 204, the memory stack 212 may share a footprint with the EIC die 204 on the PIC 200, optimizing the available space on the circuit package. As such, more of the real estate of the PIC 200 may be utilized for other electrical components that provide a variety of functionalities. Thus, one or more embodiments of the memory stack 212 as described herein may facilitate more densely or tightly populating a PIC with dies or other components, while also providing a more direct access to a larger, more robust collection of memory resources at each EIC die.

Turning now to FIGS. 2K and 2L, these figures illustrate examples of a logic buffer 216 in relation to the memory stack 212, according to embodiments of the present disclosure. The logic buffer 216 may be a circuit and/or hardware component which may facilitate a connection of the memory stack 212 with the EIC die 204 and communication therebetween. For example, the logic buffer 216 may provide access for the hardware components of the EIC die 204 to access the memory resources (e.g., memory hardware components 211) of the memory stack 212. In one or more embodiments, the logic buffer 216 is an interface die, base die, component, or chip which manages communication between the memory hardware dies 210 and one or more components of the EIC die 204 (e.g., a processor, memory controller, etc., of the EIC die 204).

As an illustrative example, the logic buffer 216 may include circuitry for data routing and signal management, such as for distributing read/write commands and data between the EIC die 204 and the memory hardware dies 210, reducing signal congestion and improving efficiency. The logic buffer 216 may provide a physical layer interface for the memory hardware die 210 for managing electrical signaling, timing, synchronization, and power management. For example, the logic buffer 16 may synchronize operations across memory layers, regulate power and thermal performance, and ensure reliable data transmission in order to facilitate high-speed communication with the memory stack 212. In some cases, the logic buffer 216 may facilitate organizing memory access and managing address schemas, implement error or other integrity-checking mechanisms, or other functionalities. In this way, the logic buffer 216 may facilitate efficient memory access of the memory stack 212, ensuring low latency and high throughput.

As shown in FIG. 2K, in some cases the logic buffer 216 may be included as part of the memory stack 212. For instance, the logic buffer 216 may be implemented as a logic buffer die which may be a bottom or base layer of the memory stack 212. To elaborate, when forming the memory stack 212 (e.g., in any of the manners described herein) the logic buffer 216 may be deposited (e.g., as a logic buffer die) as a first or bottom layer of the memory stack 212. In some cases (e.g., FIGS. 2A-2C) the logic buffer 216 may be deposited as a first layer directly on the EIC die 204, and the layers of memory hardware dies 210 may be deposited on the logic buffer die 216. In other examples, (e.g., FIGS. 2E-2G) the logic buffer 216 may be deposed as a first layer in the process of creating the memory stack 212 separate or independent of the EIC die 204. For instance, the logic buffer 216 may be a first or bottom die upon which several layers of memory hardware dies 210 may be stacked and connected to form a memory stack 212 having the logic buffer 216 as a base or bottom layer. In another example (e.g., FIGS. 2H-2J), a logic buffer wafer (e.g., having logic buffer componentry at multiple discrete regions) may be a bottom or base wafer upon which various memory hardware wafers 209 may be disposed and bonded thereto to form a memory hardware wafer stack 213 for dicing to generate discrete memory stacks 212 each having a logic buffer 216 as a bottom or base layer. Accordingly, the memory stack 212 may be physically connected, and electronically coupled, to the EIC die 204 via the logic buffer 216 a base or bottom layer of the memory stack 212.

As shown in FIG. 2L, in other cases, the logic buffer 216 may be implemented as part of the EIC die 204. For example, the logic buffer 216 may be representative of a capability or functionality of the (e.g., hardware components of the) EIC die 204 for operating as a logic buffer 216. For instance, the logic buffer 216 may not necessarily be a physical or discrete die, layer, or component, but rather, the functionality of the logic buffer 216 may be implemented via the various components and functionalities of the EIC die 204. In this way, the memory stack 212 may not, in some cases, include a layer being the logic buffer 216, but rather, the memory hardware dies 210 of memory stack 212 may be directly positioned and connected to the top of the EIC die 204.

FIGS. 2M-2O illustrate examples of the memory circuit package 214 having various interface configurations that facilitate off-chip photonic communication, according to embodiments of the present disclosure. As mentioned above, a base circuit package comprising the EIC die 204 positioned on and connected to the PIC 200 may include the features and functionalities of the electro-photonic circuit packages as described in connection with FIGS. 10A-12D For instance, the EIC die 204 may include hardware components 205 which may include processing components, memory components, storage components, routing components, communication components, or other functional hardware components. The hardware components 205 may interface with an AMS block 160, which may include electronic transceiver components, such as a modulator driver 262 and a TIA 264. These electronic transceiver components may connect to and interface with photonic transceiver components in the PIC 200, such as a MOD 256 and a PD 266. In some cases, one or more of the electronic transceiver components (e.g., illustrated as pertaining to the AMS block 160) may be implemented in the PIC 200. For example, one or more of the modulator driver 262 or the TIA 264 may be located in the PIC 200, and the hardware components 205 may connect to these components in the PIC 200. Accordingly, the hardware components 205 may send and receive signals in the photonic domain.

The hardware components 205 may be connected to the memory stack 212 via the logic buffer 216. For example, the memory stack 212 may include one or more electrical interconnects 220 which may pass therethrough and which may connect to each memory hardware die of the memory stack 212. For example, as mentioned above, the memory stack 212 may be generated based on hybrid bonding techniques, which may facilitate electrically coupling the various layers and establishing the electrical interconnects 220 therebetween. Thus, the logic buffer 216 may connect to the memory hardware dies of the memory stack 212 via the electrical interconnects 220, and may facilitate access to the memory stack 212. Accordingly, the hardware components 205 may connect to and may access the memory resources of the memory stack 212. While the logic buffer 216 is shown in FIGS. 2M-2O as a discrete layer or die of the memory stack 212 upon which the memory hardware dies 210 are stacked, it should be understood that in some cases the logic buffer 216 may not be a physical layer of the memory stack 212, but rather, may be implemented as built-in or native functionality of the EIC die 204, such as that shown and described in connection with FIG. 2L above.

In some cases, the memory circuit package 214 is equipped with an optical region 254, which may be a region of the PIC 200 configured such that photonic signals (e.g., light) may pass (e.g., enter and/or exit) through a surface of the PIC 200 through the optical region. In some cases, the optical region 254 may include one or more grating couplers. In the example shown in FIG. 2M, the optical region 254 may be located at or near a top surface of the PIC 200. For instance, the optical region 254 may be optically accessible at or through the top surface of the PIC 200 such that photonic signals may pass through the top surface of the PIC 200 at the optical region 254. In the example shown in FIG. 2N, the optical region 254 may be located at or near a bottom surface of the PIC 200. For instance, the optical region 254 may be optically accessible at or through the bottom surface of the PIC 200 such that photonic signals may pass through the bottom surface of the PIC 200 at the optical region 254.

The EIC die 204 may be coupled to the optical region 254 to facilitate transmitting and receiving signals to and from the components within the EIC die 204. For example, the MOD 256 and PD 266 may each be connected to the optical region 254 by waveguides 270, which may direct the flow of photonic signals through the substrate of the PIC 200 to (or from) the optical region 254 (and through the top or bottom surface of the PIC 200). The driver 262 and TIA 264 being coupled to the MOD 256 and PD 266, respectively, may communicate corresponding electronic signals with the hardware components 205. In this way, the EIC die 204 may be photonically coupled to the optical region 254 for sending and receiving photonic signals to/from the optical region 254. For instance, the memory stack 212 may be accessible via photonic communications through the optical region 254.

The optical region 254 may be capable of coupling with an optical interface component 222, such as a fiber array unit. For example, the optical interface component 222 may couple to the optical region 254 at the top surface of the PIC 200 (FIG. 2M) or at the bottom surface of the PIC 200 (FIG. 2N). The optical interface component 222 coupling to the optical region may refer to the optical interface component 222 being optically connected to the optical region 254 such that photonic signals may be transmitted therebetween. For example, the optical interface component 222 may couple one or more fibers with waveguides formed within the PIC 200 via the optical region 254.

In one or more embodiments, the optical interface component 222 may directly connect to or contact the optical region 254. In other examples, the optical interface component 222 may couple to the optical region 254 through one or more additional components or blocks, such as through one or more optically transparent blocks or glass substrates. For instance, where a glass or optically transparent block is positioned over the optical region 254, an optical interface component 222 may be placed over the optically transparent block such that light passing between the optical region 254 and the optical interface component 222 enables one or more fibers to be optically coupled to waveguides formed within the PIC 200.

In one or more embodiments, the optical interface component 222 may physically connect to the PIC 200 and/or optical region 254 through an adhesive, through a coupling structure or features, or through any other suitable means. In this way, the optical interface component 222 and optical region 254 may be configured to couple in order to form a photonic interface. In some cases, the optical interface component 222 and the optical region 254 are each photonic interface components, and the coupling thereof forms a photonic interface. In one or more embodiments, the optical interface component 222 is an FAU that aligns and/or couples fibers to the waveguides via the optical region 254.

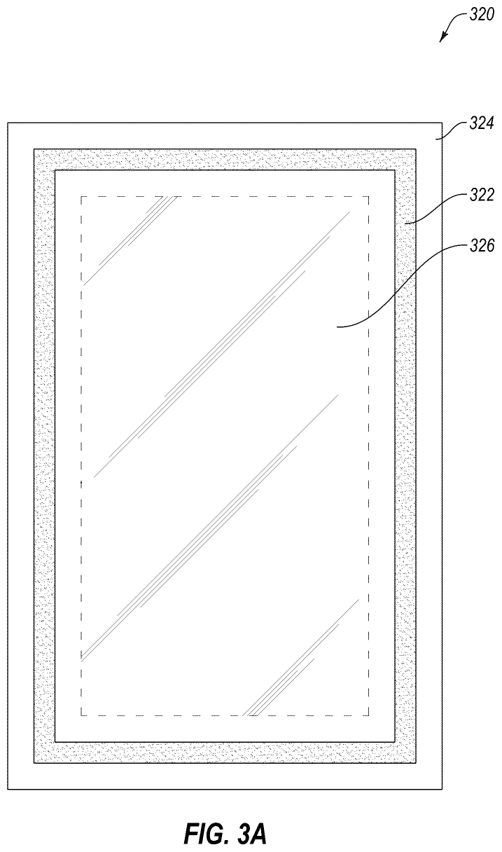

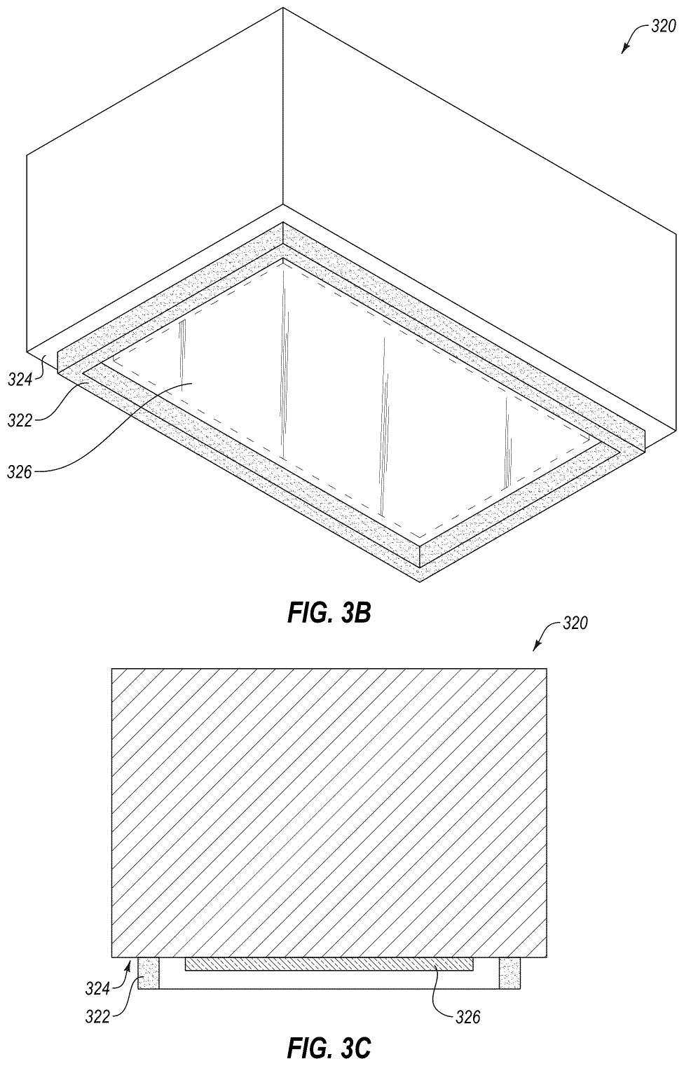

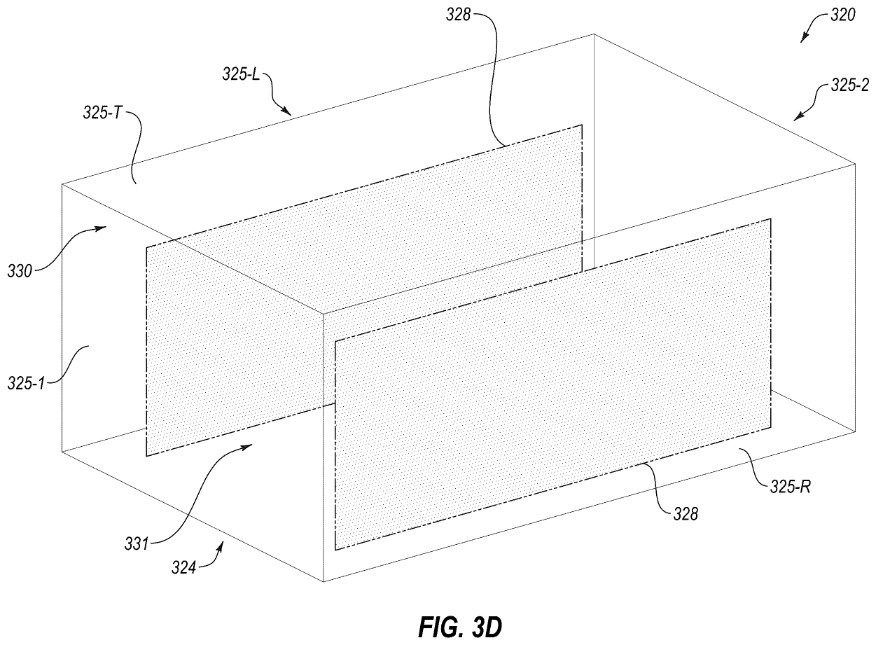

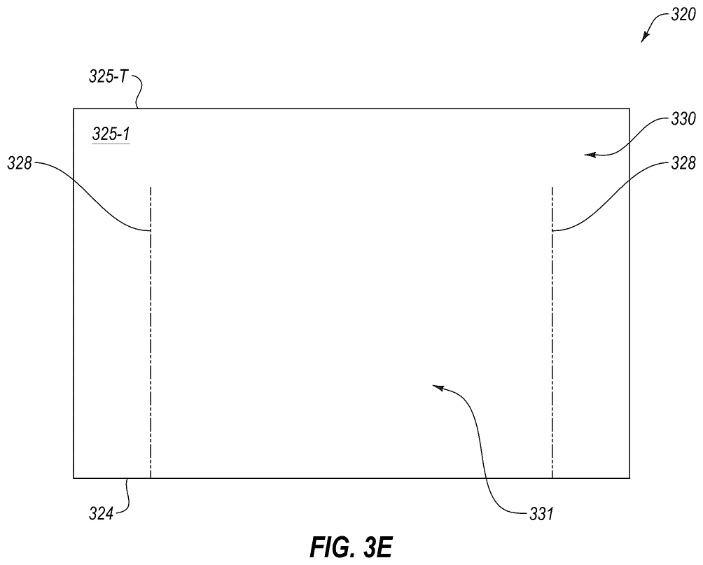

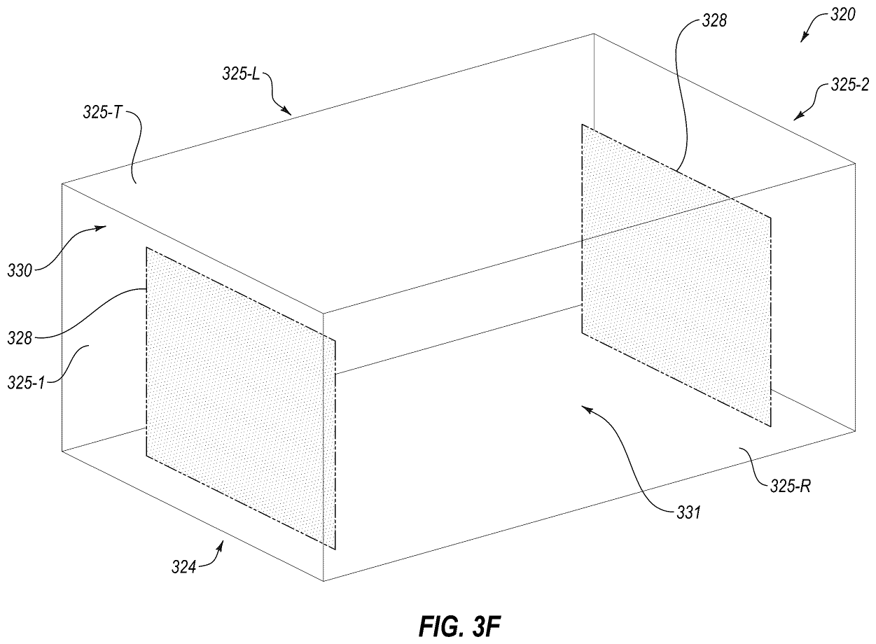

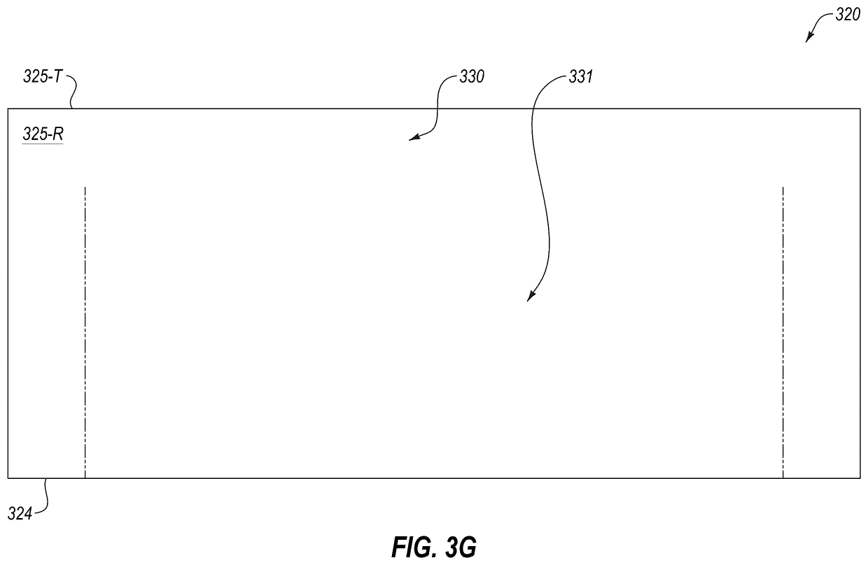

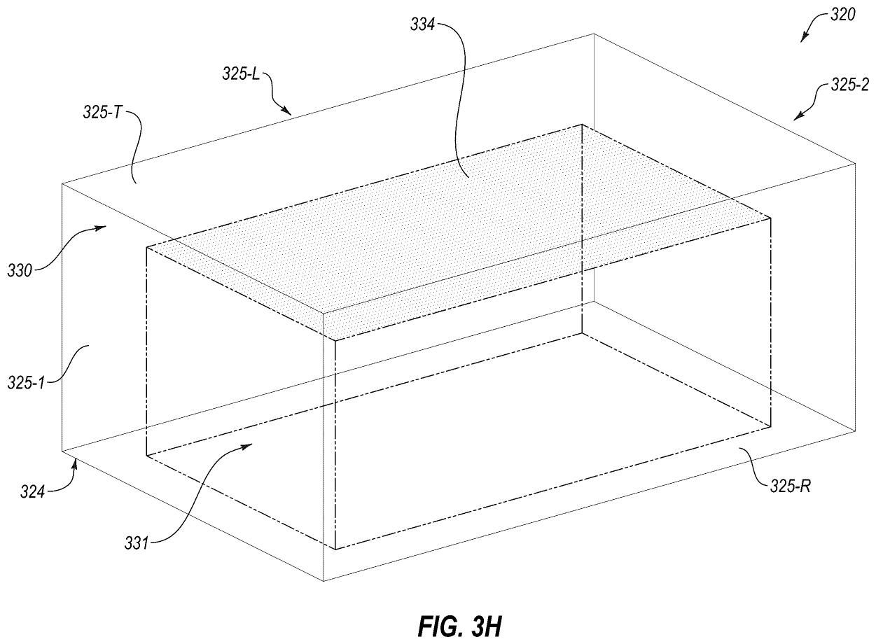

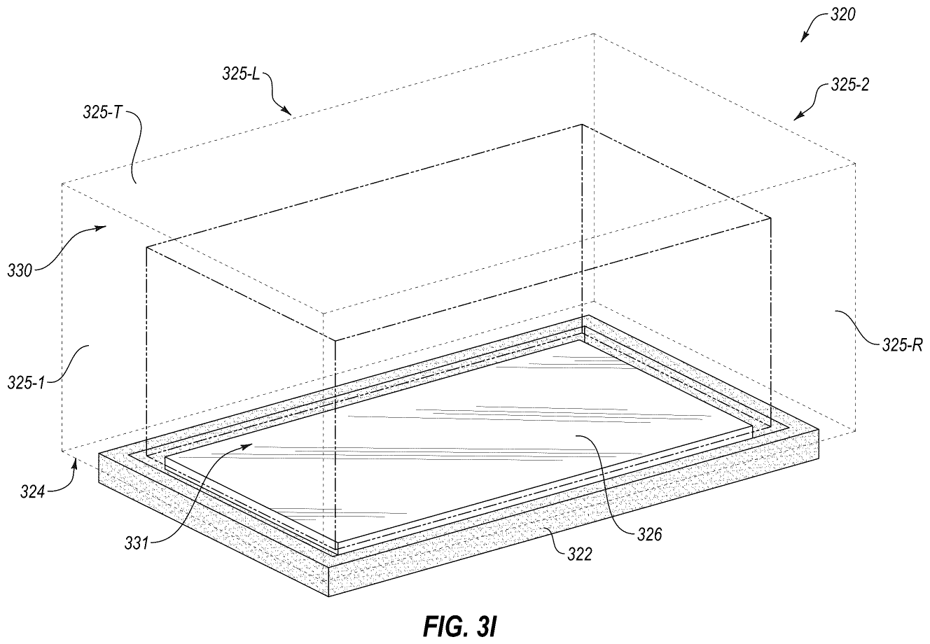

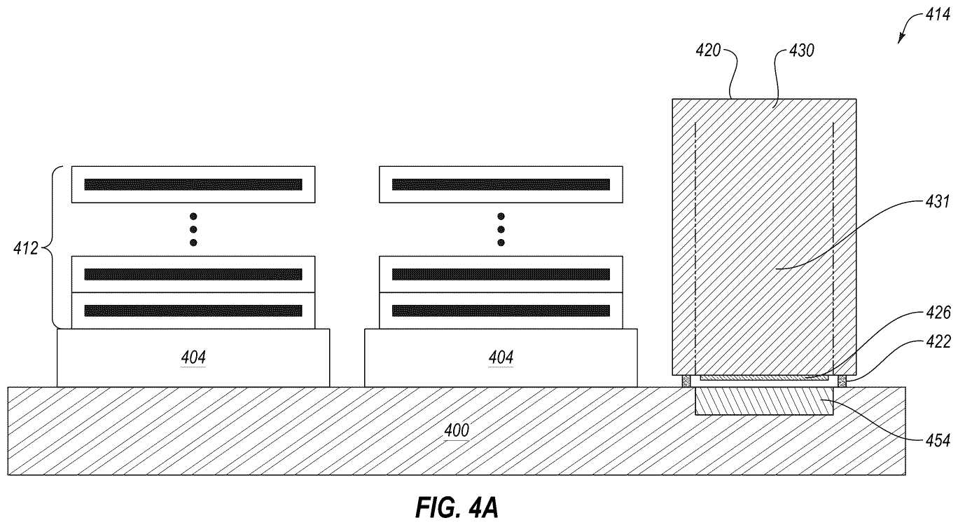

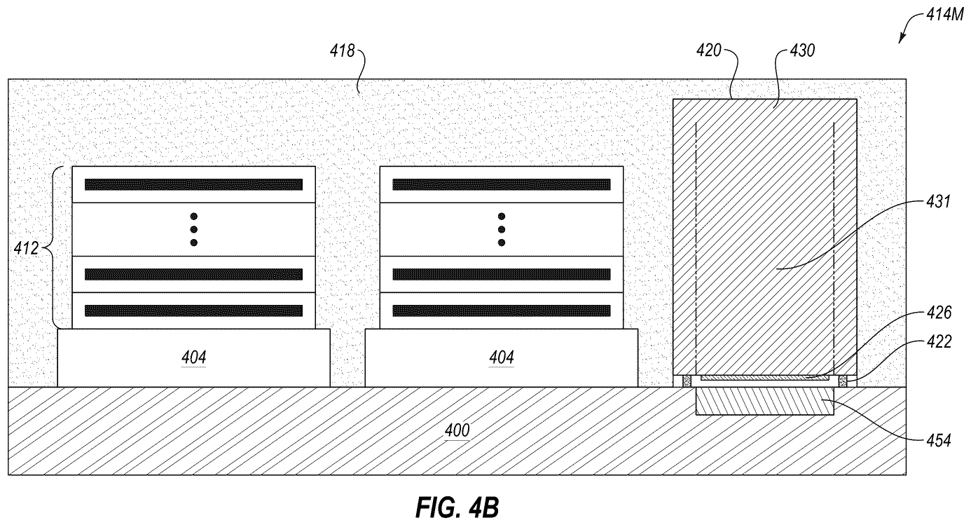

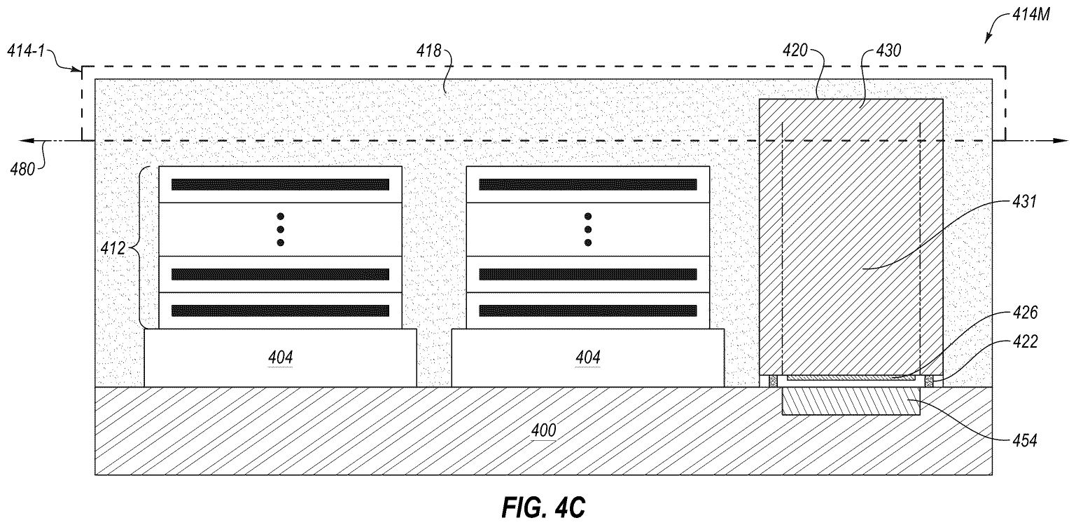

Similar to one or more embodiments described herein, in some cases the memory circuit package 214 may be covered with an overmold, the application of which may tend to cover, block access to, or obscure the optical region 254. In some cases, one or more techniques are implemented for preserving optical access to the optical region 254 through the overmold, such as producing an optical window through the overmold. While the overmold is not shown and described in connection with FIG. 2M, more details are described below in connection with FIGS. 3A-5E related to maintaining optical access to an optical region through an overmold applied to a memory circuit package.

As shown in FIG. 2N, in some cases the optical region 254 may be advantageously provided notwithstanding an overmold 218 covering (e.g., a top of) the memory circuit package 214. For example, while the overmold 218 may typically be disposed on and over the top surfaces of each of the components as shown, by implementing the optical region 254 at, near, or accessible via the bottom surface of the PIC 200, a photonic interface may be formed with the optical region 254 regardless of the overmold 218 covering (e.g., an entirety of) to top surface(s) of the memory wafer package 214. For example, the optical interface component 222 may be coupled to the optical region 254 at the bottom surface of the PIC 200, which bottom surface may remain uncovered after overmolding. In some cases, providing the optical region 254 at the bottom surface of the PIC 200 may be advantageous in that the optical region 254 does not occupy real estate on or at the top surface of the PIC 200. For example, this may facilitate positioning more components on the top surface of the PIC 200, while also providing the optical interface facilitated by the optical region 254.

The optical interface component 222 (in any of the embodiments described herein) may facilitate connecting one or more optical fibers 272 to the optical region 254 for exchanging (e.g., transmitting and/or receiving) optical signals through the optical region 254. As mentioned, the optical region 254 may be photonically coupled to the MOD 256 and the PD 266 via one or more waveguides formed within the PIC 200. The optical interface component 222 may further couple the waveguides 270, via the optical fibers 272, to one or more external devices. In this way, the EIC die 204, via the optical region 254, may be capable of communicating through photonic signals with one or more off-chip devices, such as another EIC die or EIC layer of another circuit package.

Further, the photonic connection of the EIC die 204 with the optical region 254 may facilitate photonic communication with the memory stack 212 to access the one or more memory resources thereon. For example, an off-chip device connected via the optical interface component 222 may send and receive photonic signals to/from the EIC die 204 via the optical region 254, and the EIC die 204 may provide access to the memory stack 212 as described herein. In this way, the memory stack 212 may be directly accessible to the EIC die 204, and additionally, the EIC die 204 (via a photonic connection with the optical region 254) may facilitate photonically communicating with the memory stack 212 by one or more other devices.

As shown in FIG. 2O, in some cases, the memory circuit package 214 is equipped with an optical region 252 on a side surface of the PIC 200. For instance, the optical region 252 may include one or more edge couplers, or other structures for coupling optical fibers at an edge of the PIC 200. Similar to examples described herein, the optical region 252 may be a geometry, structure, or other feature formed in the PIC 200 which may facilitate connecting one or more optical fibers 272 at an edge 224 of the PIC 200. For instance, the edge 224 may be an edge resulting from cutting or dicing the PIC 200. The optical region 252 may be representative a region, structure, or component which may facilitate photonic signals (e.g., light) passing through a side surface of the PIC 200. For example, photonic signals may enter and/or exit the PIC 200 at the edge 224, or another surface proximate or otherwise associated with the edge 224 based on the optical region 252. In a similar way to the optical region 254 as described above, the optical region 252 may facilitate photonic communication with the EIC die 204, including photonic communication with the memory stack 212. For example, the MOD 265 and PD 266 may be optically coupled to the optical region 252 via one or more waveguides 270 formed in the PIC 200 for sending and receiving photonic signals to/from the optical fibers 272 via the optical region 252.

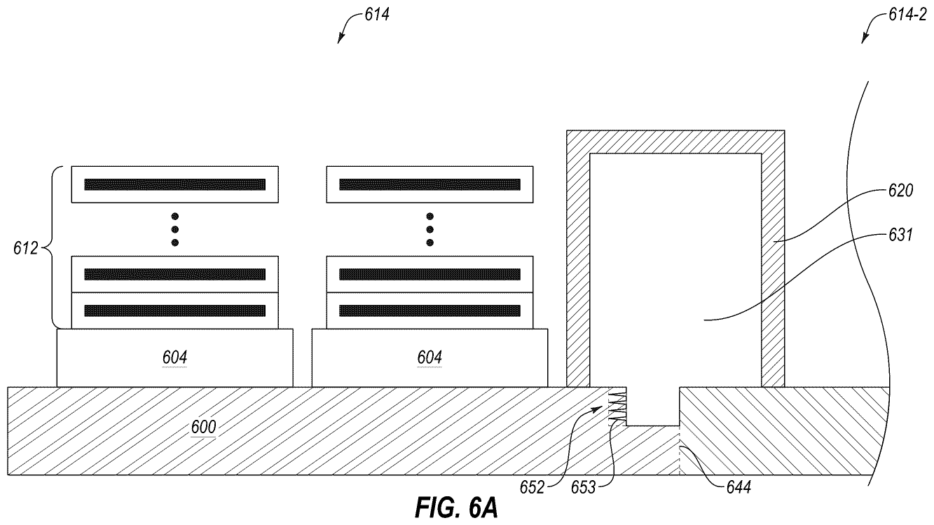

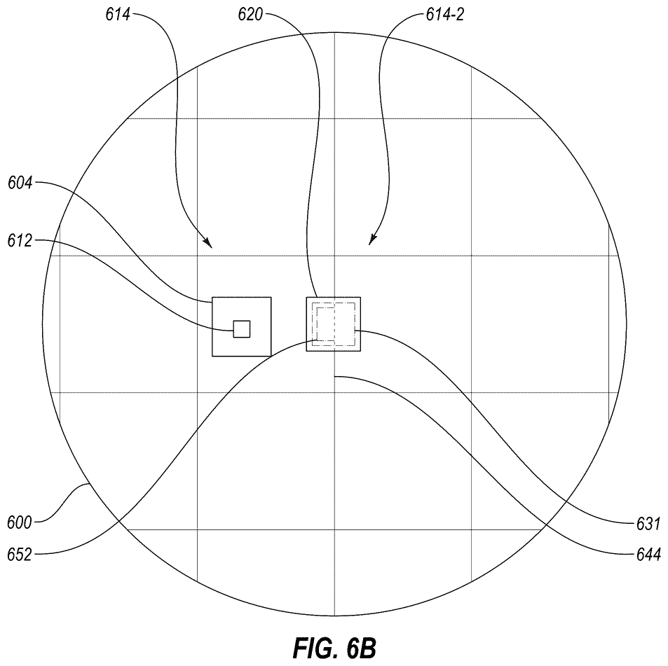

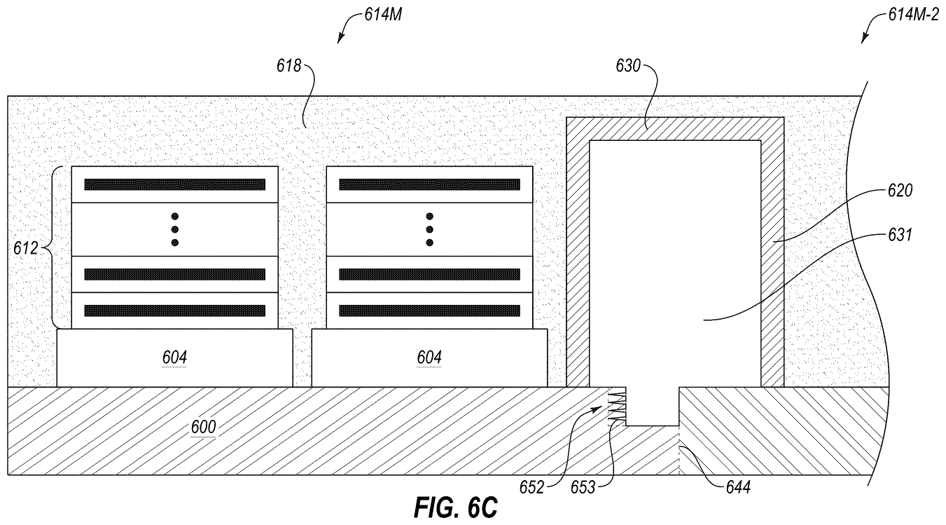

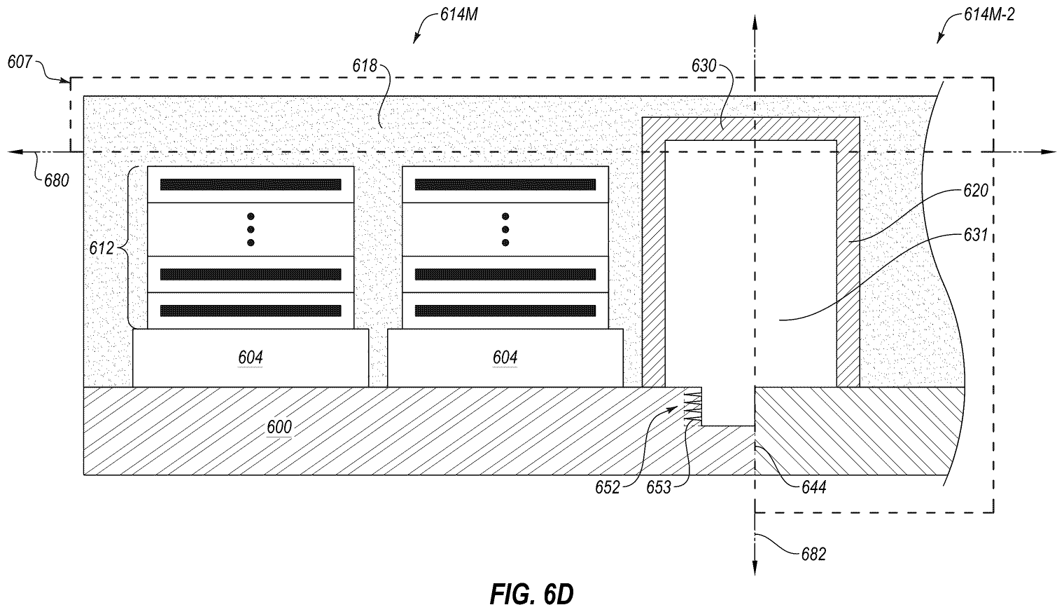

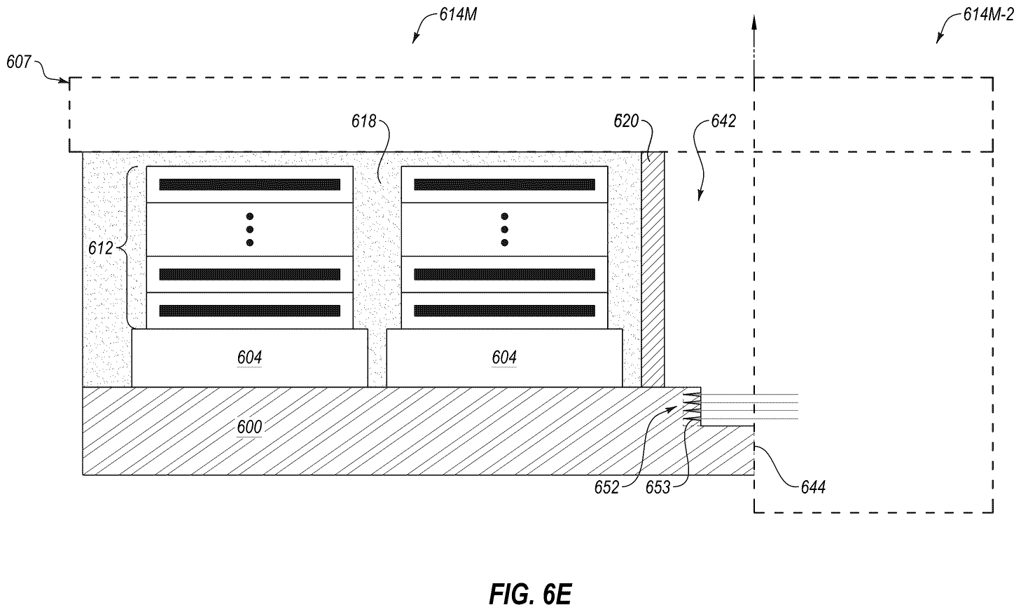

As described herein, in some cases the memory circuit package 214 may be covered with an overmold, the application of which may tend to cover, block access to, or obscure the optical region 252. In some cases, one or more techniques are implemented for preserving optical access to the optical region 252 through the overmold, such as producing an optical window through the overmold. While the overmold is not shown and described in connection with FIG. 2O, more details are described below in connection with FIGS. 6A-6E related to maintaining optical access to optical regions (e.g., specifically those positioned at or near an edge of a wafer such as edge couplers) through an overmold applied to a memory circuit package.

FIG. 2P illustrates an example of the memory circuit package 214 having multiple EIC dies 204 and memory stacks 212 being photonically coupled for inter-chip electro-photonic communication, according to embodiments of the present disclosure. As shown, the memory circuit package 214 may include two EIC dies 204 positioned on the same PIC wafer 203. For instance, the EIC layer 201 may include two (or more) EIC dies 204, such as for providing two different nodes of a computing system. The EIC dies 204 may be the same EIC die (e.g., copies of the same circuit, system, or components), or may be different.

As shown, each of the EIC dies 204 includes a memory stack 212 formed thereon, which may be accessible via the hardware components 205 of the associated EIC die 204. In some cases, the memory stacks 212 are formed on their respective EIC dies 204 in accordance with the techniques described in connection with FIGS. 2A-2C. In some cases, the memory stacks 212 are formed separately, and then disposed on and connected to their respective EIC dies 204 in accordance with the techniques described in connection with FIGS. 2E-2G. In some cases, each of the memory stacks 212 is formed through the same technique, or the memory stacks 212 may be formed through different techniques.

As shown in FIG. 2P, internal waveguides 270 in the PIC 200 may connect the photonic transceiver components for each EIC die 204. For example, the MOD 256 for each EIC die 204 may be connected via a waveguide 270 to the PD 266 for the other EIC die 204. In this way, the EIC dies 204 may be configured for inter-chip electro photonic communication by transmitting photonic signals therebetween through the PIC 200. This may facilitate the hardware components 205 of each of the EIC dies 204 communicating with one another. Additionally, the inter-chip connection between the EIC dies 204 may facilitate access of the memory stacks 212 by either EIC die 204. For example, while the hardware components 205 of each EIC die 204 may access the associated memory stack 212 positioned thereon, the hardware components 205 may also access, through inter-chip electro photonic communication via the waveguides 270, the memory stack 212 positioned on the other EIC die 205.

In this way, the memory stacks 212 included on each EIC die 204 may be accessible to other on-chip hardware components that are included on a separate or different EIC die, which may facilitate providing a larger and more robust pool of memory resources that are accessible to a wide variety of on-chip devices. For example, while the memory circuit package 214 is shown with two EIC dies 204, tens, hundreds, or more EIC dies 204 may be included on the PIC wafer 203 (e.g., with one or more or all having an associated memory stack 212 positioned thereon), and the EIC dies 204 may be photonically interconnected such that the memory stacks 212 of each of the EIC dies 204 may be widely accessible to the memory circuit package 214 as a whole.

Further, in addition to including multiple EIC dies 204 which are configured for inter-chip electro-photonic communication in this way, the memory circuit package 214 may also be configured with one or more of the photonic interface components as described in connection with FIGS. 2M-2O, such that the memory stacks 212 (of different EIC dies 204) may also be accessible through inter-chip electro-photonic communication by one or more off-chip devices. For example, the memory circuit package 214, in addition to including two or more EIC dies each having memory stacks thereon, may also include one or more photonic interfaces or optical regions, such as grating couplers or edge couplers, for connecting to off-chip devices via external optical fibers. To elaborate, each EIC die 204 may include multiple sets of electronic transceiver components (e.g., multiple AMS blocks 160), and the PIC 200 may also include multiple sets of corresponding photonic transceiver components. In this way, each EIC die 205 may be configured to connect photonically to multiple different devices or components via multiple different sets of electronic and photonic transceiver components. For example, each EIC die 204 may connect photonically to the other EIC die 204 as shown, and may also connect to an optical region (e.g., a grating coupler or an edge coupler) as described herein.

As mentioned, in some cases, an overmold may be applied or created on a circuit package which may cover one or more surfaces of the circuit package. In such cases, applying and forming the overmold may tend to cover, obscure, or otherwise block access to optical regions or photonic interface components, such as those including grating couplers and edge couplers. Details will now be described related to preserving optical access to photonic interface components through an overmold.

As noted above, one or more embodiments of the memory package may involve preserving access to an optical region formed on or near a surface of a PIC wafer (or other die). FIGS. 3A-3I illustrate an example process in which an optical path is preserved between a surface of a memory package and an optical region on a PIC wafer. For example, FIGS. 3A-3I show different views of a sacrificial die 320 for utilizing in connection with forming an overmolded circuit package in order to provide an optical path to an optical region of a PIC (or other wafer or substrate), according to embodiments of the present disclosure. In particular, FIG. 3A shows a bottom view of an example sacrificial die 320, while FIG. 3B shows a perspective view, and FIG. 3C shows a side cross-sectional view of the sacrificial die 320, according to at least one embodiment of the present disclosure.

The sacrificial die 320 may include a die having one or more sacrificial or dummy components positioned thereon. In one or more embodiments, the sacrificial die 320 may include another conventional electrical component (e.g., rather than a dummy component) that is pre-cut for the purposes of providing access to an optical region similar to one or more embodiments described herein. For example, the sacrificial die 320 may be made entirely of a substrate or wafer material or else may have one or more sacrificial components or features disposed on the substrate. In this way, the sacrificial die 320 may refer to a dummy, or non-functional component or die which has no specific electrical function or purpose. Alternatively, the sacrificial die 320 may be representative of any generic die and/or sacrificial component which can be pre-diced, deposited over a PIC wafer, and removed as part of the packaging processes described herein. For instance, in some cases the sacrificial die may include electronic components which may otherwise be functional or operable, but which may be utilized for sacrificial purposes.

The sacrificial die 320 may be made from any of a variety of materials. In one or more embodiments, the sacrificial die 320 is a metal or non-metal material such that an interior portion of the sacrificial die 320 can be removed (e.g., after pre-cutting grinding as described herein) using a magnetic tool or suction tool. In one or more embodiments, the sacrificial die 320 is a silicon material, semiconductor material, substrate, wafer material, or any other material that may be deposited over a surface of an optical region of a PIC wafer in accordance with one or more embodiments described herein. In some cases, the sacrificial die 320 is produced in conjunction with other sacrificial dies, such as on a larger wafer substrate, and several sacrificial dies are diced or cut from the wafer to produce distinct sacrificial dies for the purposes of the present techniques.

In some cases, an adhesive layer 322 is optionally deposited on a bottom surface 324 of the sacrificial die 320. For example, the bottom surface 324 may be a surface that is made to face or contact a PIC or wafer when the sacrificial die 320 is deposited thereon. The adhesive layer 322 may be an adhesive compound or material which may facilitate fixing, bonding, securing, or otherwise positioning the sacrificial die 320 on the wafer (e.g., either permanently or temporarily) in accordance with the techniques described herein. The adhesive layer 322 may be positioned around an outside portion or boundary of the sacrificial die 320. The adhesive layer 322 may not cover an entirety of the bottom surface 324, but rather, may be positioned near a perimeter of the bottom surface 324 such that an enclosed area is defined within the adhesive layer 322. For instance, the adhesive layer 322 may be deposited along opposite sides (e.g., left and right sides and/or top and bottom sides) of the bottom surface 324 of the sacrificial die 320. In some cases, the adhesive layer 322 is deposited at the perimeter, or can be offset from the perimeter of the bottom surface 324 as shown. In some cases, the adhesive layer 322 is a continuous line of adhesive which may span completely around the (e.g., perimeter of) the bottom surface 324, or else may be one or more discrete sections and/or may not be entirely enclosed. As will be discussed below, the adhesive layer 322 may be deposited on the bottom surface 324 of the sacrificial die 320 to provide a mechanism for securing the sacrificial die 320 in place on a wafer (and specifically over an optical region of a PIC wafer) in order to prevent an overmolding compound from flowing underneath the sacrificial die 320 and over the optical region.

In some embodiments, the adhesive layer 322 is deposited on the sacrificial die 320 prior to depositing the sacrificial die 320 on the PIC. Alternatively, in one or more embodiments, the adhesive layer 322 is deposited on the PIC (e.g., around the optical region) corresponding to a location that the sacrificial die 320 will be placed on the PIC and over the optical region. In some cases, the adhesive layer 322 may be deposited on, and the sacrificial die 320 joined to, the PIC as part of a PIC/EIC packaging process. For instance, in conjunction with joining or bonding die components and other EIC components to the PIC, the sacrificial die 320 may be bonded to the PIC. In one or more embodiments, the adhesive layer 322 is added and the sacrificial die 320 joined to the PIC as part of the fabrication process of the PIC (e.g., prior to adding EIC components thereto).

In some cases, in addition to the adhesive layer 322, a protective material 326 is disposed on the bottom surface 324 of the sacrificial die 320. For example, the protective material 326 may be a protective film, cover, or other component or structure which may be positioned on the bottom surface 324. As described herein, the protective material 326 may facilitate protecting or covering the optical region of the PIC when the sacrificial die 320 (or an interior portion thereof) may come into contact with the optical region. For instance, in some cases the optical region (or other portion of the PIC to be protected) may become damaged or scratched should the sacrificial die 320 (or a portion thereof) come into contact with the optical region. Accordingly, the protective material 326 may be made using any suitable material that may provide a barrier between the sacrificial die 320 and a surface of the PIC such as the optical region. For instance, the protective material 326 may refer to an underfill, molding compound, or other substance that provides some material that protects or buffers the optical region from contact with the sacrificial die 320.

In some embodiment, the protective material 326 may be positioned on the bottom surface 324 of the sacrificial die 320 to cover only a portion of the bottom surface 324. For example, in the embodiment shown, the protective material 326 is deposited over an inner portion of the bottom surface 324, such as within the enclosed area defined by adhesive layer 322. In some cases, the protective material 326 may be sized and/or shaped in accordance with a optical region (or other area for protecting) of the PIC. In some cases, the protective material 326 may be thinner than the adhesive layer 322. For instance, when the sacrificial die 320 is adhered or bonded to the PIC, the protective material 326 may not (initially) contact the PIC (e.g., the optical region) which may facilitate protecting the PIC from damage associated with contact by the sacrificial die 320. In other cases, the protective material 326 may contact the PIC when the sacrificial die 320 is connected thereto, and the protective material 326 may in this way provide protection against damage to the optical region.

In some cases, the protective material 326 is optional and/or not necessary for the techniques described herein. For example, in some cases the optical region of the PIC may have little or no risk of being damaged, scratched, etc. To elaborate, in some cases, the sacrificial die 320 (or a separated portion thereof) may not contact the optical region, or else contact of the sacrificial die 320 with the optical region may not result in any damage to the optical region. Accordingly, the protective material 326 is shown in FIGS. 3A-3C in phantom, illustrating this optional nature.

Referring now to FIGS. 3D-3I, these figures illustrate various schematic representations of the sacrificial die 320, according to at least one embodiment of the present disclosure. For example, FIGS. 3D, 3F, and 3H illustrate perspective views of the sacrificial die 320 with one or more surfaces as transparent, in order to illustrate various features of the sacrificial die 320. These figures show the sacrificial die 320 having a first end 325-1 and an opposite, second end 325-2, as well as a left side 325-L and an opposite, right side 325-R. FIG. 3E shows a corresponding side view of the first end 325-1 of the sacrificial die, and FIG. 3G shows a corresponding side view of the right side 325-R of the sacrificial die 320.

In some cases, the sacrificial die 320 is pre-cut or pre-diced. Pre-cutting or pre-dicing in this context may refer to a partial cutting, dicing, or scoring of the sacrificial die 320 as described herein for producing an interior portion 331 and an uncut portion 330. Pre-cutting or pre-dicing in this way may be in addition to (or before or after) a cutting or dicing which may be performed to separate discrete, sacrificial dies from a larger, wafer substrate.

The sacrificial die 320 may be pre-cut before it is positioned on the PIC. The pre-cutting of the sacrificial die 320 may be performed before or after depositing the adhesive layer 322 and/or the protective material 326 on the bottom surface 324. The sacrificial die 320 may be pre-cut based on forming one or more vertical cuts 328 in the sacrificial die 320. For instance, the vertical cuts 328 may be considered vertical with respect to the orientation shown and for ease of discussion, but may not necessarily be vertical in all orientations and in all implementations. The vertical cuts 328 may be formed or cut by a knife (or other physical cutting tool), laser, grind, etching, chemical process, or any other suitable method for forming the vertical cuts 328. The vertical cuts 328 may extend from the bottom surface 324 toward a top surface 325-T of the sacrificial die 320, and may extend partially through the thickness of the sacrificial die 320. For instance, in some cases the sacrificial die is 500-1000 microns thick, and the vertical cuts 328 may extend to within 50-100 microns of the top surface 325-T of the sacrificial die 320. In some cases, the vertical cuts 328 extend to within 25-75 microns of the top surface 325-T. As an example, the sacrificial die 320 may be 500 microns thick, and the vertical cuts 328 may extend 400-450 microns from the bottom surface 324. In some cases, the sacrificial die maybe 800 microns thick, and the vertical cuts 328 may extend 700-750 microns from the bottom surface 324. As another example, the sacrificial die may be 1000 microns thick and the vertical cuts 328 may extend 900-950 microns from the bottom surface 324. In this way, the vertical cuts 328 may leave an uncut portion 330 of the sacrificial die 320 near a top surface 325-T of the sacrificial die 320 (e.g., an upper region of the sacrificial die) and may define an interior portion 331 below the uncut portion 330.

In one or more embodiments, the size and/or length of the vertical cuts 328 is determined based on a later grinding process involved in creating a circuit package using the sacrificial die 320. For example, as described herein, the sacrificial die 320 may be grinded in conjunction with grinding an overmold applied to the PIC and other components. The grinding process may be performed to remove the uncut portion 330 such that the interior portion 331 of the sacrificial die may be separated and/or removed. Accordingly, the size and/or length of the vertical cuts 328 may be determined based on an amount of grinding to be performed on the sacrificial die 320 and other components of the PIC. For example, the amount of grinding to be performed (and the length of the vertical cuts 328) may be determined to provide a mechanism to ensure that the interior portion 331 is separated from the sacrificial die 320 at an appropriate stage of the package process, as discussed below.

In some cases, four (4) vertical cuts 328 may be formed in the sacrificial die 320. For example, two (2) vertical cuts 328 may be formed in alignment (e.g., parallel) with the right side 325-R and left side 325-L (e.g., FIGS. 3D and 3E), and two (2) vertical cuts 328 may be formed in alignment (e.g., parallel) with the first end 325-1 and second end 325-2 (e.g., FIGS. 3F and 3G). For ease in discussion and illustration, only two such vertical cuts 328 are shown in each of FIGS. 3D-3G, but it should be understood that each of these vertical cuts 328 may be formed in the sacrificial die 320, totaling four vertical cuts. In this way, the vertical cuts 328 may define a prismatic shape of the interior portion 331. In some cases, other quantities and/or arrangements of vertical cuts 328 may be formed in the sacrificial die 320, for example, for forming other shapes or volumes of the interior portion 331.

As mentioned, the vertical cuts 328 may originate or extend from the bottom surface 324 and may extend (e.g., partially) toward the top surface 325-T, less than a thickness of the sacrificial die 320. In this way, the interior portion 331 may be separated from the remainder of the sacrificial die 320 on four sides or at four surfaces corresponding with the vertical cuts 328. A remaining surface (e.g., in a conceptual sense), or uncut plane 334 of the interior portion 331, as shown in FIG. 3H, may remain connected and/or continuous with the rest of the body of sacrificial die 320.

As shown in FIG. 3I, the adhesive layer 322 may be positioned on the bottom surface 324 around or surrounding the vertical cuts 328 and the interior portion 331. For instance, the adhesive layer 322 may be positioned at or offset from (e.g., larger than) the perimeter of the interior portion 331. In this way, when the sacrificial die 320 is bonded to the PIC, the interior portion 331 may not be bonded to the PIC, and additionally, the adhesive layer 322 may prevent any overmold applied to the sacrificial die 320 from penetrating to and/or contacting the interior portion 331. Additionally, the protective material 326 may optionally be positioned on the interior portion 331, such as partially or entirely covering a bottom surface of the interior portion 331. As described above, when the sacrificial die 320 is grinded and the interior portion 331 separated from the sacrificial die 320, the protective material 326 may provide a barrier to protect an optical region (or other region) from the interior portion 331 dropping, falling, or otherwise contacting the optical region.

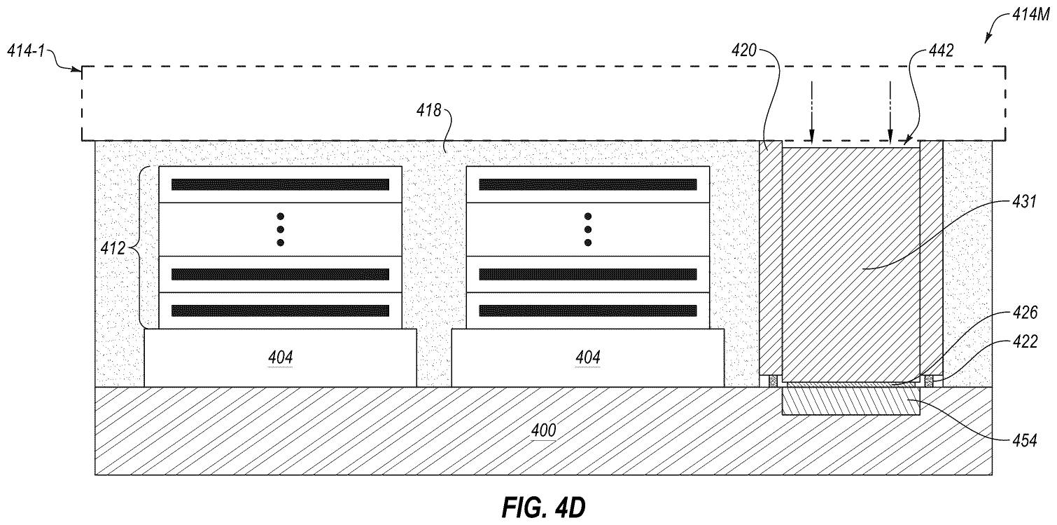

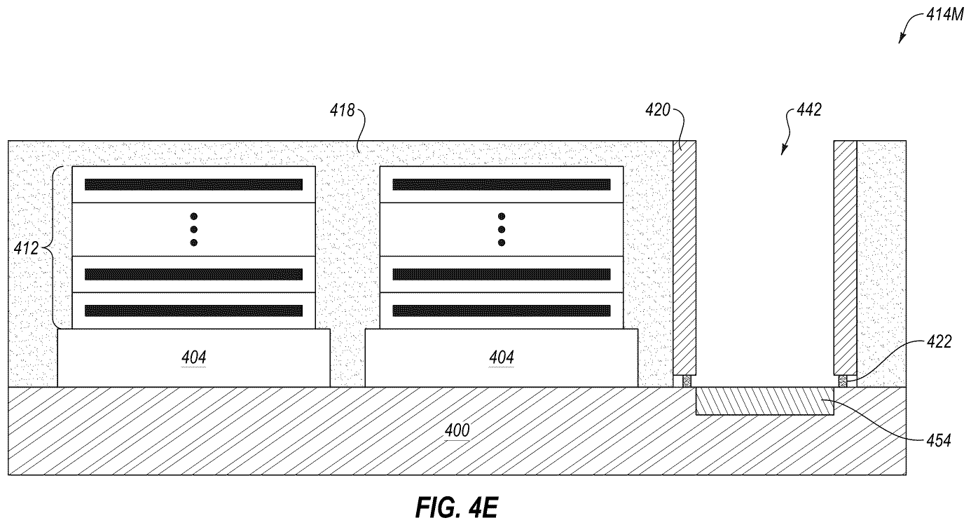

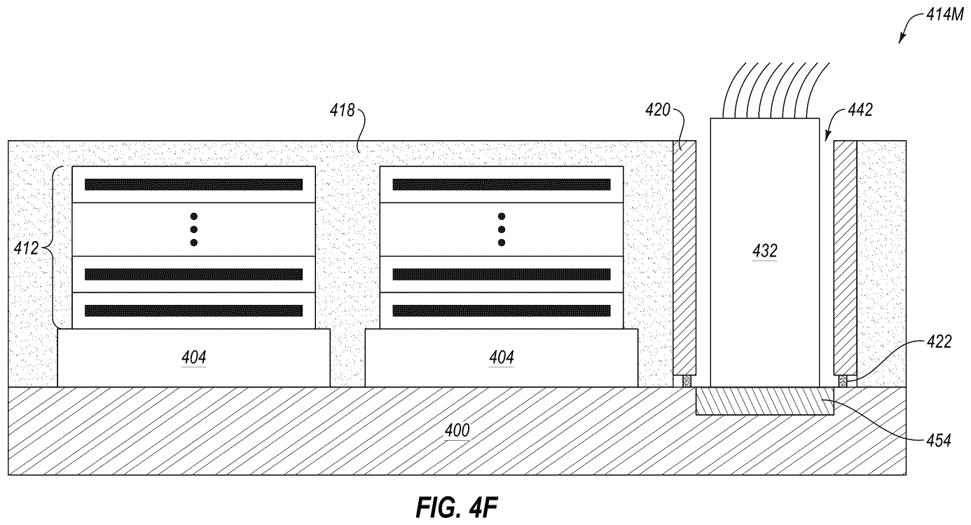

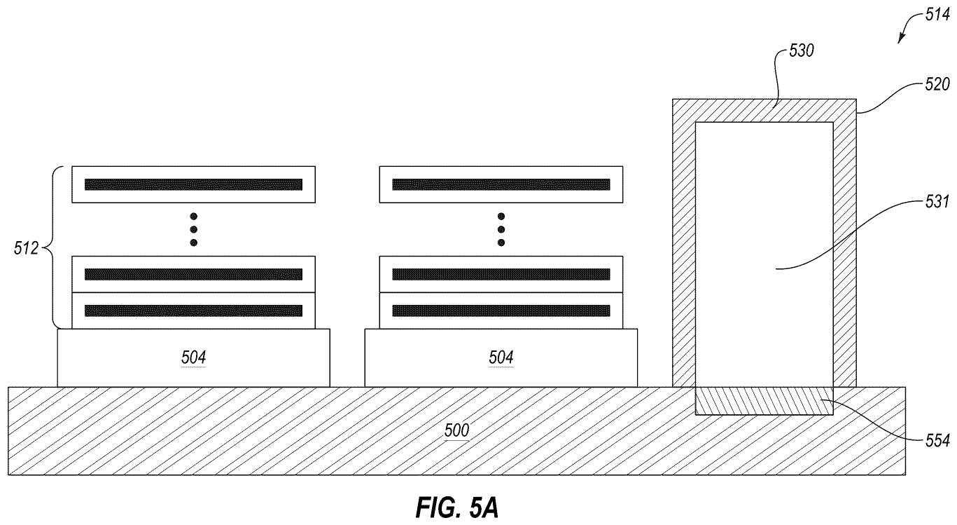

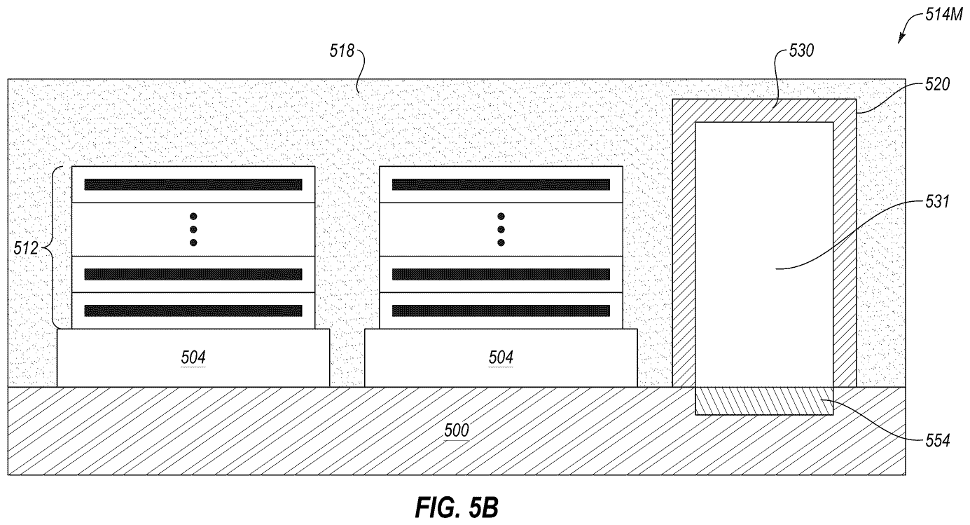

FIG. 4A illustrates a side view of a memory circuit package 414, and FIG. 4B illustrates a side view of an exemplary embodiment of forming a molded memory circuit package 414M, according to at least one embodiment of the present disclosure. The memory circuit package 414 may be a memory circuit package in accordance with any of the embodiments described herein. For instance, the memory circuit package 414 may be formed of a PIC 400 including one or more EIC dies 404 disposed thereon. The EIC die 404 (or multiple EIC dies) may include a memory stack 412 disposed thereon. As shown in FIG. 4A, a sacrificial die 420 may be implemented in connection with the PIC 400 in order to provide an optical window or optical path for optical access to an optical region 454 disposed within the PIC 400 as part of a process for forming the molded memory circuit package 414M.

The sacrificial die 420 may be a sacrificial die in accordance with that discussed above. For example, the sacrificial die 420 may be bonded, joined, or connected to the PIC 400 by an adhesive layer 422. The sacrificial die 420 may optionally include a protective material 426 disposed on the bottom surface of the sacrificial die 420. The sacrificial die 420 may also be precut in accordance with that discussed herein such that an interior portion 431 of the sacrificial die 420 is separated from the sacrificial die 420 on several sides of the interior portion 431, and an uncut portion 430 connects the interior portion 431 to the sacrificial die 420 near a top of the sacrificial die 420.

As shown, the sacrificial die 420 may be positioned on the PIC 400 above the optical region 454. The optical region 454 may be a region where photonic signals may pass through the a surface of the PIC 400. For instance, the optical region 454 may include one or more grating couplers. The adhesive layer 422 may be positioned around or surrounding the optical region 454 such that optical region 454 is contained within an area defined by the adhesive layer 422. In some cases, the adhesive layer 422 is positioned entirely around a perimeter of the optical region 454, or may be positioned around a portion of the perimeter of the optical region 454, such as on two opposite sides of the optical region 454. As shown, some measure of space may exist between the sacrificial die 420 and the PIC 400 when the sacrificial die 420 is placed in position (e.g., adhered) over the optical region 454. This space may result from the adhesive layer 422, or one or more additional components may be incorporated for elevating the sacrificial die 420 above the PIC 400. In this way, the sacrificial die 420 may be bonded, adhered, or otherwise connected to the PIC 400.

As shown in FIG. 4B, a molding compound may be applied or disposed on the PIC 400 and the components disposed thereon to create an overmold 418. For example, the overmold 418 may be comprised of a molding compound deposited over the EIC die 404, the memory stack 212, and over a top surface of the PIC 400. Additionally, the molding compound may be deposited over the sacrificial die 420. The overmold 418 may be made from a variety of materials having various properties. For example, in one or more embodiments, the overmold 418 is an epoxy molding compound in a liquid form that hardens and/or cures to secure elements of a circuit package in place when deposited over a surface of the circuit package. The overmold 418 covers each of the components positioned on the PIC 400 and fills in gaps between (and in some cases underneath) the components to cover any exposed and/or vacant areas of the memory circuit package 414. In this way the molded memory circuit package 414M may be created by applying the overmold 418 to the PIC 400.

The connection of the sacrificial die 420 to the PIC 400 may prevent the overmold 418 from penetrating or flowing between the sacrificial die 420 and the PIC 400. For example, by virtue of the adhesive layer 422, the overmold 418 may not fill in a space underneath the sacrificial die 420. In this way, the overmold 418 may not cover, contact, or flow to the optical region 454. Thus, an area under the sacrificial die 420 may be at least partially preserved to be exposed at a later stage in this packaging process as described herein.

FIGS. 4C-4F illustrate an example of forming an optical window through the overmold 418 of the molded memory circuit package 414M, according to embodiments of the present disclosure. In some embodiments, after the overmold 418 has dried, cured, and/or hardened, one or more layers of overmold 418 may be removed. For example, the molded memory circuit package 414M may be operated on to perform a grinding process 480, which may remove a layer 414-1 of the molded memory circuit package 414M. For instance, the layer 414-1 may be grinded, milled, etched, or otherwise removed from the molded memory circuit package 414M. In some cases, the layer 414-1 may include a portion of the overmold 418. In some cases, a portion of the sacrificial die 420 is removed in the layer 414-1 as part of the grinding process 480. For instance, an uncut portion 430 of the sacrificial die 420 as described herein may correspond with the layer 414-1 and may be removed by the grinding process 480. In particular, the grinding process 480 may be implemented in connection with the thickness of the uncut portion 430 and or a thickness of an interior portion 431 of the sacrificial die 420 such that the grinding process 480 removes the layer 414-1 at a thickness corresponding with an entirety (or more) of the uncut portion 430 being removed from the sacrificial die 420.

In this way, the grinding process 480 may not only remove some of the overmold 418, but may also grind or cut away the sacrificial die 420 to a degree such that the layer 414-1 overlaps or intersects vertical cuts 438 formed in the sacrificial die 420 as described herein. Accordingly, based on removing the layer 414-1 and the uncut portion 430, the interior portion 431 of the sacrificial die 420 may be separated or freed from the remainder of the sacrificial die 420. For instance, because the interior portion 431 is not adhered to the PIC 400 by the adhesive layer, and because the interior portion 431 is not directly covered by or disposed within the overmold 418, the interior portion 431 may become free, loose, detached, or separated based on the grinding process 480.

As shown in FIG. 4E, in some cases, due to the grinding process 480 (e.g., and also due to the pre-cutting or pre-dicing of the sacrificial die 420), the interior portion 431 that has been separated from the sacrificial die 420 may become loose, may fall, and/or may come into contact with the PIC 400 at the optical region 454. More specifically, because the interior portion 431 is separated from the sacrificial die 420, in some cases the interior portion may become loose within an optical window 442 within the sacrificial die 420, and a bottom surface of the interior portion 431 may come into contact with the PIC 400 at the optical region 454. As described herein, in some cases the interior portion 431 may include a protective material 426 which may facilitate protecting or preventing damage to the optical region 454. However, in some cases, such a protective material is not necessary and the optical region 454 may nevertheless not become damaged due to contact with the interior portion 431. In some cases, the interior portion 431 may become separated within the optical window 442 but may nevertheless not contact the PIC 400 and/or the optical region 454.

As shown in FIG. 4E, in some cases, the interior portion 431 is removed. For instance, the interior portion 431 may be vacuumed or suctioned away, may be adhered to and pulled away with a tape or adhesive, may be grasped and removed with a tool or implement, or any other suitable means that is designed to clean up or removed discrete components from a circuit package. In cases where the sacrificial die 420 is made of a metal material, the interior portion 431 may be removed with a magnet.

As shown, after the interior portion 431 is removed, an optical window 442 is now available that provides direct access to the optical region 454 on the PIC 400. For instance, the optical window 442 may extend and/or provide access through the overmold 418, such that the optical region 454 may be directly accessible through the overmold 418. For example, the optical window 442 (e.g., corresponding with a dimension of the removed interior portion 431) may span substantially all of the optical region 454.

This optical window 442 may be beneficial in that it may provide advantageous access for one or more external components to interface with the PIC 400 at the optical region 454. For instance, as shown in FIG. 4F, an optical interface component 432 (e.g., a fiber array unit or other optical interface component) can be inserting into and/or through the optical window 442 (e.g., through the opening in the overmold 418) such that the optical interface component 432 can couple with the optical region 454. Similar to one or more embodiments described herein, the coupling of the optical interface component 432 and the optical region 454 may provide a mechanism whereby on or more external or off-chip devices can access the memory resources of the memory stack 412 based on the EIC die 404 transmitting and receiving photonic signals via the optical region 454 and optical interface component 432 (or other photonic componentry).

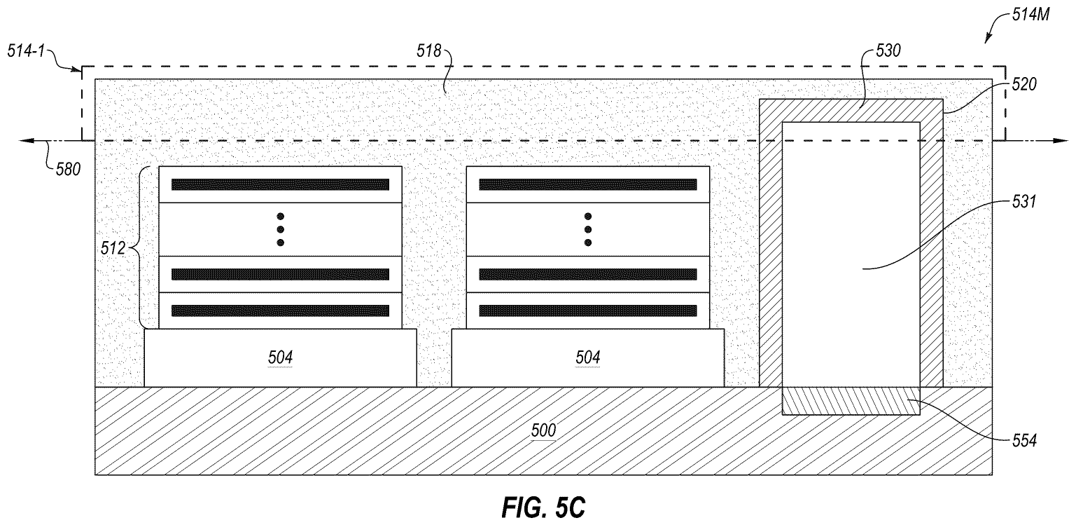

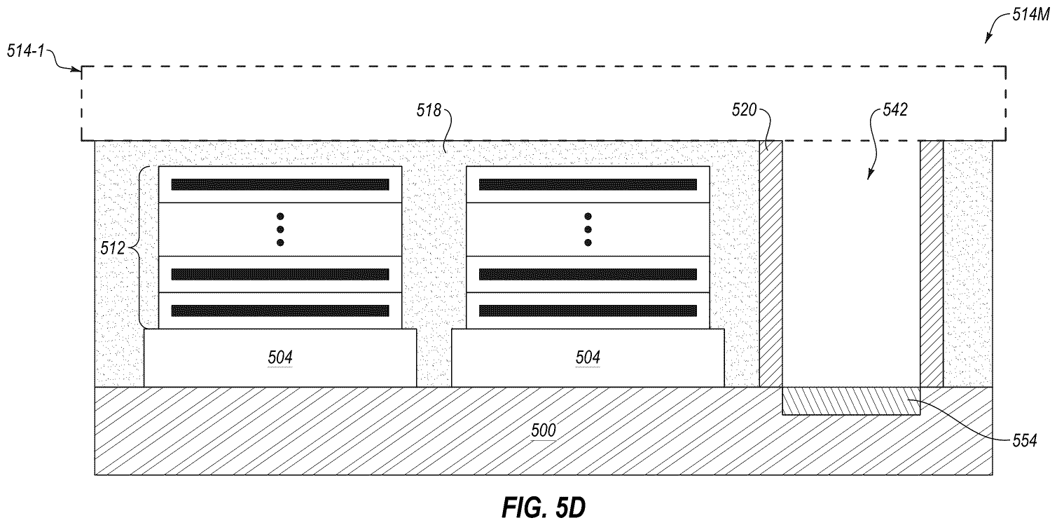

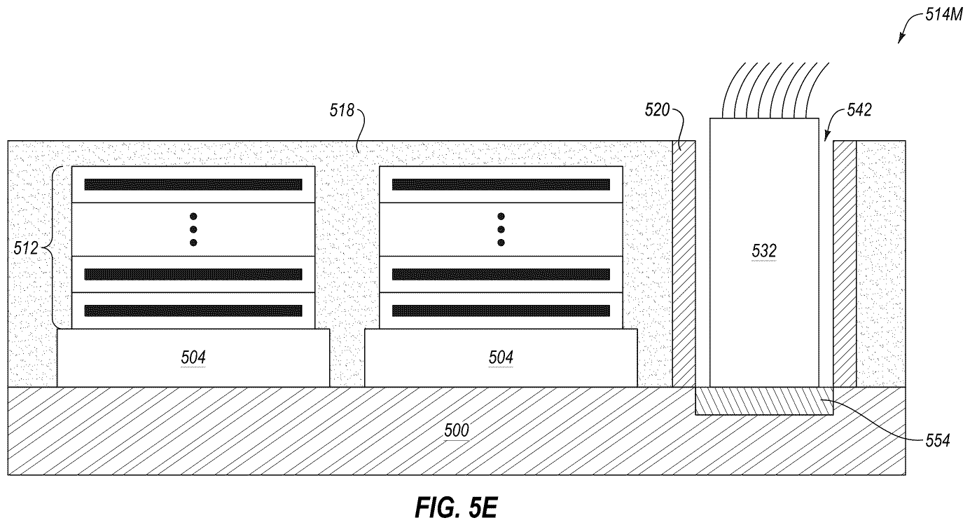

Moving on, FIGS. 5A-5E illustrate another example implementation in which optical access is preserved between a top surface of a circuit package and an optical region on a PIC wafer. For example, FIG. 5A illustrates a side view of a memory circuit package 514, and FIG. 5B illustrates a side view of an exemplary embodiment of forming a molded memory circuit package 514, according to embodiments of the present disclosure. In some cases, a sacrificial cap 520 is disposed on a PIC 500 (or other wafer or substrate) and incorporated as part of the memory circuit package 514. For example, the sacrificial cap 520 may be a component or structure which includes or defines a void or recess 531 at an inner portion of the sacrificial cap 520. The recess 531 may be a cutout or a vacant portion of the sacrificial cap 520 which is positioned at or facing a bottom surface of the sacrificial cap 520. For instance, when the sacrificial cap 520 is placed on the PIC 500, the recess 531 is disposed toward the PIC 500. While shown in 2-dimensions and as a tunnel through the sacrificial cap 520, it will be appreciated that the recess 531 may be a void entirely within a body of the sacrificial cap 520 such that the sacrificial cap 520 is continuous around a perimeter of the recess 531 with a bottom surface of the volume of the recess 531 being exposed at the bottom of the sacrificial cap 520. Thus, the recess 531 may not necessarily be a void through the sacrificial cap 520, but rather, a void disposed within the sacrificial cap 520.

As shown, the sacrificial cap 520 may be disposed on and connected to the PIC 500 over an optical region 554. The optical region 554 may be representative of a region of the PIC 500 through which optical signals may pass. For instance, the optical region 554 may include one or more grating couplers positioned within the PIC 500. The sacrificial cap 520 may be bonded, glued or adhered to the PIC 500. For example, an adhesive layer may be applied and/or positioned between the sacrificial cap 520 and the PIC 500. In some cases, the adhesive layer is deposited on the sacrificial cap 520, or else the adhesive layer may be deposited on the PIC 500. The adhesive layer may be positioned around or surrounding the optical region 554 such that the optical region 554 is contained within an enclosed area defined by the adhesive layer. For instance, the adhesive layer may be positioned entirely around a perimeter of the optical region 554.

In this way, the sacrificial cap 520 may be adhered to the PIC 500 in a surrounding configuration around a periphery of the optical region 554. For instance, the optical region 554 may be entirely contained or covered by the sacrificial cap 520, for example, in the recess 531. The sacrificial cap 520 may be disposed on and bonded to the PIC 500 in conjunction with, before, or after placement of one or more of the EIC die 504, the memory stack 512, or other components.

As shown in FIG. 5B, a molding compound may be applied or disposed on the PIC 500 and the components disposed thereon to create an overmold 518. For example, the overmold 518 may be comprised of a molding compound deposited over the EIC die 504, the memory stack 512, and over a top surface of the PIC 500. Additionally, the molding compound may be deposited over the sacrificial cap 520. The overmold 518 may be made from a variety of materials having various properties. For example, in one or more embodiments, the overmold 518 is an epoxy molding compound in a liquid form that hardens and/or cures to secure elements of a circuit package in place when deposited over a surface of the circuit package. The overmold 518 covers each of the components positioned on the PIC 500 and fills in gaps between (and in some cases underneath) the components to cover any exposed and/or vacant areas of the memory circuit package 514. In this way the molded memory circuit package 514MM may be created by applying the overmold 518 to the PIC 500.

The sacrificial cap 520 may be bonded to the PIC 500 such that the overmold 518 does not penetrate underneath the sacrificial cap 520, or between the sacrificial cap 520 and the PIC 500. Accordingly, because the sacrificial cap 520 has the recess 531 therein, and because the recess 531 is positioned over the optical region 554, a vacant space may be maintained above the optical region 554 by the sacrificial cap 520 where the overmold 518 does not enter. In other words, the overmold 518 does not come into contact with, and does not directly cover, the optical region 554 due to the sacrificial cap 520 and associated recess 531. For example, the recess 531 may be sized and shaped in accordance with the optical region 554 which it is positioned to cover. For example, a cross section or projection of the recess 531 onto the CG region may be approximately the same shape and/or size as the optical region 554. In some cases, the recess 531 may be slightly larger than the optical region 554. As will be discussed below, maintaining this space above the optical region 554 facilitates creating an optical window through the overmold 518 in connection with a grinding process, for providing access to the optical region 554.

In one or more embodiments, the sacrificial cap 520 is made of a similar type of material as the overmold 518. For example, the sacrificial cap 520 may be made of the same molding compound as the overmold 518. The sacrificial cap 520 may be pre-made using a molding compound (e.g., epoxy) that is placed into a die, mold, or template structure that, when hardened, produces the sacrificial cap 520 having the structure shown and described. In some cases, multiple sacrificial caps 520 are created at once from a mold or die having multiple instances of the sacrificial cap 520. The sacrificial cap 520 may be made of any suitable material, such as plastics and polymers, metals, substrate material (e.g., silicon), or any other material for creating a sacrificial cap to achieve the purposes described herein.

The dimensions of the recess 531 above the optical region 554 of the PIC 500 may be specifically determined in accordance with a grinding process to be performed on the molded memory circuit package 514M. For example, in some cases, the recess 531 extends approximately the same height as the EIC die 504 and memory stack 512 disposed on the PIC 500, or may extend further or thicker than the memory stack 512. In the least, the recess 531 is thick or tall enough such that the recess 531 is exposed after a grinding process has been performed. For example, the sacrificial cap 520 may be sized, shaped, and configured in accordance with a griding process to be performed such that an top portion 530 of the sacrificial cap 520 is removed during the grinding process, exposing the recess 531 underneath.

In some cases, the sacrificial cap 520 has a height or thickness of 500-1000 microns thick, and the recess 531 extends to within 50-100 microns of the top surface of the sacrificial cap 520. In some cases, the recess extends to within 25-75 microns of the top surface of the sacrificial cap 520. As an example, the sacrificial cap 520 may be 500 microns thick, and the recess 531 may extend 400-450 microns from the bottom of the sacrificial cap 520. In some cases, the sacrificial cap may be 800 microns thick, and the recess 531 may extend 700-750 microns from the bottom surface. As another example, the sacrificial cap 520 may be 1000 microns thick and the recess 531 may extend 900-950 microns from the bottom surface.

In some cases, rather than having an entirely empty or vacant recess 531, one or more fill components may be positioned in the recess 531, completely or partially filling the recess 531. For example, the fill components may be non-functional or space-filling components positioned (e.g., loose, or temporality connected) in the recess 531. When the recess 531 is exposed from the later grinding process, the fill components may be removed to expose the optical region 554. The fill components in this way may facilitate taking up space within the recess 531 such that thermal expansion and/or contraction of gasses (e.g., air) within the recess 531 does not damage the sacrificial cap 520 or a bond of the sacrificial cap 520 to the PIC 500. For instance, the memory circuit package 514 may be exposed to elevated temperatures at one or more stages, and trapped gasses in the recess 531 may tend to thermally expand. In some cases, the fill components may be made of a material which experiences thermal contraction/expansion to a lesser degree, or not at all. In this way, the sacrificial cap 520 may be filled with less gas, which may in turn exhibit less overall thermal expansion, mitigating the risks of damaging the sacrificial cap 520.

In some embodiments, the sacrificial cap 520 is equipped with one or more holes or openings such that trapped gas may vent or escape under thermal expansion. For instance, these holes or openings may be small enough that the overmold 518 (e.g., in its liquid state) does not penetrate or flow into the recess 531 due to a viscosity of the (liquid) molding compound. In another example, the sacrificial cap 520 is equipped with a chimney-like structure which may extend upwards past the upper extent of the overmold 518 such that trapped gas may escape the recess 531 while preventing the molding compound from flowing into the recess 531.

FIGS. 5C-5E illustrate an example of forming an optical window through the overmold 518 of the molded memory circuit package 514M, according to embodiments of the present disclosure. In some embodiments, after the overmold 518 has dried, cured, and/or hardened, one or more layers of overmold 518 may be removed. For example, as shown in FIG. 5D, the molded memory circuit package 514M may be operated on to perform a grinding process 580, which may remove a layer 514-1 of the molded memory circuit package 514M. For instance, the layer 514-1 may be grinded, milled, etched, or otherwise removed from the molded memory circuit package 514M. In some cases, the layer 514-1 may include a portion of the overmold 518. In some cases, a portion of the sacrificial cap 520 is removed in the layer 514-1 as part of the grinding process 580. For instance, a top portion 530 of the sacrificial cap 520 may correspond with the layer 514-1 and may be removed by the grinding process 580.

In particular, the grinding process 580 may be implemented in connection with the dimensions and/or geometry of the sacrificial cap 520, and more specifically, the dimensions and/or geometry of the recess 531. For example, the grinding process 580 may be such that it removes the layer 514-1 at a thickness corresponding with an entirety (or more) of the top portion 530 being removed from the sacrificial cap 520. Accordingly, the sacrificial cap 520 may be sized and configured in accordance with the grinding process 580, based on the various components disposed on the PIC 500. For instance, the sacrificial cap 520 may extend from the PIC 500 a greater distance than a thickness of any electronic components or dies positioned on the PIC 500. In particular, the sacrificial cap 520 may extend from the PIC 500 a greater distance than the memory stack 512 and the EIC die 504. This may facilitate the recess 531 extending past the thickness of any components disposed on the PIC 500 such that the grinding process 580 may be performed to remove the top portion 530 of the sacrificial cap 520 down to the recess 531, for example, without contacting or reaching other components (e.g., the memory stack 512) disposed on the PIC 500.

As shown, after the grinding process 580 and after the layer 514-1 (and top portion 530) are removed, an optical window 542 is now available that provides direct access to the optical region 554 on the PIC 500. For instance, the optical window 542 may extend and/or provide access through the overmold 518, such that the optical region 554 may be directly accessible through the overmold 518. For example, the optical window 542 (e.g., corresponding with a dimension of the recess 531) may span substantially all of the optical region 554.

As noted above, this optical window 542 is beneficial and provides advantageous access for one or more external components to interface with the PIC 500 at the optical region 554. For instance, as shown in FIG. 5E, an optical interface component 532 (e.g., a fiber array unit or other optical interface component) can be inserting into and/or through the optical window 542 (e.g., through the overmold 518) such that the optical interface component 532 can couple with the optical region 554. The coupling of the optical interface component 532 and the optical region 554 may provide a mechanism whereby one or more external or off-chip devices may access the memory resources of the memory stack 612 based on the EIC die 604 transmitting and receiving photonic signals via photonic interface formed by the optical region 554 and optical interface component 532.

While the techniques related to creating an optical window through an overmold by utilizing a sacrificial or pre-cut die (FIGS. 3A-4E) and/or by utilizing a sacrificial cap (FIGS. 5A-5E) have been shown and described in relation to an optical region positioned at, near, or accessible via a top surface of a PIC (e.g., the same surface upon which the EIC die is positioned), as mentioned above (e.g., FIG. 2N), in some cases an optical region, such as those including a grating coupler, may be located at, near, or accessible via a bottom surface of the PIC (e.g., an opposite surface from where the EIC die is positioned). Additionally, in some cases, overmolds may be applied or formed on the bottom surface (e.g., by flipping the PIC over) as part of the production of a circuit package. Accordingly, these overmolds may similarly tend to cover, obscure, or block access to optical regions located at the bottom surface of the PIC. It should be understood that the sacrificial die techniques, as well as the sacrificial cap techniques, described herein may each be applicable to such cases as well, in order to preserve optical access to an optical region on the bottom of the PIC. For example, a sacrificial die or a sacrificial cap may be disposed and adhered to the bottom of the PIC at and over the optical region, after which the overmold may be formed thereon and subsequently grinded down to reveal an optical window to the bottom-surface optical region as described herein. Indeed, the techniques described herein for creating optical windows to optical regions (or other optical interfaces) may be applicable for any surface of any wafer structure to which an overmold is applied.

FIG. 6A illustrates yet another example in which optical access is preserved to an optical region within a PIC wafer. For example, FIG. 6A illustrates a side view of a memory circuit package 614 and a neighboring package 614-2, according to embodiments of the present disclosure. FIG. 6B illustrates a top view of a PIC 600 by which the memory circuit package 614 and the neighboring package 614-2 are implemented, according to embodiments of the present disclosure. FIG. 6C illustrates a side view of an exemplary embodiment of forming a molded memory circuit package 614, according to embodiments of the present disclosure. The memory circuit package 614 may include any of the features and/or functionality of other circuit packages described herein. For instance, the memory circuit package 614 may include a PIC 600 having one or more EIC die 604 disposed thereon, including a memory stack 612 positioned on top of the EIC die 604.

In some embodiments, the memory circuit package 614 includes an optical region 652 formed at an edge 644 of the PIC 600. For instance, the optical region 652 may include one or more edge couplers. The edge 644 may be a physical edge or boundary of the PIC 600, and may be formed based on dicing or cutting the PIC 600 (e.g., and accordingly the memory circuit package 614) from its larger wafer structure. For example, the memory circuit package 614 may be created or disposed on the PIC 600 along with one or more other instances of (the same or different) circuit packages. Accordingly, the edge 644 may represent a boundary between the memory circuit package 614, and a next or neighboring package 614-2 which is positioned adjacent to the memory circuit package 614 on the PIC 600. The edge 644 may be a physical edge after the memory circuit package 614 is diced and separated from the neighboring package 614-2, but may also represent a demarcation between the memory circuit package 614 and the neighboring package 614-2 when both are disposed on the PIC 600 before dicing. The neighboring package 614-2 may be representative of a next or adjacent circuit package having one or more die components disposed thereon, or may be representative of a (e.g., empty) portion of the substrate of the PIC 600 having no die components thereon, for example, when the memory circuit package 614 is a circuit package at a periphery of the PIC 600.

The optical region 652 may be an area or region on the PIC 600 which includes one or multiple edge couplers or edge coupling features. For example, the optical region 652 may typically one or more edge coupling components 653. For instance, the edge coupling components 653 may include geometric features formed or cut out of the PIC 600 such as one or more alignment features or V-grooves, similar to one or more embodiments described herein. For example, the edge coupling components 653 may facilitate aligning one (and typically many) optical fibers with internal waveguides in the PIC 600. The optical region 652 may include other features and/or mechanisms whereby optical interface components may be coupled to the PIC 600. In some cases, the optical region 652 is formed in the PIC 600 as part of a manufacturing process of the PIC 600. For example, in some cases, the wafer package 301 is processed or operated on to form one or multiple optical regions 652 in one or multiple circuit packages that are included on the PIC 600.

In some cases, a sacrificial cap 620 is disposed on the PIC 600 and incorporated as part of the memory circuit package 614. For example, the sacrificial cap 620 may be a sacrificial cap in accordance with that shown and described in connection with FIGS. 5A-5E. As shown, the sacrificial cap 620 may be disposed on the PIC 600 at the edge 644 and over the optical region 652. For instance, the sacrificial cap 620 may be disposed partly on the memory circuit package 614 and partly on the neighboring package 614-2, or otherwise straddling or spanning the edge 644 between these two packages. The sacrificial cap 620 may be positioned on and adhered to the PIC 600 such that the optical region 652 is entirely contained or covered by the sacrificial cap 620, for example, in a recess 631 of the sacrificial cap 620. The sacrificial cap 620 may be disposed on and bonded to the PIC 600 in conjunction with, before, or after placement of one or more of the EIC die 604, the memory stack 612, or other components, on the PIC 600.

While the sacrificial cap 620 is shown specifically at a singular edge 644 of the memory circuit package 614, it will be appreciated that any number of the edges of the memory circuit package 614 (e.g., edges between the memory circuit package 614 and adjacent circuit packages on the PIC 600) may include optical regions 652, and accordingly, sacrificial caps 620 may be positioned at any of these edges in accordance with the techniques described herein.

As shown in FIG. 6C, a molding compound may be applied or disposed on the PIC 600 and the components disposed thereon to create an overmold 618. The overmold 618 may be applied over the PIC 600, the EIC die 604, the memory stack 612, and the sacrificial cap 620. Additionally, the overmold 618 may be applied to all of the circuit packages formed on the PIC 600. For instance, the PIC 600, and all components disposed thereon, may be covered by the overmold 618 such that the overmold is continuous over the various circuit packages of the PIC 600. To elaborate, the overmold 618 may be continuous between the memory circuit package 614 and the neighboring package 614-2. In this way, a molded memory circuit package 614M and a neighboring molded package 614M-2 are created by applying the overmold 618, which molded circuit packages area joined or connected until separated by dicing.

Similar to one or more embodiments described herein, the sacrificial cap 620 may be bonded to the PIC 600 such that the overmold 618 does not penetrate underneath the sacrificial cap 620, or between the sacrificial cap 620 and the PIC 600. Accordingly, because the sacrificial cap 620 has the recess 631 therein, and because the recess 631 is positioned over the optical region 652, a vacant space may be maintained above the optical region 652 by the sacrificial cap 620 where the overmold 618 does not enter. In other words, the overmold 618 does not come into contact with, and does not directly cover, the optical region 652 due to the sacrificial cap 620 and associated recess 631. For example, the recess 631 may be sized and shaped in accordance with the optical region 652 which it is positioned to cover. For example, a cross section or projection of the recess 631 onto the optical region 652 may be approximately the same shape and/or size as the optical region 652. In some cases, the recess 631 may be slightly larger than the optical region 652. As will be discussed below, maintaining this space above the optical region 652 facilitates creating an optical window through the overmold 618 in connection with a grinding process and/or a dicing process, for providing access to the optical region 652.

Similar to one or more embodiments described herein, the dimensions of the recess 631 above the optical region 652 of the PIC 600 may be specifically determined in accordance with a grinding process to be performed on the molded memory circuit package 614M. For example, in some cases, the recess 631 extends approximately the same height as the EIC die 604 and memory stack 612 disposed on the PIC 600, or may extend further or thicker than this. In the least, the recess 631 is thick or tall enough such that the recess 631 is exposed after a grinding process has been performed. For example, the sacrificial cap 620 may be sized, shaped, and configured in accordance with a griding process to be performed such that a top portion 630 of the sacrificial cap 620 is removed during the grinding process, exposing the recess 631 underneath.

FIGS. 6D and 6E illustrate example grinding and dicing processes of the molded memory circuit package 614M and neighboring molded package 614M-2, according to at least one embodiment of the present disclosure. In some embodiments, after the overmold 618 has dried, cured, and/or hardened, one or more layers of overmold 618 may be removed. For instance, as shown in FIG. 6D, the molded memory circuit package 614M may be operated on to perform a grinding process 680, which may remove a layer 607 of the molded memory circuit package 614M. For instance, the layer 607 may be grinded, milled, etched, or otherwise removed from the molded memory circuit package 614M. In some cases, the layer 607 may include a portion of the overmold 618. In some cases, a portion of the sacrificial cap 620 is removed in the layer 607 as part of the grinding process 680. For instance, a top portion 630 of the sacrificial cap 620 may correspond with the layer 607 and may be removed by the grinding process 680.

In particular, the grinding process 680 may be implemented in connection with the dimensions and/or geometry of the sacrificial cap 620, and more specifically, the dimensions and/or geometry of the recess 631. For example, the grinding process 680 may be such that it removes the layer 607 at a thickness corresponding with an entirety (or more) of the top portion 630 being removed from the sacrificial cap 620. Accordingly, the sacrificial cap 620 may be sized and configured in accordance with the grinding process 680, based on the various components disposed on the PIC 600. For instance, the sacrificial cap 620 may extend from the PIC 600 a greater distance than a thickness of any electronic components or dies positioned on the PIC 600. This may facilitate the recess 631 extending past the thickness of any components disposed on the PIC 600 such that the grinding process 680 may be performed to remove the top portion 630 of the sacrificial cap 620 down to the recess 631, for example, without contacting or reaching other components disposed on the PIC 600.

As shown, after the grinding process 680 and after the layer 607 (including top portion 630) are removed, an optical path or optical window 642 is now available that provides direct access to the optical region 652 on the PIC 600. For instance, the optical window 642 may extend and/or provide access through the overmold 618, such that the optical region 652 may be directly accessible (e.g., from above) through the overmold 618. For example, the optical window 642 (e.g., corresponding with a dimension of the recess 631) may span substantially all of the optical region 652.

In addition to the grinding process 680, a dicing process 682 may be performed which may dice, cut, or separate the molded memory circuit package 614M and neighboring molded package 614M-2 at the edge 644. For instance, the dicing process 682 may separate, dice, or cut a portion of the sacrificial cap 620 which, as described above, straddles or spans the edge 644. Thus, in addition to being grinded to remove a top portion of the sacrificial cap 620, the sacrificial cap 620 may further be separated (e.g., vertically) between the molded memory circuit package 614M and neighboring molded package 614M-2 via the dicing process 682. For example, a portion of the sacrificial cap 620 may remain on the molded memory circuit package 614M connected to the PIC 600 and/or embedded in the overmold 618, and another portion of the sacrificial cap 620 may remain on the neighboring molded package 614M-2 after the dicing process 682.

The dicing process 682 may create or expose the edge 644 such that the optical region 652 is positioned at the edge, end, or periphery of the molded memory circuit package 614M (e.g., the molded memory circuit package 614 now being a discrete die or chip after dicing). For example, not only does the optical window 642 provide access from above to the optical region 652, but the optical window 642 in conjunction with the diced edge 644 provides vertical or side access to the optical region 652. As shown in FIG. 6E, one or more optical fibers 672 or other optical interface components may be coupled (e.g., horizontally) to the edge coupling features and mechanisms of the optical region 652, such as coupling to the edge coupling components 653. In this way, one or more external or off-chip devices may access the memory resources of the memory stack 612 based on the EIC die 604 transmitting and receiving photonic signals via the photonic interface formed by the optical region 652 and optical fibers.

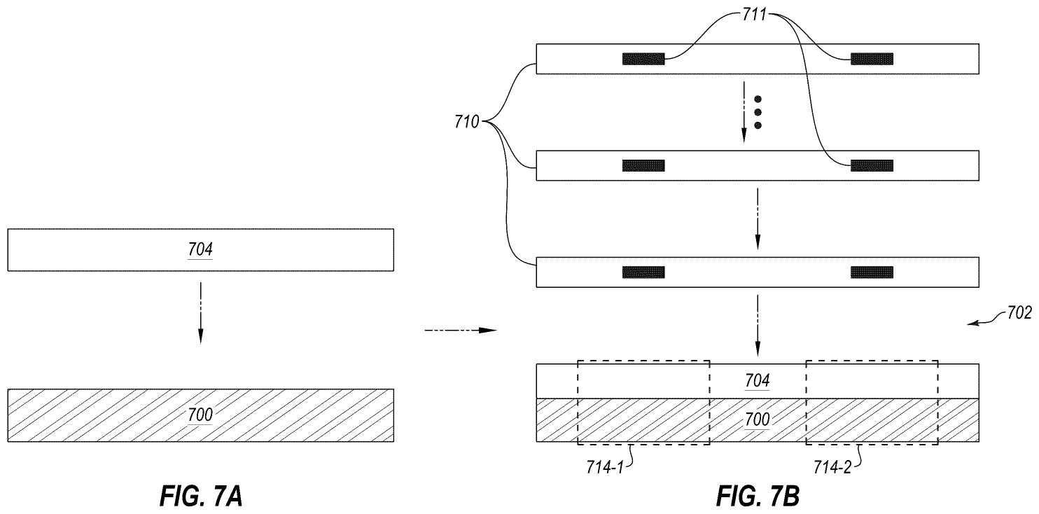

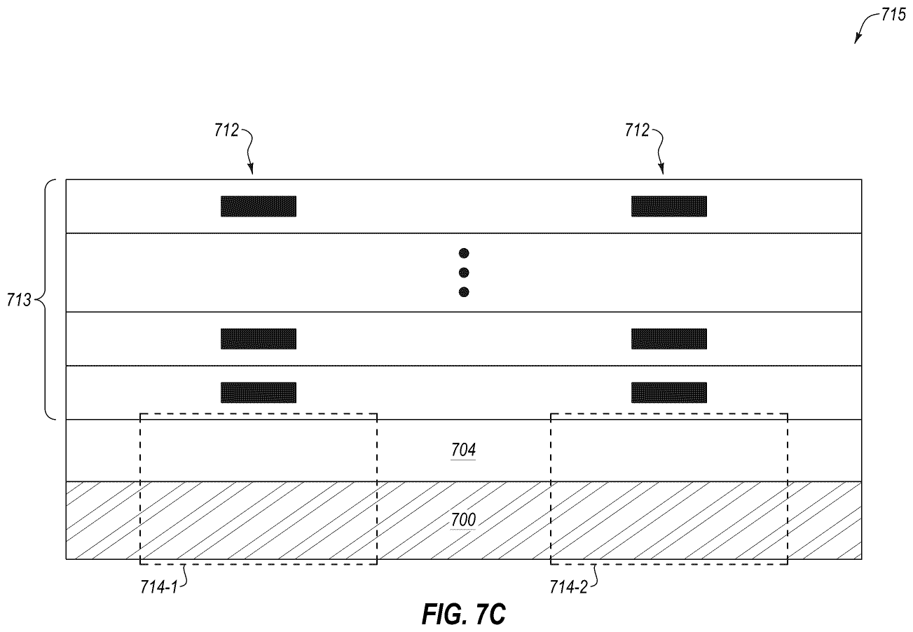

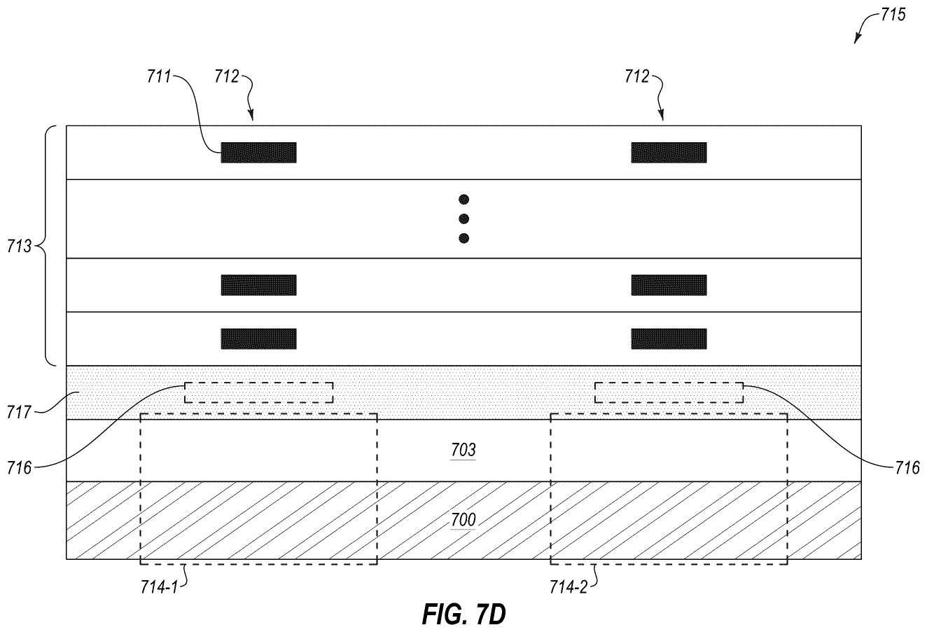

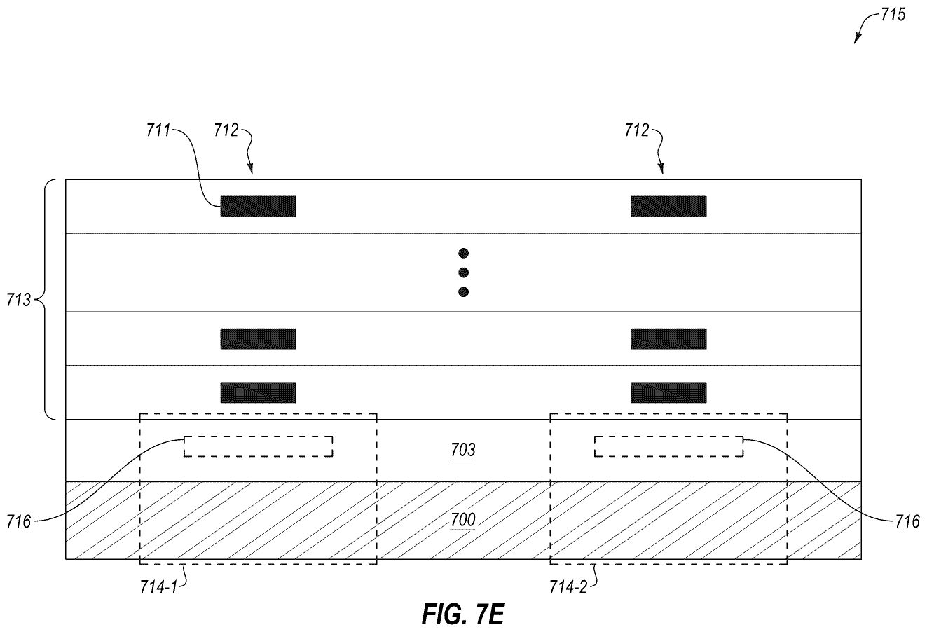

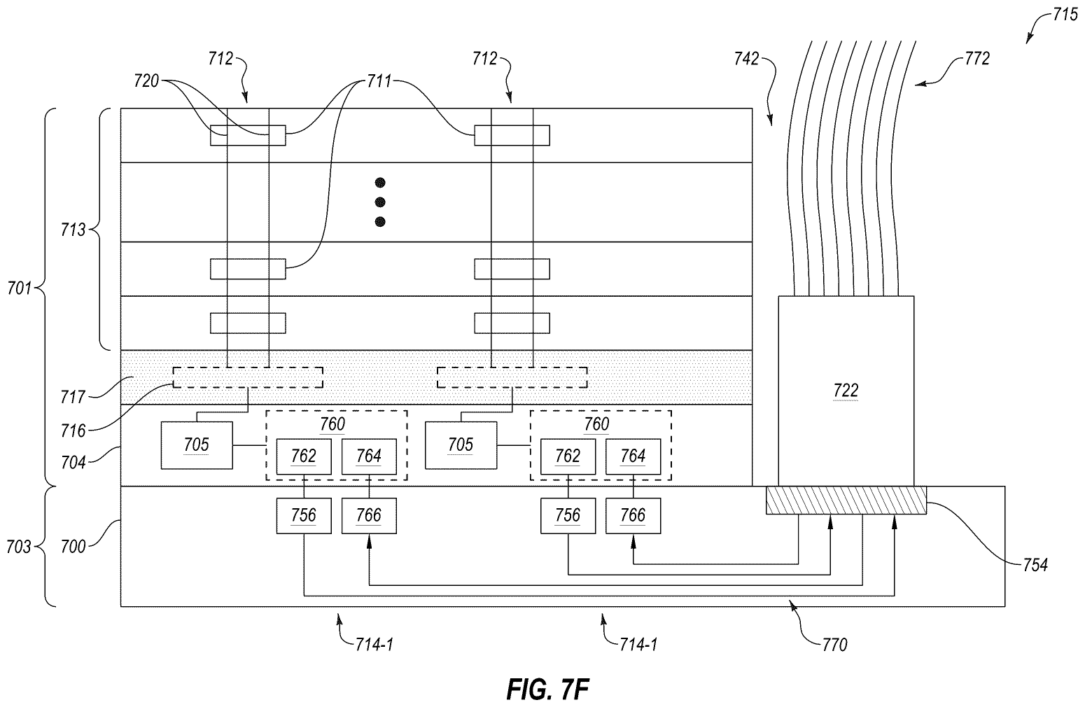

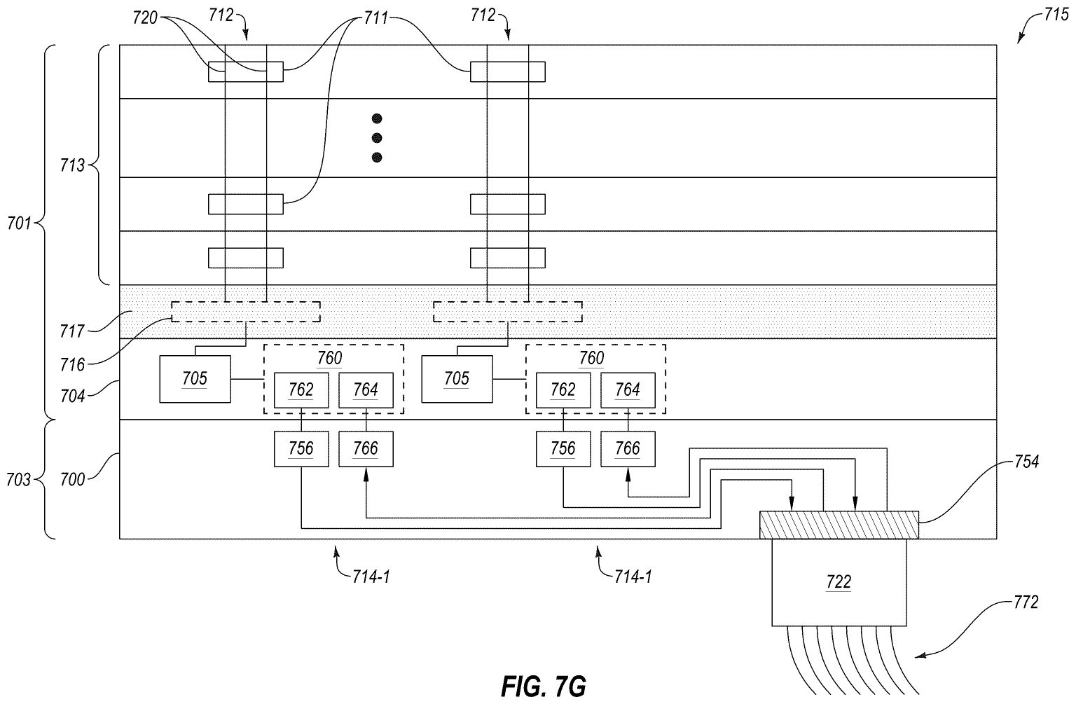

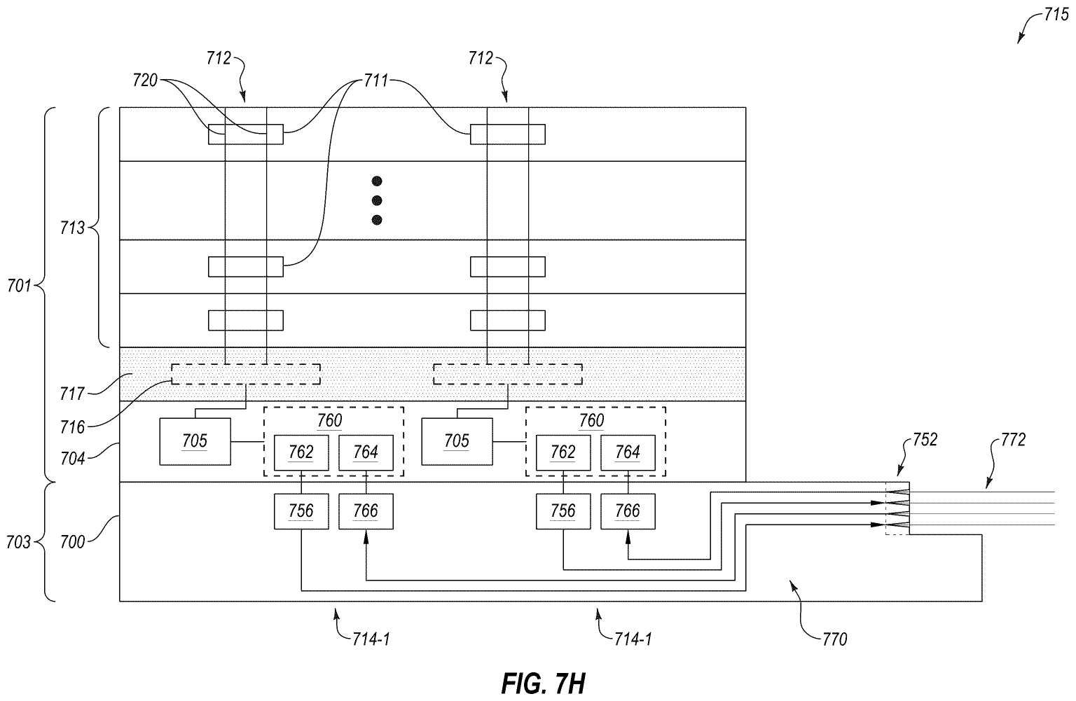

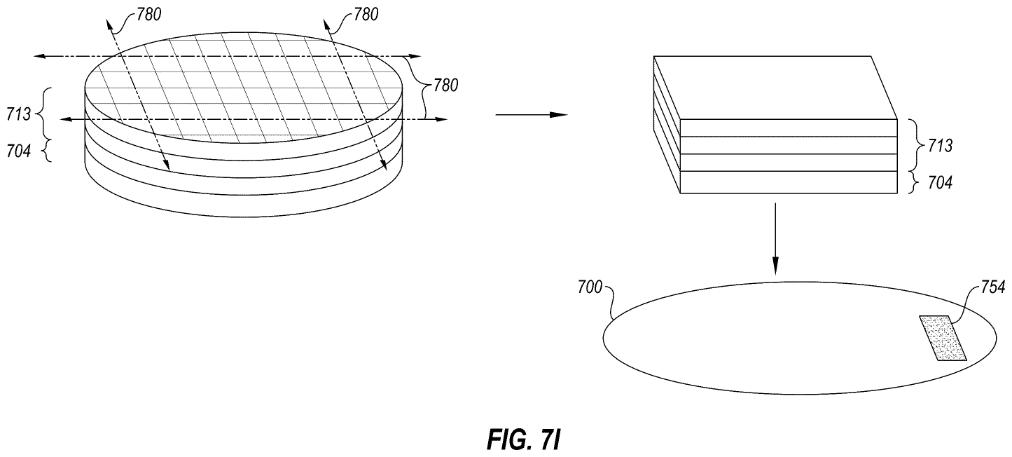

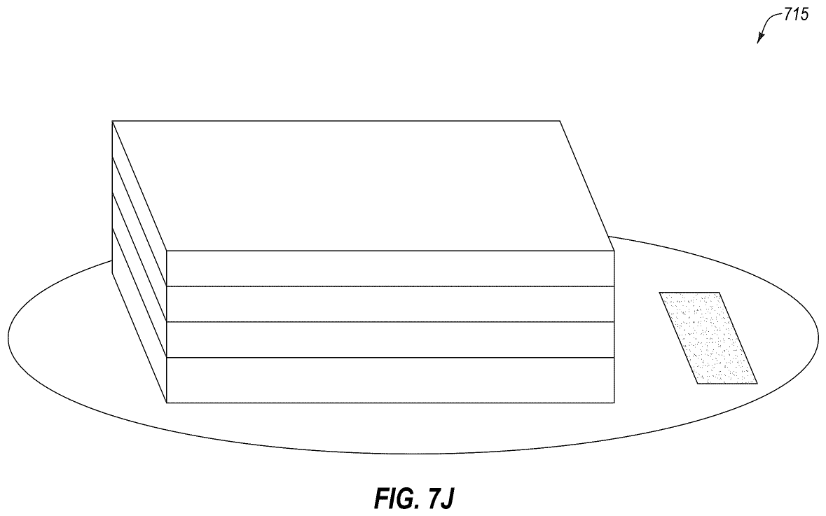

As noted above, one or more embodiments of the memory stacks refer to logic buffers and individually stacked memory layers that are placed (individually) over respective EIC dies. FIGS. 7A-7C illustrate an implementation in which the memory stacks are constructed using wafer layers that are stacked on top of one another to accomplish some of the similar benefits and features described above. For example, FIGS. 7A-7C illustrate an example process for creating a memory hardware wafer stack 713 on a base wafer package 702 to generate a memory wafer package 715. For example, as shown in FIG. 7A, an EIC wafer 704 may be positioned on, connected to, and bonded to a PIC wafer 700. The EIC wafer 704 may be a wafer or wafer structure having one or more electronic components included thereon. For example, the EIC wafer 704 may be similar to the EIC dies as described herein, but in some cases may be an entire wafer or wafer structure, for instance, that has not been cut or diced. For example, the EIC wafer 704 may include multiple EIC dies, circuits, packages, or collections of electronic components which could otherwise be diced into discrete chips or dies. This is represented at a first circuit package 714-1 and a second circuit package 714-2 (collectively circuit packages 714). Additionally, the PIC wafer 700 may be a wafer having photonic components therein as described herein, and, similar to the EIC wafer 704, may be a larger wafer structure which may be uncut or un-diced. Accordingly, the EIC wafer 703 and PIC wafer 700 may each include components which correspond with and which are positioned relative to one another so as to make up the first circuit package 714-1 and the second circuit package 714-2.

While illustrated here as including two discrete regions of circuit packages, the base wafer package 702 may include any number of (the same or different) circuit packages therein, exemplifying the benefits of utilizing an entire wafer structure to construct multiple circuit packages at scale. In some cases, the PIC wafer 700 and the EIC wafer 704 may be substantially the same size and/or shape. In other examples, the PIC wafer 700 may have one or more dimensions that are larger than the EIC wafer 704.

With reference specifically to FIG. 7B, a plurality of memory hardware wafers 710 may be disposed on the base wafer package 702, and more specifically, on a top surface of the EIC wafer 704. The memory hardware wafers 710 may be wafers having one or more memory hardware components 711 or resources thereon, as described herein. The memory hardware wafers 710 may be stacked on top of one another to form a plurality of layers. For example, in some cases the memory hardware wafers 710 are stacked in as many as 4, 6, 8, 10, 16, 20, or 24 layers. In other examples, any number of layers of the memory hardware wafers 710 may be stacked in accordance with the techniques described herein. In the particular example of FIG. 7B, the memory hardware wafers 710 are stacked and layered as mentioned based on stacking the memory hardware wafers 710 on the EIC wafer 704. For example, a first or bottom layer of the memory hardware wafers 710 may be positioned on the EIC wafer 704, after which a next memory hardware wafer 710 may be stacked on the first memory hardware wafer 704, and so on for each of the layers. In this way, a memory hardware wafer stack 713 (FIG. 2C) may be generated based on building up the stack, layer by layer, on the electrical wafer 704.

The memory hardware wafers 710 may be stacked in layers in this way with each layer connected and bonded to each adjacent layer. For example, the layers of the memory hardware wafers 710 may be connected and bonded through hybrid bonding techniques as described herein. The bonding of the memory hardware wafers 710 may establish electrical interconnects between the various layers such that the memory hardware components 711 of each layer may be accessible via the electrical interconnects. For instance, the memory hardware components 711 of each layer may be positioned on the memory hardware wafer 710 in a specific region or location such that they align with corresponding memory hardware components 711 in the various other layers. In this way, the memory hardware components 711 may aligned in one or more vertical stacks at a localized region of the memory hardware wafers 710. For instance, the memory hardware wafers 710 may form various memory stacks 712 from the aligned memory hardware components 711 contained thereon. In some cases, the memory stacks 712 may be positioned and aligned with the circuit packages 714-1, 714-2 defined in the base wafer package 702. For example, the memory stacks 712 may be formed in the memory hardware wafer stack 713 such that a memory stack 712 is positioned on top of each of the first circuit package 714-1 and the second circuit package 714-2. In this way, the memory stacks 712 may be positioned on top of the circuit packages 714-2, 714-2 in a similar way to the other memory stacks as described herein, while contained or formed in a same, singular memory hardware wafer stack 713.

The memory hardware wafer stack 712 may be physically connected to the EIC wafer 704, and be may electronically coupled to hardware components of the EIC wafer 704. For instance, a logic buffer may be connected to the memory hardware wafer stack 712 and to the EIC wafer 704 and may facilitate accessing the memory hardware components 711 of the memory hardware wafer stack(s) 712, as described in connection with FIGS. 7D and 7E. In this way, a memory wafer package 715 may be generated having the EIC wafer 704 disposed on the PIC wafer 700, and the memory hardware wafer stack 713 formed on the EIC wafer 704. In some cases, an overmold may be applied to the memory wafer package 714 to create an overmolded circuit package.

Generating the memory wafer package 714 by disposing and bonding various wafers together (e.g., rather than discrete dies or chips) may provide simplicity, efficiency, and/or ease of manufacturing and/or processing of circuit packages. For example, in some cases, it may be advantageous to manipulate and/or position wafers having a same size, shape, and/or dimension, for example, rather than positioning smaller chips or dies on a larger or different sized PIC wafer. In some cases, forming the memory wafer package 714 from various whole or uncut wafers may provide the benefit of adding mechanical strength and integrity to the resulting wafer package, for example, based on a greater amount of substrate material making up the resulting wafer package, (e.g., rather than the PIC wafer 700 and/or other base substrate providing the base for supporting the entire package).

In other examples, utilizing larger or entire wafer structures as described may facilitate generating multiple circuit packages and/or multiple memory stacks at once. For example, in some cases, the PIC wafer 700 and EIC wafer 704 may have tens, hundreds, or more copies, iterations, or variations of a circuit, package, or collection of components thereon. Rather than dicing these discrete packages from their respective wafers and assembling them at a chip or die level, it may be advantageous to assemble multiple packages at scale, based on bonding the entire wafers together. Similarly, each memory hardware wafer 710 may have multiple copies, iterations, or variations, of memory hardware components 711 thereon at corresponding locations to those of the circuit packages of the base wafer package 702. Thus, by layering and connecting multiple memory hardware wafers 710 to the base wafer package 022, multiple (e.g., many) memory stacks 712 can be generated and connected to underlying circuit packages formed in the base wafer package 702. In some cases, the memory wafer package 715 may be diced to produce discrete memory circuit packages, or the memory wafer package 715 may be left uncut or intact having multiple memory circuit packages formed thereon.

Turning now to FIGS. 7D and 7E, these figures illustrate examples of a logic buffer 716 in relation to the memory hardware wafer stack 712, according to embodiments of the present disclosure. Similar to that described above in connection with FIGS. 2K and 2L, the memory hardware components 711 of the memory hardware wafer stack 713 may be connected to associated hardware components in the EIC wafer 703 via a logic buffer 716. As shown in FIG. 7D, in some cases the memory hardware wafer stack 712 may include a logic buffer wafer 717, which may include circuits and/or components thereon comprising logic buffers 716. Components comprising the logic buffers 716 may be located on the logic buffer wafer 717 as a bottom or first layer of the memory hardware wafer stack 713. The logic buffer wafer 717 may facilitate connecting the memory stacks 712 to their associated circuit packages in the EIC wafer 703, for facilitating communicating thereto. In this way, the hardware memory hardware wafer stack 713 may be implemented with a logic buffer wafer 717 as a bottom or first layer.

As shown in FIG. 7E, in some cases the logic buffer(s) 716 may be included as part of the EIC wafer 704. For example, as described above, the functionality of the logic buffers 716 may be included as part of the corresponding circuit packages 714 in the EIC wafer 704 for facilitating communication with the memory stack 712 formed by the memory hardware wafer stack 712. In this way, each memory stacks 712 may be accessible to an associated circuit package in the EIC wafer 703 via a logic buffer 716 which may be implemented as native, built-in, or co-packaged functionality within the circuit package, without the memory hardware wafer stack 713 including a dedicated logic buffer wafer.

FIGS. 7F-7H illustrate examples of the memory wafer package 715 having various photonic interfaces for facilitating off-chip communication, according to embodiments of the present disclosure. As mentioned above, a base wafer package comprising the EIC wafer 704 positioned on and connected to the PIC wafer 700 may form or define various circuit packages 714 which may each include any of the features and functionalities of the electro-photonic circuit packages as described in connection with FIGS. 10A-12D below. For instance, the EIC wafer 704 may include, at each circuit package 714-1, 714-2, hardware components 705 which may include processing components, memory components, storage components, routing components, communication components, or other functional hardware components. The hardware components 705 may interface with an AMS block 760, which may include electronic transceiver components, such as a modulator driver 762 and a TIA 764. These electronic transceiver components may connect to and interface with photonic transceiver components in the PIC wafer 700, such as a MOD 756 and a PD 766. Accordingly, the hardware components 705 may send and receive signals in the photonic domain.

The hardware components 705 of a given circuit package 714 may be connected to the associated memory stack 712 formed in the hardware memory hardware wafer stack 713 via the logic buffer 716. For example, the memory stack 712 may include one or more electrical interconnects 720 which may pass therethrough and which may connect to each memory hardware die of the memory stack 712. Accordingly, the hardware components 705 may connect to and may access the memory resources of the memory stack 712. While the logic buffer 716 is shown in FIGS. 7F-7H as being implemented by a logic buffer wafer 704 that is a discrete layer of the memory hardware wafer stack 713, it should be understood that in some cases the logic buffer 716 may not be a physical layer of the memory hardware wafer stack 713, but rather, may be implemented as built-in or native functionality of the circuit packages 714 and/or the EIC wafer 704, similar to that shown and described in connection with FIG. 7E above.

In some cases, the memory wafer package 714 is equipped with a photonic interface and/or with photonic interface components. For example, an optical region 754 may be positioned in the PIC wafer 700. In the example shown in FIG. 7F, the optical region 754 may be located at or near a top surface of the PIC wafer 700. For instance, the optical region 754 may be optically accessible at or through the top surface of the PIC wafer 700. In the example shown in FIG. 7G, the optical region 754 may be located at or near a bottom surface of the PIC wafer 700. For instance, the optical region 754 may be optically accessible at or through the bottom surface of the PIC wafer 700. The optical region 754 may be capable of coupling with an optical interface component 722, such as a fiber array unit. For example, the optical interface component 722 may couple to the optical region 254 at the top surface of the PIC 200 (FIG. 7F) or at the bottom surface of the PIC wafer 700 (FIG. 7G).

Each of the circuit packages 714-1, 714-2 may be photonically coupled to the optical region 754 in order to facilitate sending and receiving signals with the hardware components 705 (e.g., via the AMS block 160) through the optical region 754. For example, each of the MODs 756 and PDs 766 may each be connected to the optical region 754 by waveguides 770, which may transmit or direct the flow of photonic signals through discrete regions of the optical region 754. The drivers 762 and TIAs 764 being coupled to the respective MODs 756 and PDs 766 may communicate corresponding electronic signals with the hardware components 205. In this way, each of the circuit packages 714 may be photonically coupled to the optical region 754 for sending and receiving photonic signals to/from the optical region 754. For instance, the memory stacks 712 may be accessible by via photonic communications through the optical region 754 by one or more external devices connected to the optical interface component 722.

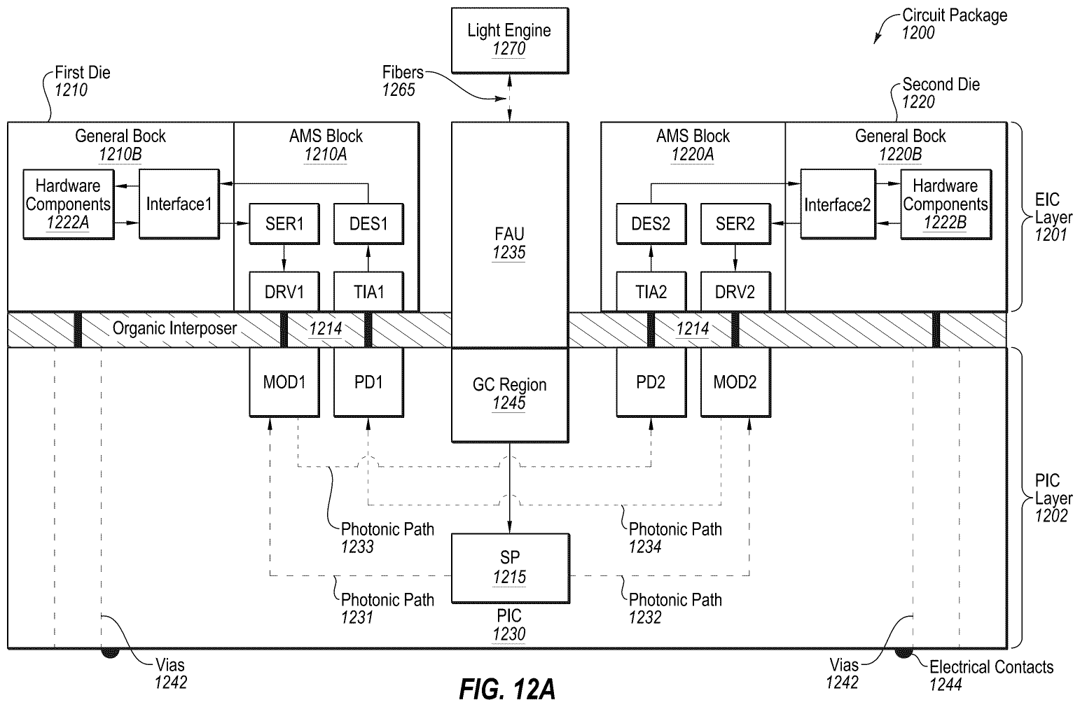

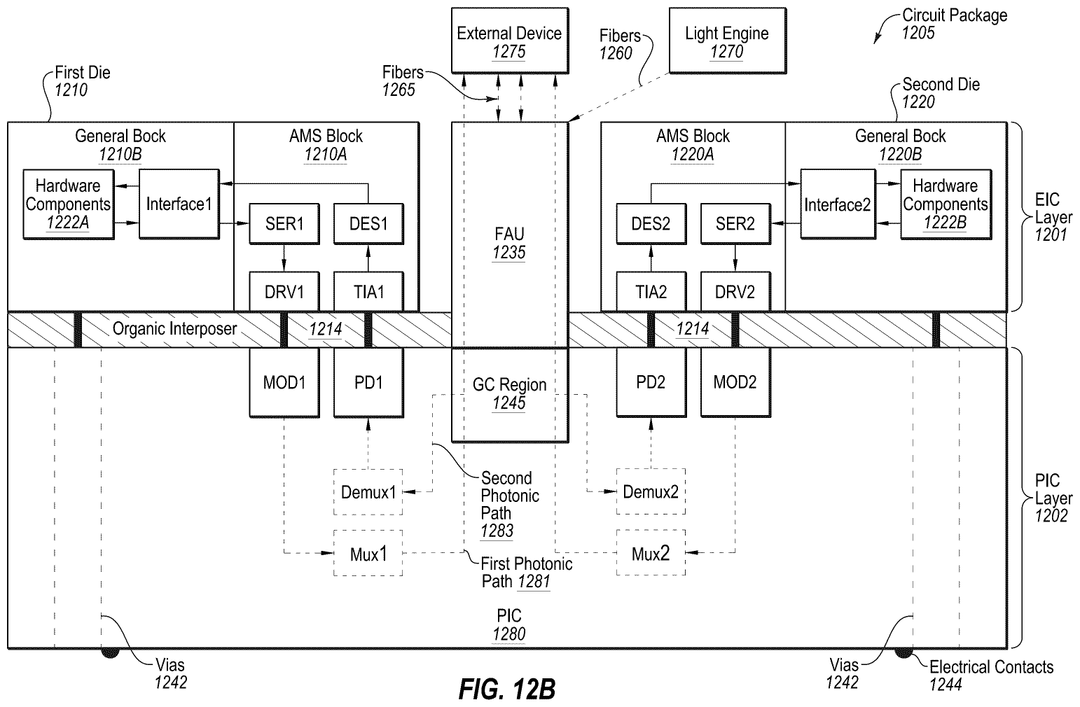

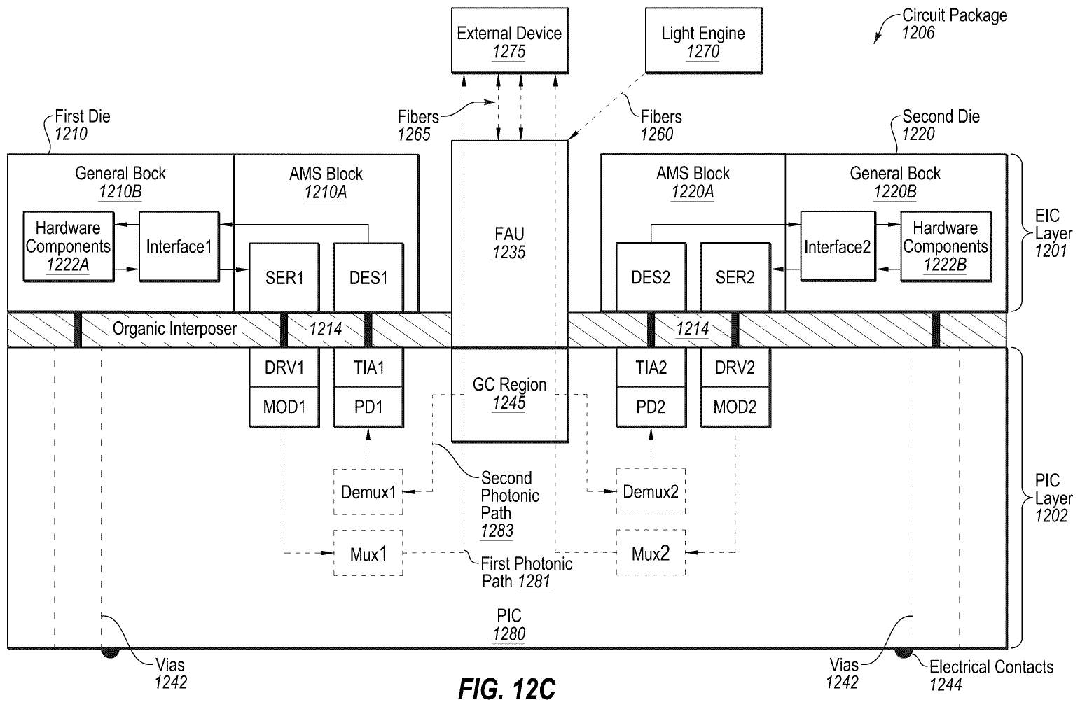

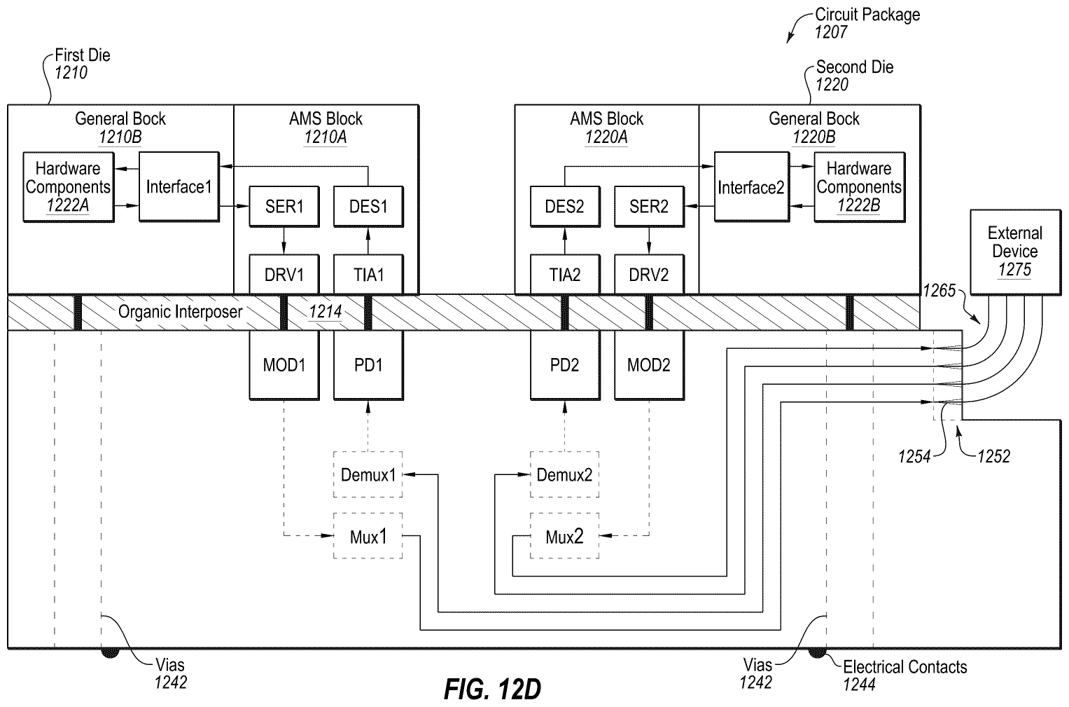

With reference now to FIG. 7H, in some cases the memory wafer package 715 is equipped with an optical region 752 positioned at or near an edge of the PIC 700. For instance, the optical region 752 may include one or more edge couplers. Similar to that described below in connection with FIGS. 12D, the optical region 752 may be a geometry, structure, or other feature formed in the PIC wafer 700 which may facilitate connecting one or more optical fibers 772 at an edge of the PIC wafer 700. The optical region 752 may be positioned on a portion of the PIC wafer 700 that is adjacent, to a lateral side, or positioned away from the EIC wafer 704 and memory hardware wafer stack 713 such that the optical region 752 is accessible for coupling to one or more optical fibers 772. For example, the PIC wafer 700 may have a size and/or shape that is larger than the EIC wafer 704 and the memory hardware wafer stack 713. In a similar manner to other optical regions as discussed herein, the MODs 756 and PDs 766 of the circuit packages 714 may be photonically connected to the optical region 752 via waveguides 770 for transmitting and receiving photonic signals to/from the optical fibers 772.

Additionally, in some cases, the circuit packages 714 are connected to each other by inter-chip photonic channels such that they may communicate with each other via photonic signals traversing the PIC wafer 700. For example, similar to that shown in FIG. 2P, photonic transceiver components of the circuit packages 714 may be connected via waveguides 770 for transmitting photonic signals therebetween through the PIC wafer 700. This inter-chip photonic connection between the circuit packages 714 may be in addition to each of the circuit packages 714 also being photonically coupled to the optical region 754 and/or the optical region 752.

As shown in FIG. 7F, in some cases, an optical window 742 may be formed at least partially through one or more of the wafers of the memory wafer package 715. For example, because the memory wafer package 714 is formed by depositing various (e.g., whole or entire) wafers upon one another and bonding the same together. In some cases, the EIC wafer 704 and/or the memory hardware wafer stack 713 may be sized and/or positioned on the PIC wafer 700 such that the optical region 754 may be exposed via the optical window 742. For instance, in some cases, an optical window 742 is formed through the various layers of wafers deposited on top of the PIC wafer 700 such that a path to the optical region 754 remains through which the optical interface component 722 may connect to the optical region 754.

FIG. 7I illustrates an example of the memory wafer package 715 having an optical window 742 formed therein, according to embodiment of the present disclosure. As shown, each of the wafers comprising the memory hardware wafer stack 713, as well as the EIC wafer 704, may have a cutout 743 therein. For example, the cutout 743 may be cut, diced, etched, or otherwise removed from the respective wafers such that there is a void, passage, or opening through the wafer. In the case of the memory hardware wafer stack 713, the cutout(s) 743 may be formed in each wafer individually and/or separately (e.g., prior to stacking the layers of wafers) and the memory hardware wafer stack 713 may be assembled as described herein to form one cutout 743 that passes through the entire stack. In another example, the wafer layers may be assembled and/or connected to form the memory hardware wafer stack 713, after which the cutout 743 may be formed through the entirety of the stack (i.e., through all of the layers).

The various cutouts 743 in the memory hardware wafer stack 713 and in the EIC wafer 704 may be positioned and/or aligned in accordance with a optical region 754 of the PIC wafer 700. For example, when the memory hardware wafer stack 713 and EIC wafer 704 are assembled on top of the PIC wafer 700, the cutouts 743 may be positioned at, on, or over the optical region 754. In some cases, the cutouts 743 are sized and shaped in accordance with the optical region 754, such as having a same size and/or shape, or even having a larger size and/or shape. In this way, the optical window 742 may be formed or maintained through any of the wafers positioned on top of the PIC wafer 700 (e.g., as shown in FIG. 7F), such that the optical region 754 is optically accessible at a top surface of the PIC wafer 700. For example, an optical interface component 722 may be coupled to the optical region 754 at the top surface of the PIC wafer 700 through the optical window 742 (e.g., through the cutouts 743).

FIG. 7J illustrates another example of the memory hardware wafer stack 713 having an optical region 754 in the PIC wafer 700, according to embodiments of the present disclosure. As shown, in some cases the optical region 754 may be positioned in the PIC wafer 700 at a location that is next to, adjacent, or not beneath the EIC wafer 704 and the memory hardware wafer stack 713. For example, in some cases the PIC wafer 700 may have a size and/or shape that is larger than the EIC wafer 704 and the memory hardware wafer stack 713 such that a portion of the PIC wafer 700 is exposed and/or accessible to a lateral side the EIC wafer 704, corresponding with the location of the optical region 754. In this way, the EIC wafer 704 and memory hardware wafer stack 713 may not overhang, overlap, or cover the optical region 754, and the optical region 754 may be accessible at the top surface of the PIC wafer 700. For example, an optical interface component 722 may couple with the optical region 754 at the top surface of the PIC wafer 700.

FIGS. 7I and 7J illustrate an example of generating the memory wafer package 715 having a optical region 754 accessible to a lateral side of the EIC wafer 704 and memory hardware wafer stack 713, according to embodiments of the present disclosure. For example, as shown, in some cases the EIC wafer 704 and the wafers of the memory hardware wafer stack 713 may be shaped and/or sized (in one or more dimensions) smaller than the PIC wafer 700. For example, through a dicing process 780, the wafers may be diced or cut one or more times to a smaller form factor. While the EIC wafer 704 and memory hardware wafer stack 713 are shown as being diced together or as one unit, it should be understood that this is merely illustrative of the end result, size, and/or shape of these wafers. For example, the EIC wafer 704 may be diced separately from the memory hardware wafer stack 713 and disposed on the PIC wafer 700. Additionally, the wafers of the memory hardware wafer stack 713 may be diced either all together (e.g., after forming the memory hardware wafer stack), or else individually and thereafter assembled into the memory hardware wafer stack 713 in any of the manners described herein.

Accordingly, after dicing, the EIC wafer 704 and memory hardware wafer stack 713 may be assembled on the PIC wafer 700. For example, the EIC wafer 704 may be disposed and connected to the PIC wafer 700, after which the memory hardware wafer stack 713 may be formed on the EIC wafer 704, or else separately formed and disposed on the EIC wafer 704. As shown, the EIC wafer 704 and memory hardware wafer stack 713 may be positioned on the PIC wafer 700 such that a optical region 754 remains exposed or uncovered at the top surface of the PIC wafer 700. For example, because of the smaller size or form factor of the EIC wafer 704 and memory hardware wafer stack 713, these diced wafers may be positioned on the PIC wafer 700 next to, apart from, and/or adjacent the optical region 754.

In some cases, the techniques of FIGS. 7I and 7J may be implemented in connection with a PIC wafer 700 having other types of optical regions thereon, such as optical regions at an edge of the PIC wafer 700 and for facilitating connecting optical interface components at the edge. For instance, other types of optical regions may include edge coupler. Taking this example, the PIC wafer 700 may be somewhat larger than the EIC wafer 701 and memory hardware wafer stack 713 such that, when positioned on the PIC wafer 700, a portion of the PIC wafer 700 remains uncovered by the EIC wafer 703, which portion may contain an optical region at an edge as described herein. Further, while only one optical regions 754 is shown, it should be understood that these techniques may be applicable for positioning an EIC wafer 704 and accompanying memory hardware wafer stack 713 on a PIC wafer 700 for maintaining access to any number of photonic interfaces or optical regions at any number of different locations, such as multiple optical interfaces 754 (e.g., multiple grating couplers, multiple edge couplers, or a combination of one or more grating couplers and one or more edge couplers).

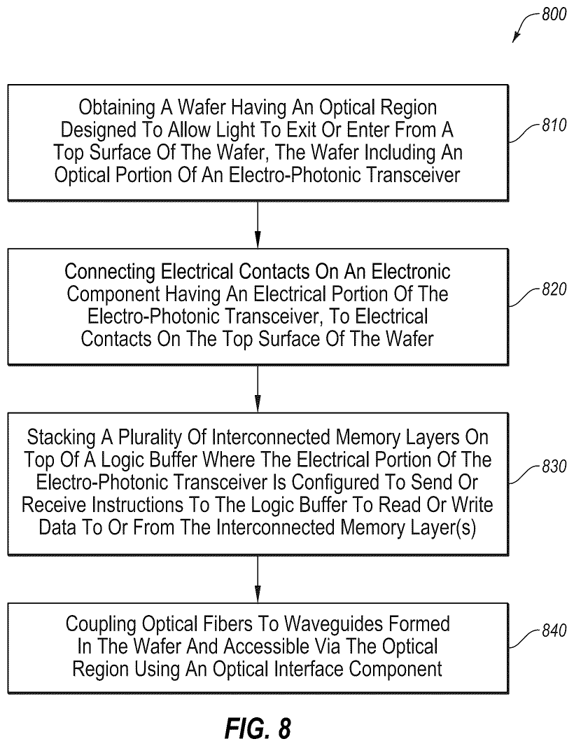

FIG. 8 illustrates an example flow diagram showing a series of acts for generating a memory package in accordance with one or more embodiments. While FIG. 8 illustrates acts according to one embodiment, alternative embodiments may add to, omit, reorder, or modify any of the acts of FIG. 8.

As shown in FIG. 8, a series of act 800 includes an act 810 of obtaining a wafer having an optical region designed to allow light to exit or enter from a top surface of the wafer, the wafer including an optical portion of an electro-photonic transceiver. In one or more embodiments, the act 810 includes obtaining a wafer having an optical region designed to allow light to exit or enter from a top surface of the wafer, the wafer including an optical portion of an electro-photonic transceiver in optical communication with the optical region.

As shown in FIG. 8, the series of acts 800 further includes an act 820 of connecting electrical contacts on an electronic component having an electrical portion of the electro-photonic transceiver, to electrical contacts on the top surface of the wafer. In one or more embodiments, the act 820 includes connecting electrical contacts on an electronic component having an electrical portion of the electro-photonic transceiver, to electrical contacts on the top surface of the wafer and forming electro-optical paths to and from the electronic component to the optical region via waveguides formed within the wafer.

As further shown in FIG. 8, the series of acts 800 includes an act 830 of stacking a plurality of interconnected memory layers on top of a logic buffer where the electrical portion of the electro-photonic transceiver is configured to send or receive instructions to the logic buffer to read or write data to or from the interconnected memory layer(s). In one or more embodiments, the act 830 includes stacking a plurality of interconnected memory layers on top of a logic buffer positioned between the plurality of interconnected memory layers and the electrical portion of the electro-photonic transceiver, wherein the electrical portion of the electro-photonic transceiver is configured to send or receive instructions to the logic buffer to read or write data to or from one or more of the interconnected memory layers of the plurality of interconnected memory layers.

As further shown in FIG. 8, the series of acts 800 includes an act 840 of coupling optical fibers to waveguides formed in the wafer and accessible via the optical region using an optical interface component. In one or more embodiments, the act 840 includes coupling a plurality of optical fibers to waveguides formed in the wafer and accessible via the optical region using an optical interface component.

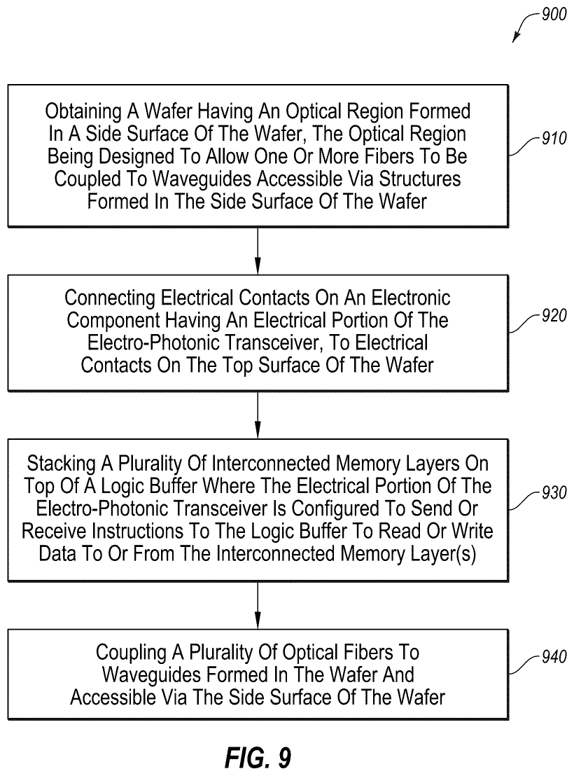

Moving on, FIG. 9 illustrates another example series of acts 900 related to generating a memory package. As shown in FIG. 9, the series of acts 900 includes an act 910 of obtaining a wafer having an optical region formed in a side surface of the wafer, the optical region being designed to allow one or more fibers to be coupled to waveguides accessible via structures formed in the side surface of the wafer. In one or more embodiments, the act 810 includes obtaining a wafer having an optical region formed in a side surface of the wafer, the optical region being designed to allow one or more fibers to be coupled to waveguides that are formed within the wafer and accessible via one or more structures formed in the side surface of the wafer.

As further shown in FIG. 9, the series of acts 900 includes an act 920 of connecting electrical contacts on an electronic component having an electrical portion of the electro-photonic transceiver, to electrical contacts on the top surface of the wafer. In one or more embodiments, the act 820 includes connecting electrical contacts on an electronic component having an electrical portion of the electro-photonic transceiver to electrical contacts on the top surface of the wafer and forming electro-optical paths to and from the electronic component to the optical region via waveguides formed within the wafer.

As further shown in FIG. 9, the series of acts 900 includes an act 930 of stacking a plurality of interconnected memory layers on top of a logic buffer where the electrical portion of the electro-photonic transceiver is configured to send or receive instructions to the logic buffer to read or write data to or from the interconnected memory layer(s). In one or more embodiments, the act 830 includes stacking a plurality of interconnected memory layers on top of a logic buffer positioned between the plurality of interconnected memory layers and the electrical portion of the electro-photonic transceiver, wherein the electrical portion of the electro-photonic transceiver is configured to send or receive instructions to the logic buffer to read or write data to or from one or more of the interconnected memory layers of the plurality of interconnected memory layers.

As further shown in FIG. 9, the series of acts 900 includes an act 940 of coupling a plurality of optical fibers to waveguides formed in the wafer and accessible via the side surface of the wafer. In one or more embodiments, the act 840 includes coupling a plurality of optical fibers to waveguides formed in the wafer and accessible via the one or more structures formed in the side surface of the wafer.

Additional details are now provided regarding circuit packages, including electro-photonic circuit packages. In particular, FIGS. 10A-10B, FIG. 11, and FIG. 12A-12D provide additional details regarding wafers, circuit packages, bidirectional photonic paths, and optical connections via an optical interface component (e.g., an FAU, edge coupling components).

As used herein, the term “photonic” refers to the use of light and/or photons for various applications. For instance, a “photonic path,” “photonic channel,” “photonic element,” “photonic signal,” and other similar uses operate based on the transmission of electromagnetic radiation as photons. For instance, in some cases photonic refers to the transmission, manipulation, and/or use of light, such as light in the visible spectrum, or from about 400 to about 700 nm. In some cases, photonic refers specifically to laser light. For example, in some cases photonic may include light or electromagnetic radiation in one or more of the ultraviolet spectrum (100 to 400 nm), the visible light spectrum (400 to 700 nm), or the infrared spectrum (700 nm to 1 mm). For example, in some cases herein, photons may be transmitted via a laser light source operating in any of these (or a smaller range) of wavelengths. In some cases, the term “optical” is used interchangeably herein to mean photonic.

Accordingly, a photonic path or photonic channel refers to the trajectory that photons (e.g., particles of light) follow through a medium or a device designed to guide or manipulate light. A photonic path can include waveguides, fibers, free space transmission paths, and other elements that provide precise control over photon behavior. In some instances, a photonic path includes photonic elements which route light through a medium. In various implementations, a photonic path corresponds to both macroscopic (classical optics) and microscopic (quantum optics) manipulations of photons.

In various implementations, various components of a circuit package may be created using wafers. For example, FIG. 10A corresponds to using wafers to create circuit package components according to some implementations. To illustrate, FIG. 10A shows a top view of a wafer 1000 and a die 1002, which may be included in one or more circuit packages (e.g., microelectronic packages).

In some instances, the wafer 1000 is composed of semiconductor material and includes one or more dies having integrated circuit (IC) structures formed on the surface of the wafer 1000. As shown, the wafer 1000 may comprise multiple (and often many) dies, which may be copies or iterations of the same IC, or may be ICs of different variations. Each of the dies may be a unit of a semiconductor product or other hardware that includes a suitable IC. After the fabrication of the semiconductor product is complete, the wafer 1000 may undergo a singulation process in which the dies are separated from one another to provide discrete “chips” of the semiconductor product. The die 1002, and at least one other die, may be included in a microelectronic package with a PIC. Accordingly, a die as used herein may refer to a section or portion of a larger wafer structure having an IC formed thereon or may refer to that section or portion having been diced or cut from the wafer as a discrete chip.

A PIC can be formed in a second process using a second wafer (not shown) in a manner analogous to the fabrication of the die 1002. While the die 1002 may be used to fabricate electronic elements, such as EIC components, a PIC may be fabricated with optical components. In some implementations, the PIC can be embedded into a package substrate. The package substrate may be considered a cored or coreless substrate and may include one or more layers of dielectric material, which may be organic or inorganic.

The package substrate may further include one or more conductive elements, such as vias, pads, traces, microstrips, strip lines, etc. The conductive elements may be internal to, or on the surface of, the package substrate. Generally, the conductive elements may allow for the routing of signals through the package substrate or between elements coupled to the package substrate. In some implementations, the package substrate may be a printed circuit board (PCB), an interposer (e.g., an organic interposer), a motherboard, or other types of substrate.

In one or more implementations, the wafer 1000 or the die 1002 may include a memory device, a computing device, a storage device, or a combination thereof (examples include, but are not limited to, a random-access memory (RAM) device (such as a static RAM (SRAM) device, a magnetic RAM (MRAM) device, a resistive RAM (RRAM) device, or a conductive-bridging RAM (CBRAM) device), a logic device (e.g., an AND, OR, NAND, NOR, or EXOR gate), a NANO flash memory, a solid-state drive (SSD) memory, a NOR flash memory, a CMOS memory, a thin-film transistor-based memory, a phase-change memory (PCM), a storage class memory (SCM), a magneto-resistive memory (MRAM), a resistive RAM, a DRAM, a high bandwidth memory (HBM), a DOR-based DRAM, a DIMM memory, a CPU, a GPU, an MPU, a tensor engine, a load/store unit (LDSU), a neural compute engine, a dot-product and/or convolution engine, a field-programmable gate array (FPGA), an artificial intelligence (AI) accelerator, or any other suitable circuit element.

Multiple instances of these devices may be combined on a single die. For example, the die 1002 may include a memory comprising multiple memory arrays, one or more processors, other logic, communication circuits, and power management functions. The die may operate to execute instructions stored in the memory array or otherwise interact with the memory array using the processors on die 1002.

As an additional example of using wafers, FIG. 10B corresponds to components formed on wafers, including one or more circuit packages according to some implementations. To illustrate, FIG. 10B shows a top view of a wafer 1010 having various components disposed thereon. For example, one or more circuit packages 1012 (e.g., electro-photonic circuit packages) may be formed from various electronic components disposed on a corresponding portion of the wafer 1010.

In some cases, the wafer 1010 may be composed of a substrate material such as silicon or another substrate material. The substrate may include one or more layers of a dielectric material, which may be organic or inorganic. The wafer 1010 may be a PIC wafer having photonic components and/or an EIC wafer having electronic components. In various implementations, the wafer 1010 provides various photonic interfaces, channels, photonic components, and other photonic features which, in connection with corresponding electronic components, may form one or more circuit packages 1012.

Similar to the above description, the wafer 1010 may further include one or more conductive elements, such as vertical interconnect accesses (vias), pads, traces, microstrips, strip lines, etc. The conductive elements may be internal to, or on the surface of, the wafer 1010. Generally, the conductive elements may allow for the routing of signals (e.g., power and/or communication signals) through the wafer 1010 or between elements coupled to the wafer 1010. In some implementations, the wafer 1010 may be a PCB, PIC substrate, an interposer (e.g., organic interposer), a motherboard, or another type of substrate.

As mentioned, the one or more circuit packages 1012, including electro-photonic circuit packages, may be formed from various electronic components disposed on the wafer 1010. In some cases, the electronic components are coupled to photonic components in the wafer 1010. In various implementations, the one or more circuit packages 1012 include a memory device, a computing device, a storage device, or a combination thereof.

Multiple instances of these examples may be combined in a circuit package. For example, a circuit package may include a memory comprising multiple memory arrays, one or more processors, other logic, communication circuits, and power management functions. Furthermore, the circuit package may execute instructions stored in the memory array or otherwise interact with the memory array using the processors on the one or more circuit packages 1012.

In some cases, a single wafer may be advantageously manufactured and utilized for producing several circuit packages. For example, after the fabrication and/or assembly of the circuit packages is complete, the wafer 1010 may undergo a singulation (e.g., dicing) process in which individual circuit packages are separated from one another to provide discrete “chips,” as mentioned above. An electro-photonic circuit package may include any of the features and/or functionalities according to any of the circuit packages described in this document.

In some cases, each of the one or more circuit packages 1012 of the wafer 1010 is the same. In various implementations, one or more of the one or more circuit packages 1012 (e.g., electro-photonic circuit packages) are configured differently.

In one or more implementations, the wafer 1010 may be implemented in connection with various processing equipment by positioning, supporting, and/or securing the wafer 1010 with respect to the processing equipment. In some cases, the processing equipment may manipulate, process, or otherwise operate on the wafer 1010 as part of forming the one or more circuit packages 1012, such as to form one or more TSVs at least partially through the wafer 1010, to dispose, position, and/or bond dies to the wafer 1010, to form overmolding on the wafer 1010, or other processes.

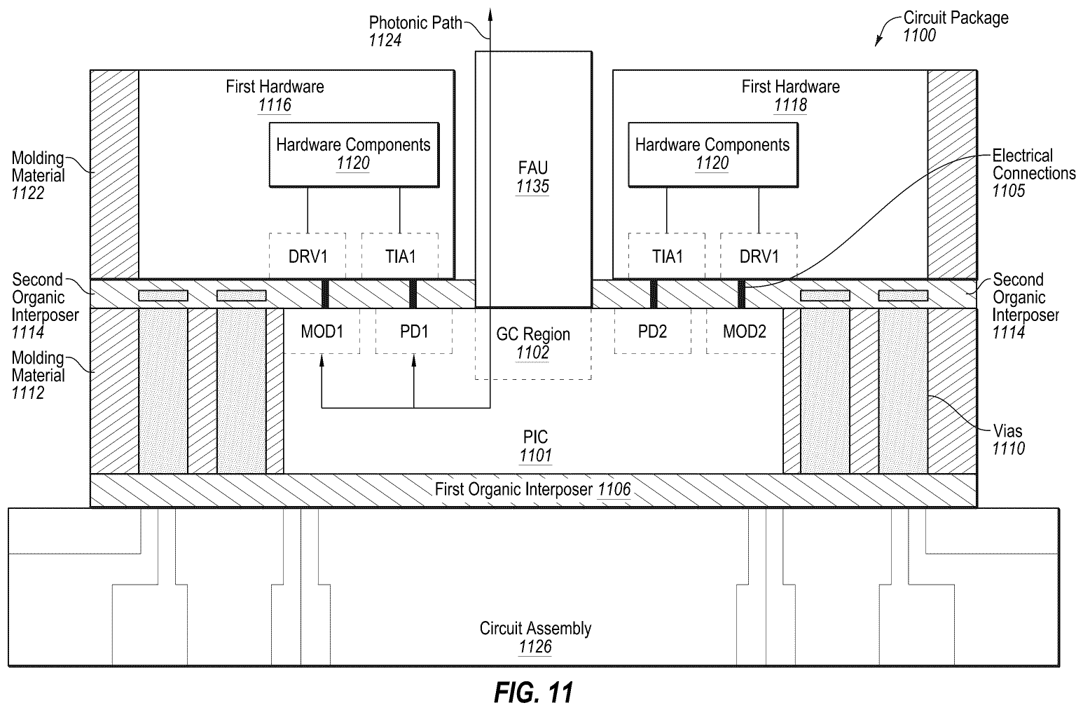

As mentioned above, circuit packages can include various components and connections. To illustrate, FIG. 11 shows an example side-view cross-section diagram of a circuit package that includes various components and that is coupled to a fiber array unit. In particular, FIG. 11 illustrates an example circuit package having various PIC components and EIC components according to some implementations. While FIG. 11 provides one example implementation of a circuit package that may be used in connection with a PIC and other circuit packages described in this document, FIG. 11 is not intended to limit all circuit packages.

As shown, FIG. 11 includes a circuit package 1100 with a PIC 1101, a first hardware 1116 (e.g., a first die), and a second hardware 1118 (e.g., a second die), each having one or more hardware components 1120 and/or hardware elements. As shown, the PIC 1101 includes a GC region 1102 that allows photonic (e.g., optical or light) signals to enter and exit the PIC 1101. In many implementations, the GC region 1102 is coupled to an FAU 1135, which sits between an internal cavity area within a second organic interposer 1114.

As shown in FIG. 11, the PIC 1101 is positioned over a first organic interposer 1106. The first organic interposer 1106 may be a redistribution layer (RDL) that provides any number of connection structures (e.g., interconnects or connection elements) through which components of the circuit package 1100 and a circuit assembly 1126 (e.g., a substrate) may communicate. For example, in some instances, the circuit assembly 1126 is coupled to electrical or electro-photonic components that enable electrical communications to pass between the circuit package 1100 and other components that are electrically coupled to the circuit assembly 1126.

The first organic interposer 1106 (and organic interposer layers such as the second organic interposer 1114) may refer to a layer having a variety of thicknesses and which includes one or more input/output (I/O) pads (electrical connection elements) that provide connectivity for electrical elements of the circuit package to communicate electronically with other elements of the circuit package. The organic interposer layers (e.g., the first organic interposer 1106 and the second organic interposer 1114) may include wiring, interconnects, and other components that enable components of the circuit package 1200 to be electrically coupled to components of one or more additional electronic packages.

In various implementations, the circuit package 1100 provides optically accessible co-packaged optics to connect one or more external packages to the PIC 1101. Indeed, the GC region 1102 couples to the FAU 1135 (or another optical interface component) such that some or all of a bidirectional photonic path within the circuit package 1100 photonically communicates with a light engine or another external device. In turn, the bidirectional photonic path allows these external components to communicate with the hardware components (e.g., the first hardware 1116 and the second hardware 1118) of the circuit package 1100 via a photonic path 1124.

The circuit package 1100 also includes vias 1110 (e.g., conductive through vias such as through-silicon vias (TSVs), through-chip vias, or through-substrate vias). The vias 1110 may be manufactured in any known way so electrical signals (such as power and control signals) can travel between the organic interposers. The vias 1110 provide interconnectivity between different layers of an electrical system within the circuit package 1100. In addition, it will be understood that while FIG. 11 illustrates four of the vias 1110, the circuit package 1100 may include any number of the vias 1110 in various configurations. Further, while FIG. 11 illustrates a side view showing a single row of vias 1110, additional vias may be manufactured toward additional axes (e.g., y-axis, z-axis) relative to the side view shown.

In some implementations, the vias 1110 are formed by etching, removing, or otherwise forming a channel void, conduit, or passage, then depositing one or more conductive layers in the channel. In some cases, the vias may pass entirely from a top surface to the bottom surface of a substrate or material (e.g., an organic interposer). In some cases, the vias may connect to one or more conductive layers, such as to one or more organic interposers. In this way, the vias 1110 may facilitate connecting one or more components positioned on opposite surfaces of an organic interposer, such as connecting EIC components in a hardware or die to corresponding components in a PIC opposite the organic interposer. Additionally, vias may facilitate providing power transmission to various hardware components of the electrical dies by transmitting the power from or through the bottom surface of the circuit package 1100.

As further shown in FIG. 11, the circuit package 1100 includes molding materials 1112, 1122 deposited as part of the process of manufacturing the circuit package 1100. The molding materials 1112, 1122 may be made from a variety of materials having various properties. For example, in one or more implementations, the molding materials 1112, 1122 are epoxy molding compounds in a liquid form that secure elements of the circuit package 1100 in place and cover certain elements contained within the structure of the circuit package 1100.

As shown in FIG. 11, the circuit package 1100 includes a second organic interposer 1114. As mentioned above, the second organic interposer 1114 may be an RDL that provides any number of connection structures (e.g., interconnects) through which components of the circuit package 1100 may communicate. For example, the second organic interposer 1114 includes connective elements and/or interconnects between the vias 1110 and the hardware components (e.g., the first hardware 1116 and the second hardware 1118) within the electronic portion (e.g., the electrical layer) of the circuit package 1100. The second organic interposer 1114 also includes electrical connections 1105 (e.g., electrical interconnects or interconnections, such as copper pillars or wires) between the hardware components and the photonic components (e.g., MOD1, MOD2, PD1, and PD2) in the PIC 1101.

As further shown in FIG. 11, the circuit package 1100 includes connected hardware components (e.g., dies having EIC components) attached above the second organic interposer 1114. In some implementations, the hardware components may include analog-mixed signal (AMS) blocks with components for facilitating the transmission of signals between an electronic domain and a photonic domain. For instance, the AMS blocks include photonic modulator drivers (DRV1, DRV2) for controlling associated photonic modulators (MOD1, MOD2). The AMS blocks can also include serializers and de serializers between the photonic modulators and hardware components (as shown in examples below), The modulators (MOD1, MOD2) receive photonic carrier signals and encode data into the carrier signals to transmit, via waveguides (e.g., a portion of the photonic path 1124 located on the PIC 1101), encoded or modulated photonic signals.

In various implementations, the AMS blocks also include transimpedance amplifiers (TIA1, TIA2) for receiving, through a connection to associated photo detectors (PD1, PD2), encoded photonic signals via one or more waveguides. In various implementations, the AMS blocks communicate with electrical hardware blocks (e.g., hardware components), which may refer to a variety of hardware blocks or dies, including EIC die(s) and/or application-specific integrated circuit (ASIC) die(s) having one or more of the components described in this document.

The electrical components of the electrical dies, such as the drivers (DRV1, DRV2) and the TIAs (TIA1, TIA2), may be connected to the corresponding photonic components in the PIC 1101, such as MODs (MOD1, MOD2) and PDs (PD1, PD2), through electrical connections 1105 (e.g., electrical interconnects). For example, the electrical connections 1105 may be solder bumps, copper pillars, microbumps, or other interconnects for facilitating a connection of components at the surface of a wafer.

The electrical connections 1105 may be printed, deposited, or otherwise positioned on a wafer in accordance with the topography, architecture, or layout of the photonic components in the PIC 1101. For instance, the electrical connections 1105 may be positioned on the surface of a wafer and may form a map or guide for orienting the positioning of the electrical dies (e.g., the first hardware 1216 and the second hardware 1118) on a wafer. In this way, disposing, positioning, bonding, or connecting components of EIC components with each electrical hardware to the wafer may include precisely aligning the EIC components with corresponding electrical connections to form electrical connections.

As mentioned above, in various implementations, the circuit package 1100 is an electro-photonic circuit package that performs one or more computing, memory, or other functionalities and may communicate (e.g., transmit and/or receive) data via photonic signals. Indeed, the circuit package 1100 may facilitate intra-chip electro-photonic communication as well as inter-chip electro-photonic communication.

The circuit package 1100 includes a first hardware 1116 and a second hardware 1118, which may include one or more hardware components 1120. The first hardware 1116 and the second hardware 1118 may have similar or different types of hardware components. For example, the first hardware 1116 includes an ASIC chip that has been programmed, customized, or otherwise configured for a particular use. The first hardware 1116 may additionally or alternatively include other types of hardware components (e.g., electrical hardware components).

The second hardware 1118 may include a similar or different type of hardware components as the first hardware 1116. For example, in one or more implementations, the second hardware 1118 includes high bandwidth memory (HBM) hardware, a CPU, a GPU, a tensor engine, a neural compute engine, or an AI accelerator. Other implementations may include other types of hardware components. In one or more implementations, one or both of the hardware components are electronic hardware components.

While not shown in the illustrated example in FIG. 11, additional components and layers may be manufactured or otherwise added onto the surface of the circuit package 1200. For example, one or more additional distribution layers may be added, and additional circuitry or hardware may be connected having a similar configuration as discussed in connection with any examples discussed herein.

As mentioned, the circuit package 1100 couples with the FAU 1135 or another type of optical interface (O/I) component(s), which attaches to the GC region 1102 of the PIC 1101 of the circuit package 1100. The FAU 1135 allows for optical fibers to be connected to the circuit package 1100. Indeed, the interface block allows for an off-chip bidirectional photonic link to be created between the package hardware and external devices. In some implementations, the FAU 1135 couples one or more optical fibers for transmitting photonic signals to and/or from the PIC 1101 via the GC region 1102.

In some implementations, the FAU 1135 and the GC region 1102 may facilitate receiving and transmitting (e.g., encoded) photonic signals between the circuit package 1100 and other (e.g., off-chip) circuit packages. The GC region 1102 of the PIC 1101 may be an optical region that utilizes a photonic path or photonic connection with the FAU 1135. For example, the FAU 1135 directly mounts or connects to the GC region 1102 such that photonic signals are transmitted directly between GCs in the GC region 1102 and corresponding optical elements in the FAU 1135.

FIGS. 12A-12D illustrate example versions of circuit packages that create a photonic path between a circuit package and one or more circuit packages and/or external devices. Similar to the above description, the packages include a GC region (GC) within a PIC coupled to an FAU (e.g., an optical interface O/I component). In some implementations, the PIC includes a GC region on the bottom surface, which enables the FAU or other optical interface component(s) to couple to the GC region on the bottom of the PIC. In one or more the following illustrated examples, a GC region is shown that is positioned at various locations on a PIC. For example, in one or more of the illustrated examples, a GC region is shown positioned between two dies. It will be appreciated that this positioning is provided by way of example for convenience in showing example couplings between the GC region and multiple dies (via waveguides and other optical components formed within the PIC). Other implementations may include a GC region positions on a side area or around a perimeter of a PIC such that electrical dies positioned within the perimeter can be coupled to the GC region on the side area of the PIC.

FIG. 12A shows an example package 1200 having an EIC layer 1201 with a first die 1210 and a second die 1220 having intra-chip connections therebetween. The circuit package 1200 also includes a PIC layer 1202 that includes the PIC 1230. To illustrate, FIG. 12A shows photonic paths starting at a light engine 1270 that pass through the FAU 1235 and the GC region 1245 to provide light to a PIC 1230. Additionally, the package 1200 includes a first die 1210, divided into a general block 1210B that may include various processing, storage, and communication functions and/or components (e.g., Interface1 and hardware components 1222A), and an AMS block 1210A that includes analog/mixed-signal circuits for interfacing with the PIC 1230. The AMS block 1210A of the first die 1210 may include a driver (DRV1), a transimpedance amplifier (TIA1), a serializer (SER1), and a deserializer (DES1). An AMS block 1220A of the second die 1220 may include a driver (DRV2), a transimpedance amplifier (TIA2), a serializer (SER1), and a deserializer (DES2). A general block 1220B of the second die 1220 may include various processing, storage, and communication functions and/or components (e.g., Interface 2 and hardware components 1222B). In some instances, the package includes molding material surrounding the PIC 1230 (e.g., an optical substrate).

As shown in FIG. 12A, the light engine 1270 (e.g., laser light source) transmits light via fibers 1260 to the FAU 1235 and from the FAU 1235 inside the PIC 1230 via the GC region 1245. In some instances, the GC region and the FAU is located on the bottom of the PIC, as described above. Once inside the PIC 1230, the light travels to a splitter 1215 (SP) that distributes the light over two different photonic paths 1231 and 1232 towards modulator MOD1 and modulator MOD2. Example modulator types include a Mach-Zehnder interferometer (MZI), ring resonator, electro-optic modulator (EOM), acousto-optic modulator (AOM), liquid crystal modulator (LCM), and digital micromirror device (DMD).

In one or more implementations, the splitter 1215, or a splitter tree, distributes the light over more than two different photonic paths to additional modulators. A photonic path may be implemented with any suitable optical transmission medium and may include a mixture of waveguides, fibers, and/or free-space optical transmission paths.

Modulator MOD1 modulates the light it receives from the splitter 1215 with information from driver DRV1 and transmits the modulated light to photodetector PD2 via photonic path 1233. Photodetector PD2 converts the received modulated light into an electrical signal for the second die 1220. Driver DRV1 serializer and SER1 in the first die 1210, together with transimpedance amplifier TIA2, and a deserializer DES2 in the second die 1220, along with modulator MOD1, photonic path 1233, and photodetector PD2, these elements form a data channel, or a unidirectional electro-photonic link, from the first die 1210 to the second die 1220.

Similarly, modulator MOD2 modulates the light it receives from the splitter 1215 with information from driver DRV2 and transmits the modulated light to photodetector PD1 via photonic path 1234. Photodetector PD1 converts the received modulated light into an electrical signal for the first die 1210. Driver 2 and serializer SER2 in the second die 1220, together with transimpedance amplifier TIA1 and deserializer DES1 in the first die 1210, along with modulator MOD2, photonic path 1234, and photodetector PD1, these elements form a data channel, or a unidirectional electro-photonic link, from the second die 1220 to the first die 1210.

As shown in FIG. 12A, the PIC 1230 (e.g., a photonic IC) is attached to an organic interposer 1214. The organic interposer 1214 may include a bondpad pattern (e.g., an electrical connection element) located over MOD1 and PD1 that matches a bondpad pattern on the first die 1210 located under DRV1 and TIA1, or is otherwise configured to form an electrical interconnection between the respective components. The organic interposer 1214 may also include a bondpad pattern located over PD2 and MOD2 that matches a bondpad pattern on the second die 1220 located under TIA2 and DRV2, or is otherwise configured to form an electrical interconnection between the respective components.

Two or more bondpads of the bondpad pattern on the first die 1210 are physically and electrically coupled with two or more bondpads of the bondpad pattern in the organic interposer 1214. Similarly, two or more bondpads of the bondpad pattern on the second die 1220 are physically and electrically coupled with two or more bondpads of the bondpad pattern in the organic interposer 1214.

In one or more implementations, the connective elements (e.g., interconnects) in the organic interposer 1214 connect the dies (e.g., the first die 1210 and/or the second die 1220) to the top surface of the PIC 1230. In addition, the interconnects may be implemented using a variety of structures, including copper pillars, solder connections, pads (e.g., bondpads), bump attachments, vias, or any variety of means by which the dies may be coupled to the PIC 1230.

In FIG. 12A, an electrical interconnect is shown making a coupling (or abutted coupling) between elements in the AMS blocks of the dies and the corresponding elements in the PIC 1230. In one or more implementations, the interconnect is a copper pillar no longer than 2 millimeters. In one or more implementations, the copper pillar can be less than 2 millimeters and, in some instances, less than 400 microns. In other implementations, the electrical interconnects can be solder bumps made of materials such as tin, silver, or copper. If solder bumps are used for the interconnects, then the solder bumps may be flip-chip bumps. In other implementations, the interconnects may be elements of a ball-grid array (BGA), pins of a pin grid array (PGA), elements of a land grid array (LGA), or another type of interconnect. In each of these examples, the interconnects can be less than 2 millimeters and, in some cases, range from 1 to 400 microns.

In general, the interconnects have drivers (DRVs) or transimpedance amplifiers (TIAs) at one end and optical modulators (MODs) or photodetectors (PDs) at the other end. For example, in one or more implementations, the interconnects (e.g., vias such as TSVs) may physically couple with, and allow electrical signals to pass between, electrical elements (e.g., pads) of the dies and and/or the PIC 1230. For instance, vias 1242 pass through the PIC 1230 and electrically couple to electrical contacts 1244 at the bottom of the PIC 1230 or the circuit package 1200.

Additionally, in some instances, an electrical interconnect between a driver and a modulator allows the driver to provide an electrical signal that drives the modulator. In another instance, an interconnect between a transimpedance amplifier (TIA) and a photodetector allows the transimpedance amplifier to receive an electrical signal from the photodetector. In some implementations, the interconnects are such that a driver is stacked directly about a corresponding modulator with no lateral displacement between the two components and/or the two components are substantially in the same vertical column. Likewise, in some implementations, a TIA is stacked directly above a corresponding photodetector with no lateral displacement between the two components and/or the two components are substantially in the same vertical column.

The interconnects in the organic interposer may not have a uniform size, shape, or pitch. A finer pitch of interconnects may be desirable to allow a denser communication pathway between elements coupled to the PIC 1230. In one or more implementations, one or more interconnects have minimal lateral displacement. For example, an interconnect is a copper pillar that is straight up and down, perpendicular to the face of a die and the PIC 1230 (e.g., between 1-400 microns in length). This allows the electronic transceiver portions in the AMS block (e.g., DRV and TIA) to be directly stacked at one end of the interconnect above its respective photonic transceiver portion in the PIC (EAM and PD) at the other end of the interconnect. In some implementations, the DRV and TIA, as well as the EAM and PD, can be slightly offset from the copper pillar to reduce parasitic effects while still enabling a sub-400-micron gap (interconnect length) between heat-producing elements in the EIC/AMS and passive elements in the PIC 1230.

FIG. 12B shows an example of a circuit package 1305 that enables an inter-chip or inter-package connection. In particular, FIG. 12B shows a circuit package 1205 (e.g., an electro-photonic circuit package) with a photonic path between the circuit package 1205 and one or more external devices, which may include another circuit package. Similar to the description above, the circuit package 1205 includes the GC region 1245 of the PIC 1280 connected to an FAU 1235. The circuit package 1205 includes an internal cavity area in the organic interposer 1214 that enables the FAU 1235 to couple directly to the GC region 1245. Through the FAU 1235 and the PIC 1280, light signals can enter and exit the circuit package 1205. For example, one or more bidirectional photonic paths through the PIC 1280 allow dies connected to the PIC 1280 to communicate with other external devices.

In FIG. 12B, paths for unmodulated light have been omitted in the PIC 1280. Instead, FIG. 12B shows a first die 1210 and second die 1220 that can photonically communicate with an external device 1275 (e.g., an external device optical interface) via fibers 1265 (e.g., optical fibers), the FAU 1235, and the PIC 1280.

The first die 1210 may transmit data to the external device 1275 via hardware components 1222A, Interface 1, SER1, DRV1, MOD1, and a first photonic path 1281. As shown, the first photonic path 1281 includes an optional multiplexer (MUX1) when wavelength division multiplexing is desired, a first grating coupler in the GC region 1245, the FAU 1235, and/or the fibers 1265. Similarly, the first die 1210 may receive data from the external device 1275 via a second photonic path 1283. The second photonic path 1283 includes the fibers 1265, the FAU 1235, a second grating coupler in the GC region 1245, and/or an optional demultiplexer when wavelength division demultiplexing is desired, PD1, TIA1, SER2 and Interface1 (I/F1). The first photonic path 1281 and the second photonic path 1283 (also referred to as unidirectional electro-photonic links) form a bidirectional data path between two devices on different chips.

While one or more of the above examples refer to specific types of dies, interconnects, substrates, grating couplers, and other specific elements associated with transmitting signals via respective components of the example packages, these are illustrative examples and may utilize different types of components. For example, the two (or more) dies may refer to a variety of hardware or dies and not necessarily the pairing of a general die and an AMS die as described in specific implementations herein. Indeed, the two dies may be similar types of hardware and may refer to computing hardware, processing hardware, storage hardware, memory hardware, or other hardware that is implemented on dies and may be coupled to a PIC that optically couples one or more of the dies to an external component in accordance with one or more implementations described herein.

As mentioned above, inter-chip or inter-package connections can include a photonic pathway in both directions (e.g., a bidirectional electro-photonic path), through which data may be communicated between a variety of external components (e.g., another circuit package) that are configured with the external device. In addition, it should be noted that features and functionality of the circuit package may be implemented within a variety of implementations and configurations of packages having different components, setups, and configurations.

FIG. 12C illustrates another example of the circuit package 1206 that enables an inter-chip or inter-package connection. As with the circuit package 1205 in FIG. 12B, the circuit package 1206 in FIG. 12C can represent an electro-photonic circuit package with a photonic path between the circuit package 1206 and one or more external devices, which may include another circuit package.

Differing from the circuit package 1205 of FIG. 12B, the circuit package 1206 in FIG. 12C shows the drivers and the transimpedance amplifiers, located on the PIC 1280 rather than in the dies. In particular, driver DRV1 is connected to modulator MOD1 in the PIC 1280, and transimpedance amplifier TIA1 is connected to photodetector PD1 in the PIC 1280. Similarly, the circuit package 1206 shows that driver DRV2 is connected to modulator MOD2 in the PIC 1280, and that transimpedance amplifier TIA2 is connected to photodetector PD2 in the PIC 1280.

The drivers (DRV1, DRV2) and modulators (MOD1, MOD2) may be directly connected, connected via an electrical connection, or otherwise electrically connected. Similarly, the transimpedance amplifiers (TIA1, TAI2) and the photodetectors (PD1, PD2) may be directly connected, connected via an electrical connection, or otherwise electrically connected. In various implementations, connecting drivers with modulators and transimpedance amplifiers with photodetectors in close proximity causes the heat from the drivers and transimpedance amplifiers to thermally stabilize the modulators and photodetectors to operate in optimal operational ranges.

Additionally, similar to the circuit package 1205 of FIG. 12B, the circuit package 1206 in FIG. 12C includes serializers (SER1, SER2) and deserializers (DES1, DES2) in the AMS blocks. However, the serializers and deserializers in the circuit package 1206 connect to the drivers and transimpedance amplifiers via the organic interposer 1214 rather than within the AMS blocks.

As mentioned, the circuit package 1206 includes an organic interposer 1214 between the PIC 1280 and the dies (e.g., the first die 1210 and the second die 1220). The organic interposer 1214 may include a bondpad pattern (e.g., an electrical connection element) located over DRV1 and TIA1 that matches a bondpad pattern on the first die 1210 located under SER1 and SER2, or is otherwise configured to form an electrical interconnection between the respective components. The organic interposer 1214 may also include a bondpad pattern located over TIA2 and DRV2 that matches a bondpad pattern on the second die 1220 located under DES2 and SER2, or is otherwise configured to form an electrical interconnection between the respective components.

Two or more bondpads of the bondpad pattern on the first die 1210 are physically and electrically coupled with two or more bondpads of the bondpad pattern in the organic interposer 1214. Similarly, two or more bondpads of the bondpad pattern on the second die 1220 are physically and electrically coupled with two or more bondpads of the bondpad pattern in the organic interposer 1214.

In one or more implementations, the connective elements (e.g., interconnects) in the organic interposer 1214 connect the dies (e.g., the first die 1210 and/or the second die 1220) to the top surface of the PIC 1230. In addition, the interconnects may be implemented using a variety of structures, including copper pillars, solder connections, pads (e.g., bondpads), bump attachments, vias, or any variety of means by which the dies may be coupled to the PIC 1230. Other similarities discussed above with the circuit package 1205 in FIG. 12B may also apply to the circuit package 1206 of FIG. 12C.

FIG. 12D illustrates another example of the circuit package 1207 having inter-chip or inter-package connections via an edge coupler 1252, according to embodiments of the present disclosure. The edge coupler 1252 may be located at an edge of the PIC 1280 and/or PIC layer 1202 and may facilitate photonically connecting one or more optical fibers 1265 (e.g., horizontally) at the edge of the PIC 1280 to photonically connect the circuit package 1207 with an external device 1275. For example, the edge coupler 1252 may be positioned at an edge that is formed in the PIC 1280 after the PIC 1280 is diced to separate and/or isolate the circuit package 1207 as a discrete chip from one or more other circuit packages that may be formed on a larger wafer structure.

The edge coupler 1252 may include one or more (typically many) alignment features 1254, such as grooves (e.g., V-grooves), slots, cutouts, or other geometries which may receive and/or align the optical fiber(s) 1265 such that the optical fiber(s) 1265 align with one or more waveguides within the PIC 1280. For instance, these alignment features 1254 may be structures which are designed with a tapered or mode-matching region, to align modes of the optical fibers 1265 and the waveguides at the edge of the PIC 1280 thereby reducing insertion loss and enhancing coupling efficiency therebetween. The waveguides may connect to the various photonic components of the PIC 1230 in any manner described herein (e.g., including any other photonic components of the PIC 1230 as described). In this way, the edge coupler 1252 may provide a photonic interface for the photonic components of the PIC 1230 to transmit and receive off-chip photonic signals, similar to the GC region 1245 as described above.

The edge coupler 1252 may be implemented in the circuit package 1207 as an alternative to the GC region 1245 and FAU 1235, or else may be included in addition to these components. For example, in some implementations the GC region 1245 and the edge coupler 1252 are each photonic interfaces which achieve similar objectives of facilitating photonic communication to and/or from the circuit package 1207 with another device, and the circuit package 1207 may be implemented with only one type of these photonic interfaces. For instance, in some cases the GC region 1245 and FAU 1235 may facilitate a vertical or top connection of one or more optical fibers 1265, and the edge coupler 1252 may facilitate a horizontal or side connection of one or more optical fibers 1265. Accordingly, the GC region 1245 or else the edge coupler 1252 may be particularly suited for a specific implementation, space, and/or packaging requirement of the circuit package 1207. In other cases, the circuit package 1207 may be implemented with both the GC region 1245 and the edge coupler 1252, for example, for providing adaptability and connectivity to many different types of devices.

The PIC 1280 and the circuit package 1207 as described above may be exemplary of any of the wafers, circuit packages, wafer packages, or other connections and/or collections of components as described in any of the embodiments herein. For example, various embodiments herein may be described as having a wafer, PIC, PIC wafer, substrate, dies, EIC, etc., and it should be understood that any of these embodiments (e.g., and others described herein) may be implemented having any of the features, components, or configurations as described in FIGS. 8A-12D. For instance, in cases where an electronic component, die, EIC, chip, etc., is described as being connected to, coupled to, positioned on, disposed on, bonded to, etc., in connection with a PIC or PIC wafer (or the like), it should be understood that such components are positioned with respect to photonic components in the PIC wafer and correspondingly connected to the same via electronic interconnects.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or processing process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A memory package, comprising:
a first plurality of interconnected memory layers stacked on top of a first logic buffer;
a second plurality of interconnected memory layers stacked on top of a second logic buffer;
a first die layer comprising:
a first die having an electrical portion of a first electro-photonic transceiver stacked below the first logic buffer, the electrical portion of the first electro-photonic transceiver being configured to send or receive instructions to the first logic buffer to read or write data to or from one or more of the first plurality of interconnected memory layers; and
a second die having an electrical portion of second electro-photonic transceiver stacked below the second logic buffer, the electrical portion of the second electro-photonic transceiver being configured to send or receive instructions to the second logic buffer to read or write data to or from one or more of the second plurality of interconnected memory layers; and
a second die layer stacked below the first die layer comprising a wafer having an optical portion of the first electro-photonic transceiver and an optical portion of the second electro-photonic transceiver, the optical portion of the first electro-photonic transceiver being connected to the electrical portion of the first electro-photonic transceiver via first electrical interconnects between a top surface of the wafer a bottom surface of the first die, the optical portion of the second electro-photonic transceiver being connected to the electrical portion of the second electro-photonic transceiver via second electrical interconnects between the top surface of the wafer and a bottom surface of the second die, the second die layer including a plurality of waveguides formed in the wafer optically coupling the optical portion of the first electro-photonic transceiver and the optical portion of the second electro-photonic transceiver.

2. The memory package of claim 1, wherein the first plurality of interconnected memory layers and the second plurality of interconnected memory layers are formed within a plurality of memory wafers that are stacked over the first die layer.

3. The memory package of claim 2, wherein a first memory layer of the first plurality of interconnected memory layers and a first memory layer of the second plurality of interconnected memory layers are formed within a first memory wafer of the plurality of memory wafers, and wherein a second memory layer of the first plurality of interconnected memory layers and a second memory layer of the second plurality of interconnected memory layers are formed within a second memory wafer of the plurality of memory wafers.

4. The memory package of claim 1, further comprising an overmold layer including an overmold deposited over the first plurality of interconnected memory layers, the second plurality of interconnected memory layers, and at least a portion of a top surface of the wafer of the second die layer.

5. The memory package of claim 1, wherein the first plurality of interconnected memory layers and the first logic buffer are connected using a first one or more electrical vias, and wherein the second plurality of interconnected memory layers and the second logic buffer are connected using a second one or more electrical vias.

6. The memory package of claim 1, wherein the first logic buffer is implemented as a layer within a first memory stack including the first plurality of interconnected memory layers, the first logic buffer positioned between the first plurality of interconnected memory layers and top surface of the first die, and wherein the second logic buffer is implemented as a layer within a second memory stack including the second plurality of interconnected memory layers, the second logic buffer positioned between the second plurality of interconnected memory layers and top surface of the second die.

7. The memory package of claim 1, wherein the first logic buffer is implemented within the first die and the second logic buffer is implemented within the second die.

8. The memory package of claim 1, wherein each electro-photonic transceiver of the first and second electro-photonic transceivers includes:
a driver connected to a modulator in the wafer;
a transimpedance amplifier (TIA) connected to a photodiode in the wafer;
a serializer in the first die layer that provides an output to the driver; and
a deserializer in the first die layer that receives an input from the TIA.

9. The memory package of claim 8, wherein one or more of the driver and the TIA is in the wafer of the second die layer.

10. The memory package of claim 8, wherein the driver is selected from the group consisting of an electro-absorption modulator (EAM), a micro-ring resonator, a ring modulator, a Mach-Zender interferometer (MZI), and a quantum confined stark effect (QCSE) electro-absorptive modulator.

11. The memory package of claim 1, wherein each memory layer of the first and second plurality of interconnected memory layers includes a memory resource, wherein the memory resource is one or more of a NAND Flash memory, a solid-state drive (SSD) memory, a NOR Flash memory, a CMOS memory, a thin film transistor-based memory, a phase change memory (PCM), a storage class memory (SCM), a magneto-resistive memory (MRAM), a resistive RAM, a DRAM, an HBM, a DDR-based DRAM, or a DIMM memory.

12. The memory package of claim 1, further comprising an optical region on a surface of the wafer of the second die layer being designed to allow light to exit or enter from the top surface of the wafer, the optical region being in communication with an optical portion of an additional electro-photonic transceiver, the additional electro-photonic transceiver including an electrical portion in the first die layer and a photonic portion in the second die layer, wherein the optical region is coupled to the photonic portion of the additional electro-photonic transceiver via one or more waveguides formed within the wafer.

13. The memory package of claim 12, further comprising an optical interface component configured to couple a first optical signal in a first fiber to a first waveguide in the second die layer when receiving and to couple a second optical signal from a second waveguide to a second fiber when transmitting.

14. The memory package of claim 13, wherein the optical interface component is a fiber array unit (FAU).

15. The memory package of claim 13, wherein the optical interface component is an edge coupling structure formed within a side surface of the wafer.

16. A memory package, comprising:
a first plurality of interconnected memory layers stacked on top of a first logic buffer;
a second plurality of interconnected memory layers stacked on top of a second logic buffer;
an electronic integrated circuit (EIC) layer, comprising:
a first electrical die having an electrical portion of a first electro-photonic transceiver stacked below the first logic buffer, the electrical portion of the first electro-photonic transceiver being configured to send or receive instructions to the first logic buffer to read or write data to or from one or more of the first plurality of interconnected memory layers; and
a second electrical die having an electrical portion of a second electro-photonic transceiver stacked below the second logic buffer, the electrical portion of the second electro-photonic transceiver being configured to send or receive instructions to the second logic buffer to read or write data to or from one or more of the second plurality of interconnected memory layers; and
a photonic integrated circuit (PIC) wafer having an optical portion of the first electro-photonic transceiver and an optical portion of the second electro-photonic transceiver, the optical portion of the first electro-photonic transceiver being connected to the electrical portion of the first electro-photonic transceiver via first electrical interconnects between a top surface of the PIC wafer and a bottom surface of the first electrical die, the optical portion of the second electro-photonic transceiver being connected to the electrical portion of the second electro-photonic transceiver via second electrical interconnects between the top surface of the PIC wafer and a bottom surface of the second electrical die, the PIC wafer including a plurality of waveguides optically coupling the optical portion of the first electro-photonic transceiver and the optical portion of the second electro-photonic transceiver.

17. The memory package of claim 16, wherein the first plurality of interconnected memory layers and the second plurality of interconnected memory layers are formed within a plurality of memory wafers that are stacked over the EIC layer.

18. The memory package of claim 17, wherein a first memory layer of the first plurality of interconnected memory layers and a first memory layer of the second plurality of interconnected memory layers are formed within a first memory wafer of the plurality of memory wafers, and wherein a second memory layer of the first plurality of interconnected memory layers and a second memory layer of the second plurality of interconnected memory layers are formed within a second memory wafer of the plurality of memory wafers.

19. The memory package of claim 16, further comprising an overmold layer including an overmold deposited over the first plurality of interconnected memory layers, the second plurality of interconnected memory layers, and at least a portion of a top surface of the PIC wafer.

20. The memory package of claim 16, wherein the first plurality of interconnected memory layers and the first logic buffer are connected using a first one or more electrical vias, and wherein the second plurality of interconnected memory layers and the second logic buffer are connected using a second one or more electrical vias.

21. The memory package of claim 16, wherein the first logic buffer is implemented as a layer within a first memory stack including the first plurality of interconnected memory layers, the first logic buffer positioned between the first plurality of interconnected memory layers and top surface of the first electrical die, and wherein the second logic buffer is implemented as a layer within a second memory stack including the second plurality of interconnected memory layers, the second logic buffer positioned between the second plurality of interconnected memory layers and top surface of the second electrical die.

22. The memory package of claim 16, wherein the first logic buffer and the second logic buffer are implemented within the EIC layer.

23. The memory package of claim 16, wherein each electro-photonic transceiver of the first and second electro-photonic transceivers includes:
a driver connected to a modulator in the PIC wafer;
a transimpedance amplifier (TIA) connected to a photodiode in the PIC wafer;
a serializer in the EIC layer that provides an output to the driver; and
a deserializer in the EIC layer that receives an input from the TIA.

24. The memory package of claim 23, wherein one or more of the driver and the TIA is in the PIC wafer of the second die layer.

25. The memory package of claim 23, wherein the driver is selected from the group consisting of an electro-absorption modulator (EAM), a micro-ring resonator, a ring modulator, a Mach-Zender interferometer (MZI), and a quantum confined stark effect (QCSE) electro-absorptive modulator.

26. The memory package of claim 16, wherein each memory layer of the first and second plurality of interconnected memory layers includes a memory resource, wherein the memory resource is one or more of a NAND Flash memory, a solid-state drive (SSD) memory, a NOR Flash memory, a CMOS memory, a thin film transistor-based memory, a phase change memory (PCM), a storage class memory (SCM), a magneto-resistive memory (MRAM), a resistive RAM, a DRAM, an HBM, a DDR-based DRAM, or a DIMM memory.

27. The memory package of claim 16, further comprising an optical region on a surface of the PIC wafer being designed to allow light to exit or enter from the top surface of the PIC wafer, the optical region being in communication with an optical portion of an additional electro-photonic transceiver, the additional electro-photonic transceiver including an electrical portion in the EIC layer and a photonic portion in the PIC wafer, wherein the optical region is coupled to the photonic portion of the additional electro-photonic transceiver via one or more waveguides formed within the PIC wafer.

28. The memory package of claim 16, further comprising an optical interface component configured to couple a first optical signal in a first fiber to a first waveguide in the PIC wafer when receiving and to couple a second optical signal from a second waveguide to a second fiber when transmitting.
